(19) United States
(12) Patent Application Publication
(10) Pub. No.: US 2011/0311914 A1
(43) Pub. Date: Dec. 22, 2011

(54) RESIST COMPOSITION FOR NEGATIVE-TONE DEVELOPMENT AND PATTERN FORMING METHOD USING THE SAME

(75) Inventors: Sou Kamimura, Shizuoka (JP); Shinji Tarutani, Shizuoka (JP)

(73) Assignee: FUJIFILM CORPORATION, Tokyo (JP)

(21) Appl. No.: 13/203,025

(22) PCT Filed: Feb. 24, 2010
(86) PCT No.: PCT/JP2010/053375

§ 371 Date: Aug. 24, 2011

(30) Foreign Application Priority Data
Feb. 24, 2009 (JP) 2009-041379

(51) Int. Cl. G03F 7/004; G03F 7/20

(52) U.S. Cl. 430/270.1; 430/325; 430/326

(57) ABSTRACT

Provided is a resist composition for negative-tone development, including: (A) a resin having an acid-decomposable repeating unit represented by the following general formula (1) and being capable of decreasing the solubility in a negative developer by the action of an acid:

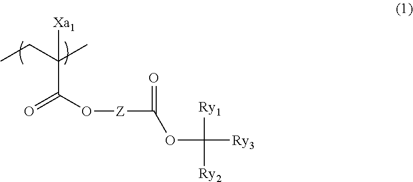

wherein, in the general formula (1), Xa₁ represents a hydrogen atom, an alkyl group, a cyano group, or a halogen atom, each of Ry₁ to Ry₃ independently represents an alkyl group or a cycloalkyl group, and at least two of Ry₁ to Ry₃ may be bonded to each other to form a ring structure, and Z represents a divalent linking group.

### TECHNICAL FIELD

The present invention relates to a resist composition for negative-tone development, which is used in the preparation process for semiconductors such as IC and the like, in the preparation of a circuit substrate of liquid crystal, thermal heads, or the like, and further, in the lithographic process for other photofabrications, and a pattern forming method using the same. Particularly, the present invention relates to a resist composition for negative-tone development, which is suitable for exposure by an ArF exposure apparatus and an immersion-type projection exposure apparatus, each using a light source of emitting far ultraviolet light at a wavelength of 300 nm or less, and a pattern forming method using the same.

### BACKGROUND ART

In the positive-tone system for pattern formation as described above (combination of a resist composition and a positive-tone developer), there is merely provided a material whereby a pattern is formed by selectively dissolving and removing an area with high light irradiation intensity in the aerial frequencies of an optical image, as shown in FIG. 1. On the contrary, in the negative-tone system as described above (combination of a resist composition and a negative-tone developer), there is merely provided a material system whereby a pattern is formed by selectively dissolving and removing an area with low light irradiation intensity.

The positive-tone developer as used herein refers to a developer by which an exposed part at or above a predetermined threshold shown by the solid line in FIG. 1 is selectively dissolved and removed, and the negative-tone developer refers to a developer by which an exposed part at or under the predetermined threshold is selectively dissolved and removed. A development step using a positive-tone developer is called positive-tone development (also called a positive-tone development step), while a development step using a negative-tone developer is called negative-tone development (also called a negative-tone development step).

As for a positive-tone system, for example, JP-A-2005-352466 describes a chemical amplification positive-tone resist composition containing a resin having at least one repeating unit selected from the group consisting of a repeating unit having a specific adamantane structure and a repeating unit having a specific butyrolactone structure, and a repeating unit having a specific norbornane lactone structure, and an acid generator, and it is described that according to this positive-tone resist composition, a resist composition suitable for ArF excimer laser lithography, which has good line edge roughness, in addition to the performances such as resolution, sensitivity, pattern shape, and the like, and which is capable of forming a finer pattern in a reflow process is obtained.

On the other hand, a double development technique as a double patterning technique for further improving resolution higher than that of conventional positive-tone systems is described in JP-A-2000-199953. In this instance, a general image forming method by chemical amplification is employed, and by utilizing a phenomenon that the polarity of a resin in a resist composition is elevated by exposure in an area with a high light intensity and lowered in an area with a low light intensity, the positive-tone development is conducted by dissolving a high exposure area of a specific resist film in a developer having a high polarity and the negative-tone development is conducted by dissolving a low exposure area thereof in a developer having a low polarity. Specifically, an area wherein the exposure dose of irradiation light 1 is E2 or more is dissolved by using an aqueous alkali solution as a positive-tone developer, while an area wherein the exposure dose is E1 or less is dissolved by using a specific organic solvent as a negative-tone developer, as shown in FIG. 2. Thus, an area with a medium exposure dose (E2 to E1) remains as a non-developed area and an L/S pattern 3 whose pitch is half that of the mask pattern for exposure 2 is formed on a wafer 4, as shown in FIG. 2.

JP-A-2008-292975 discloses a pattern forming method by negative tone development and by double development and double exposure each using the negative development.

However, in the pattern forming using the negative-tone development which can be used for forming the fine pattern as described above, there is a demand that a fine pattern having higher precision can be stably obtained due to its excellent line width roughness (LWR), exposure latitude (EL), and depth of focus (DOF).

### SUMMARY OF INVENTION

It is an object of the present invention to provide a resist composition for negative-tone development, which is excellent in line width roughness (LWR), exposure latitude (EL), and depth of focus (DOF), and a pattern forming method using the same, so that a fine pattern having high precision for the preparation of an electronic device having high precision as well as high integration may be stably formed, by solving the above-described problems.

The present invention has the following constitution, whereby the object of the present invention as described above is accomplished.

(1) A resist composition for negative-tone development, comprising:

(A) a resin having an acid-decomposable repeating unit represented by the following general formula (1) and being capable of decreasing the solubility in a negative developer by the action of an acid:

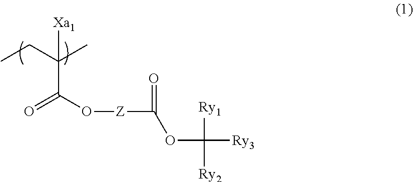

wherein, in the general formula (1),

Xa₁ represents a hydrogen atom, an alkyl group, a cyano group, or a halogen atom,

each of Ry₁ to Ry₃ independently represents an alkyl group or a cycloalkyl group, and at least two of Ry₁ to Ry₃ may be bonded to each other to form a ring structure, and

Z represents a divalent linking group.

(2) The resist composition for negative-tone development as described in (1), wherein

in the case where at least two of Ry₁ to Ry₃ are bonded to each other to form a monocyclic hydrocarbon structure, the monocyclic hydrocarbon structure is a 6 or more-membered ring.

(3) The resist composition for negative-tone development as described in (1), wherein

the repeating unit represented by the general formula (1) is an acid-decomposable repeating unit represented by the following general formula (2a) or (2b):

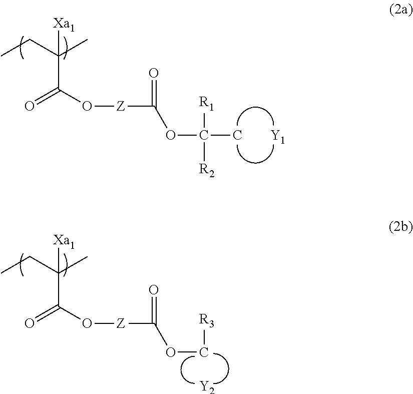

wherein, in the general formulae (2a) and (2b),

Xa₁ and Z are respectively the same as Xa₁ and Z in the general formula (1),

Y₁ represents a plurality of atoms necessary to complete an alicyclic hydrocarbon group together with the carbon atom as shown,

Y₂ represents a plurality of atoms necessary to complete an alicyclic hydrocarbon group together with the carbon atom as shown, and

each of R₁, R₂, and R₃ independently represents an alkyl group or a cycloalkyl group.

(4) The resist composition for negative-tone development as described in (3), wherein

the resin (A) does not have a repeating unit derived from an acrylic acid or an acrylic ester, in the case where the total number of carbon atoms of Y₁, R₁, and R₂ in the general formula (2a) is 6 or less, and in the case where the total number of carbon atoms of Y₂ and R₃ in the general formula (2b) is 6 or less.

(5) The resist composition for negative-tone development as described in (3), wherein

with respect to all repeating units derived from an acrylic acid or an acrylic ester in the resin (A), a carbon atom at the α-position in the repeating units, which is a carbon atom constituting a main chain of the resin and bonding to a —C(═O)— group, is substituted with a substituent other than a hydrogen atom via a bonding moiety not constituting the main chain of the resin and not bonding to the —C(═O)— group, in the case where the total number of carbon atoms of Y₁, R₁, and R₂ in the general formula (2a) is 6 or less, and in the case where the total number of carbon atoms of Y₂ and R₃ in the general formula (2b) is 6 or less.

(6) The resist composition for negative-tone development as described in (5), wherein

the substituent is an alkyl group, a cyano group, or a halogen atom.

(7) The resist composition for negative-tone development as described in (5), wherein

the substituent is a methyl group.

(8) The resist composition for negative-tone development as described in any one of (1) to (7), further comprising:

(B) an acid generator; and

(C) a solvent.

(9) A pattern forming method comprising:

(a) a step of forming a film with the resist composition for negative-tone development as described in any one of (1) to (8),

(b) a step of exposing the film, and

(d) a step of developing the film with a negative-tone developer.

(10) The pattern forming method as described in (9), further comprising:

(c) a step of developing the film with a positive-tone developer,

wherein

the resin is a resin capable of increasing the polarity by the action of an acid to increase the solubility in a positive-tone developer.

### BRIEF DESCRIPTION OF DRAWINGS

FIG. 1 is a schematic view showing the relationship of the positive-tone development, the negative-tone development, and the exposure dose in a conventional method;

FIG. 2 is a schematic view showing the pattern forming method with the use of combination of the positive-tone development and the negative-tone development;

FIG. 3 is a schematic view showing the relationship of the positive-tone development, the negative-tone development, and the exposure dose;

FIG. 4 is graphs each showing the relationship of the exposure dose and the residual film ratio in the case of using a positive-tone developer or a negative-tone developer;

FIG. 5 is a schematic view showing the relationship of the positive-tone development, the negative-tone development, and the exposure dose in the method of the present invention;

FIG. 6 is a schematic view showing the relationship of the positive-tone development, the negative-tone development, and the exposure dose in the method of the present invention;

FIG. 7 is a schematic view showing the relationship of the positive-tone development, the negative-tone development, and the exposure dose in the method of the present invention;

FIG. 8 shows the aerial intensity distribution of an optical image;

FIG. 9 is a schematic view showing the relationship of the positive-tone development, the threshold (a), and the light intensity;

FIG. 10 shows the aerial intensity distribution of an optical image; and

FIG. 11 is a schematic view showing the relationship of the negative-tone development, the threshold (b), and the light intensity,

wherein
1 denotes Irradiation light, 2 denotes Exposure mask, 3 denotes Pattern, and 4 denotes Wafer.

### DESCRIPTION OF EMBODIMENTS

Next, the best mode for carrying out the present invention will be described.

Further, in illustrating groups (atomic groups) in the present specification, those which are not indicated as being substituted or unsubstituted include both of groups having no substituent and those having a substituent. For example, the “alkyl group” includes an alkyl group having no substituent (an unsubstituted alkyl group) as well as an alkyl group having a substituent (a substituted alkyl group).

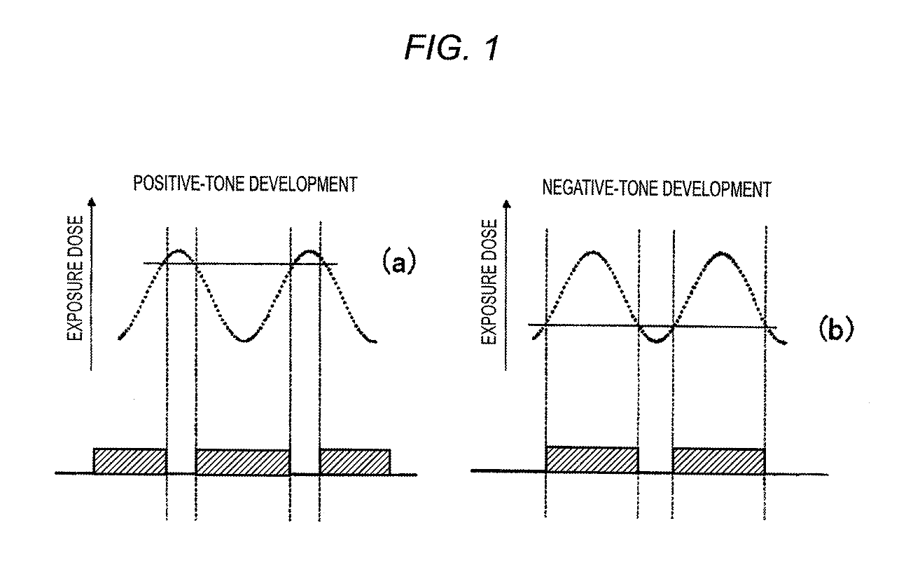

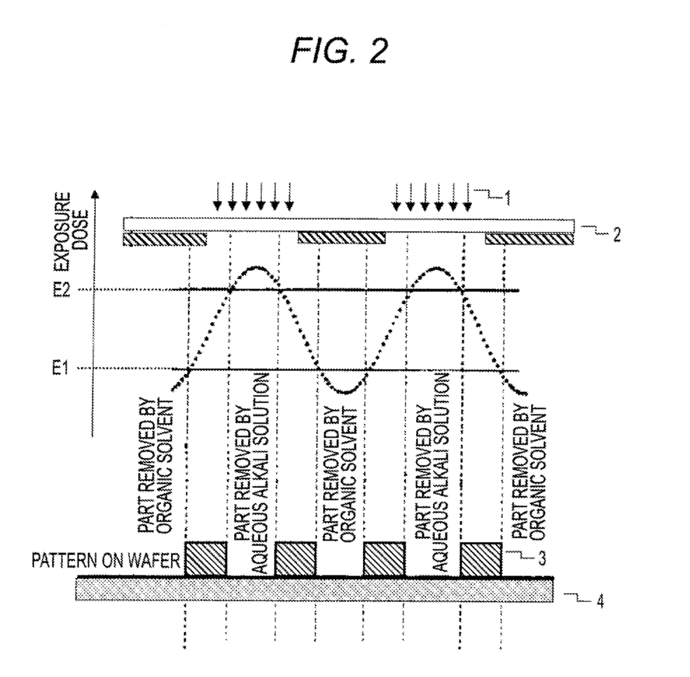

First, the meanings of terms as used in the specification will be described. Pattern forming methods are classified into the positive tone and the negative tone, and although a change in the solubility of a resist film in a developer due to a chemical reaction induced by light irradiation is utilized in both of these systems, an irradiated part is dissolved in a developer in the positive-tone system while a non-irradiated part is dissolved in a developer in the negative-tone system. There are two types of developers, i.e., a negative-tone developer and a positive-tone developer, to be used therein. Positive-tone developer refers to a developer by which an exposed part at or above a predetermined threshold shown by a solid line in FIG. 1 is selectively dissolved and removed. Negative-tone developer is, as described above, a developer by which an exposed part at or under the predetermined threshold is selectively dissolved and removed. A development step using a positive-tone developer is called a positive-tone development (also called a positive-tone development step), while a development step using a negative-tone developer is called a negative-tone development (also called a negative-tone development step). Multiple development (also called a multiple development step) is a development system wherein a development step with the use of a positive-tone developer as described above is combined with a development system with the use of a negative-tone developer as described above. In the present invention, the resist composition used in negative-tone development is called a resist composition for negative-tone development, while the resist composition used in multiple development is called a resist composition for multiple development. A simple expression, “the resist composition” indicates both of a resist composition for negative-tone development and a resist composition for multiple development. A rinsing liquid for negative-tone development means a rinsing liquid containing an organic solvent which is used in a washing step following the negative-tone development step.

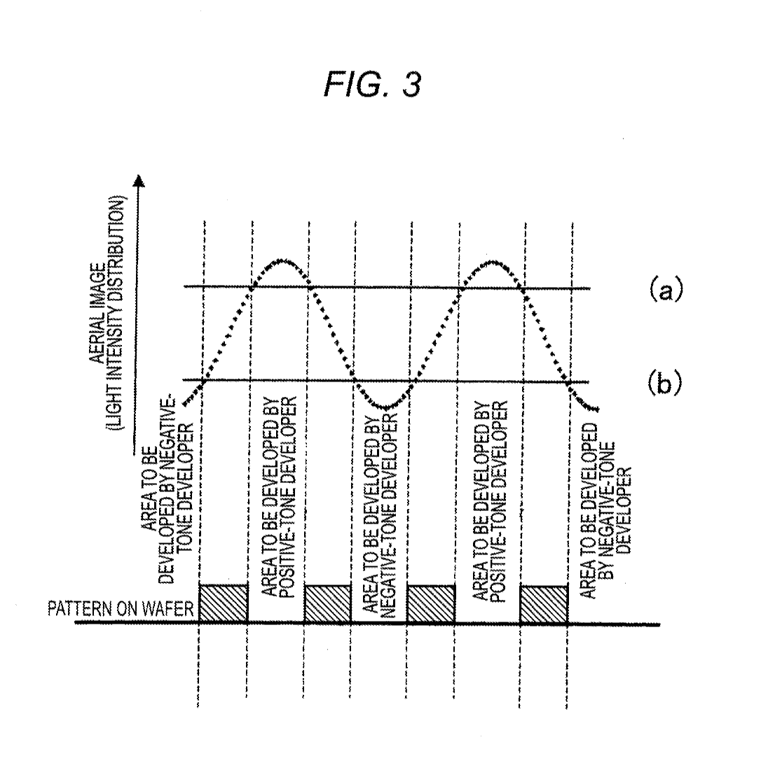

In the present invention, as a technique for improving resolution, the present invention presents a novel pattern forming method, in which a developer (a negative-tone developer) by which an exposed part at or under a predetermined threshold (b) is selectively dissolved and removed as shown in FIG. 3 is combined with a resist composition for negative-tone development for forming a film, which contains a resin capable of increasing the polarity by the action of an acid, and which shows, upon irradiation with an actinic ray or radiation, an increase the solubility in a positive-tone developer (preferably an alkali developer) and a decrease in the solubility in a negative-tone developer (preferably an organic developer).

The resist composition for negative-tone development of the present invention further exhibits excellent development characteristics to a developer (a positive-tone developer) by which an exposed part at or above a predetermined threshold (a) is selectively dissolved and removed. Pattern formation using multiple development can be performed by combining a developer (a positive-tone developer) by which an exposed part at or above a predetermined threshold (a) is selectively dissolved and removed, a developer (a negative-tone developer) by which an exposed part at or under a predetermined threshold (b) is selectively dissolved and removed, and a resist composition for negative-tone development.

That is, when pattern elements on an exposure mask are projected onto a wafer by light irradiation as shown in FIG. 3, an area with a high irradiation intensity (an exposed area at or above the predetermined threshold (a)) is dissolved and removed by using a positive-tone developer, while an area with a low irradiation intensity (an exposed area at or under the predetermined threshold (b)) is dissolved and removed by using a negative-tone developer. As a result, a pattern having a resolution twice as high as the frequency of an optical aerial image (light intensity distribution) can be obtained.

Accordingly, the resist composition for negative-tone development of the present invention can be suitably used as a resist composition for multiple development.

The pattern forming process necessary to carry out the present invention includes the following steps.

A pattern forming method including

(a) a step of forming a film with a resist composition for negative-tone development, which contains a resin having an acid-decomposable repeating unit represented by following general formula (1) (which will be described in detail later) and being capable of decreasing the solubility in a negative developer by the action of an acid.

(b) a step of exposing the film; and

(d) a step of developing the film with a negative-tone developer.

For the pattern forming method of the present invention, the negative-tone developer is preferably a developer containing at least one solvent selected from a ketone-based solvent, an ester-based solvent, an alcohol-based solvent, an amide-based solvent, and an ether-based solvent.

For the pattern forming method of the present invention, the resin is a resin capable of increasing the polarity by the action of an acid to increase the solubility in a positive-tone developer, and it is preferable that the method further includes (c) a step of developing the film with a positive-tone developer.

It is preferable that the pattern forming method of the present invention further includes (f) a step of washing with a rinsing liquid including an organic solvent.

It is preferable that the pattern forming method of the present invention includes (e) a step of heating which follows (b) the step of exposing.

In the pattern forming method of the present invention, (b) the step of exposing can be conducted multiple times.

In the pattern forming method of the present invention, (e) the step of heating can be conducted multiple times.

In order to carry the present invention, a resist composition for negative-tone development, which contains (A) a resin having an acid-decomposable repeating unit represented by following general formula (1) (which will be described in detail later) and being capable of decreasing the solubility in a negative developer by the action of an acid, and (Ab) a negative-tone developer (preferably an organic developer) are needed.

It is preferable that (Ac) a positive-tone developer (preferably an alkali developer) is further used in order to carry out the present invention.

It is preferable that (Ad) a rinsing liquid for negative-tone development, containing an organic solvent is further used in order to carry out the present invention.

In the case of carrying out a pattern forming process using two kinds of developers, i.e., a positive-tone developer and a negative-tone developer, the order of the developments is not particularly limited, but after conducting the first exposure, a first development is preferably conducted using a positive-tone developer or a negative-tone developer and then a negative or positive-tone development is conducted using a developer of the different type from the first development. It is also preferable to conduct washing with a rinsing liquid for negative-tone development, containing an organic solvent after conducting the negative-tone development.

Examples of the pattern forming systems include (a) a system using a chemical reaction such as polarity change and the like, and (b) a system using the intermolecular bond formation such as a crosslinking reaction, a polymerization reaction, and the like.

In a resist material system in which the molecular weight of the resin increases due to the intermolecular bonding such as a crosslinking reaction, a polymerization reaction, and the like, it was difficult to construct a system wherein one resist material serves as a positive-tone resist to a developer but as a negative-tone resist to another developer.

According to the present invention, one resist composition can serve as a negative resist to a negative-tone developer but as a positive resist to a positive-tone developer, at the same time.

In the present invention, an organic-based developer containing an organic solvent can be used as a negative-tone developer, while an alkali (aqueous) developer can be used as a positive-tone developer.

In the present invention, it is important to control the “thresholds” of the exposure dose (i.e., the exposure dose at which a film becomes soluble or insoluble in the light irradiation area). To obtain a desired line width in pattern forming, the minimum exposure amount at which the film is soluble in the positive-tone developer and the minimum exposure dose at which the film is insoluble in the negative-tone developer are regarded as the “thresholds”.

The “thresholds” can be determined in the following manner.

That is, so as to obtain a desired line width in conducting the pattern formation, the minimum exposure amount at which the film is soluble in the positive-tone developer and the minimum exposure dose at which the film is insoluble in the negative-tone developer are regarded as the thresholds.

More strictly speaking, the thresholds are defined as follows.

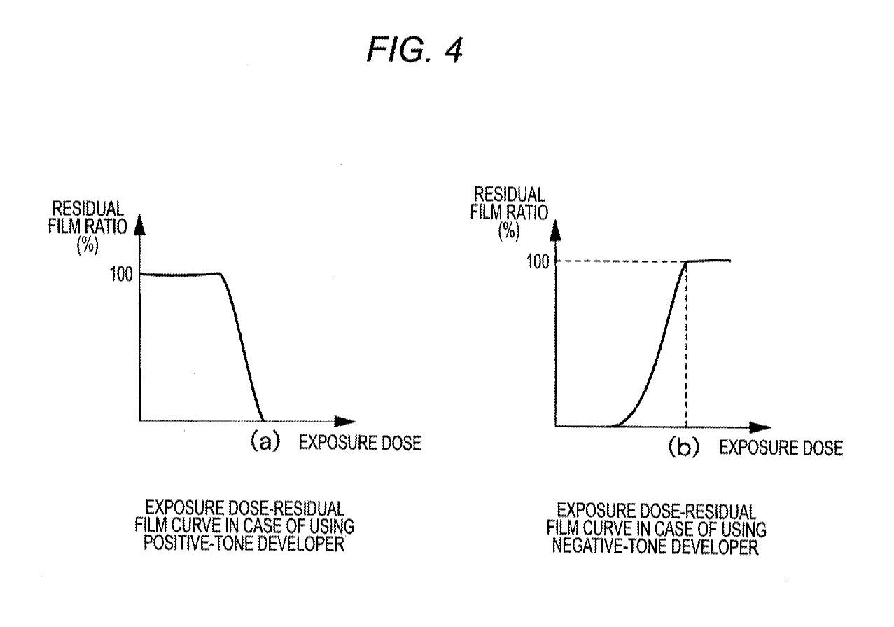

When the residual film ratio of a resist film to an exposure dose is measured, the exposure dose at which the residual film ratio to a positive-tone developer attains 0% is referred to as the threshold (a), and the exposure dose at which the residual film ratio to a negative-tone developer attains 100% is referred to as the threshold (b), as shown in FIG. 4.

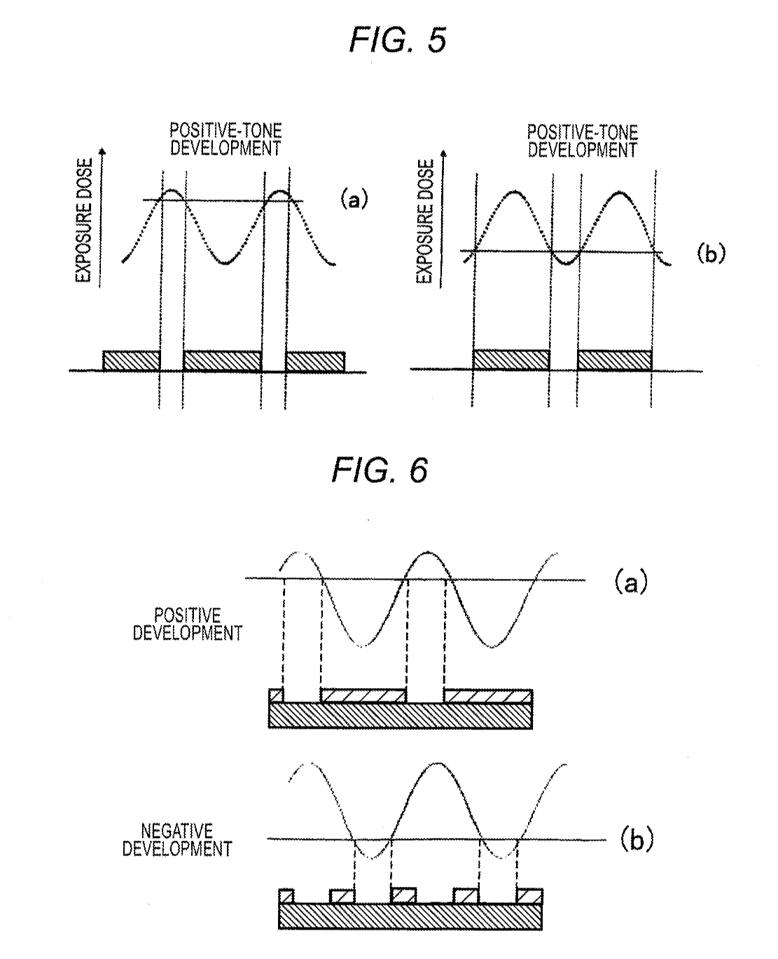

For example, by controlling the threshold (a) of the exposure dose at which the film becomes soluble in the positive-tone developer to a level higher than the threshold (b) of the exposure dose at which the film becomes soluble in the negative-tone developer as shown in FIG. 5, a pattern can be made by a single exposure. That is, a resist is first coated on a wafer, the wafer is exposed, and a part at or above the threshold (a) of the exposure dose is first dissolved by using the positive-tone developer, as shown in FIG. 6. Subsequently, a part at or under the threshold (b) of the exposure dose is dissolved by using the negative-tone developer. Thus, pattern forming can be completed by a single exposure. In this case, the development with the positive-tone developer and the development with the negative-tone developer may be conducted in an arbitrary order. By washing the film with a rinsing liquid containing an organic solvent after the negative-tone development, better pattern formation can be allowed.

Examples of the methods of controlling the thresholds include a method including controlling parameters concerning the materials such as a resist composition and a developer or parameters concerning the process.

As the parameters concerning the materials, it is effective to control various physical values concerning the solubilities of the resist composition in developers and organic solvents, i.e., SP values (solubility parameters), Log P values, and the like. Specific examples thereof include the weight-average molecular weight, the weight average dispersion, the monomer composition ratio, the monomer polarity, the monomer sequence, the polymer blend, and the addition of a low-molecular weight additive of a polymer contained in the resist composition, and for the developer, the concentrations of a developer, the addition of a low-molecular weight additive, the addition of a surfactant, and the like.

Further, examples of the parameters concerning the process include the film-forming temperature, the film-forming time, the temperature and time upon the post-exposure heating, the temperature upon development, the development time, the nozzle system (solution-supply method) of the development device, the post-development rinsing method, and the like.

Therefore, in order to obtain an excellent pattern in the pattern forming method by using negative-tone development and the pattern forming method by multiple development with the use of a combination of negative-tone development with positive-tone development, it is important to appropriately control the parameters concerning the materials and the parameters concerning the process as described above, and combine them.

In the pattern forming process by using two types of developers, i.e., a positive-tone developer and a negative-tone developer, the exposure may be conducted once as described above. Alternatively, the exposure may be conducted twice or more. That is, the first exposure is conducted, followed by development by using a positive or negative-tone developer, and then the second exposure is conducted, followed by development by using a developer which is different from the one used in the first development.

The merit achieved by conducting the exposure twice or more resides in that the thresholds in the development following the first exposure can be controlled and the thresholds in the development following the second exposure can be controlled at a higher degree of freedom. In the case of conducting the exposure twice or more, it is desirable that the exposure dose in the second exposure is higher than the exposure dose in the first exposure. In the second development, as shown in FIG. 7, the thresholds are determined based on the added amount of the history of the first and second exposure doses. When the exposure dose in the second exposure is sufficiently higher than the exposure dose in the first exposure, the exposure dose in the first exposure exerts only a small effect that can be ignored in some cases.

It is desirable that the exposure dose (Eo1 [mJ/cm²]) in the first exposure step is lower by 5 [mJ/cm²] or more than the exposure dose (Eo2 [mJ/cm²]) in the second exposure step. Thus, the effect of the first exposure history on the pattern forming process by the second exposure can be lessened.

In order to change the first exposure dose and the second exposure dose, it is effective to employ the method of controlling various parameters concerning the materials and the process as discussed above. It is particularly effective to control the temperature in the first heating step and the temperature in the second heating step. To make the first exposure dose lower than the second exposure dose, it is effective to conduct the first heating step at a higher temperature than in the second heating step.

In a practical lithography process, the threshold (a) in positive-tone development is as follows.

On a substrate, a film is formed with a resist composition which shows an increase in the solubility in a positive-tone developer and a decrease in the solubility in a negative-tone developer upon irradiation with an actinic ray or radiation. Next, the film is exposed under desired illumination conditions via a photo-mask having a desired pattern size. In this step, the exposure is conducted while altering the exposure focus at intervals of 0.05 [μm] and the exposure dose at intervals of 0.5 [mJ/cm²]. After the exposure, the film is heated at a desired temperature for a desired period of time and developed with an alkali developer having a desired concentration for a desired period of time. After the development, the pattern line width is measured by using a CD-SEM so that the exposure dose A [mJ/cm²] and the focal position at which a desired line width is formed are determined. Subsequently, the film is irradiated at a specific exposure dose A [mJ/cm²] and a specific focal position via the above-described photo-mask and the intensity distribution of the optical image is computed. The computation can be made by using simulation software (Prolith ver. 9. 2. 0. 15 manufactured by KLA). A detailed computation method is described in Inside PROLITH (Edited by Chris. A. Mack, FINLE Technologies, Inc. Chapter 2 Aerial Image Formation).

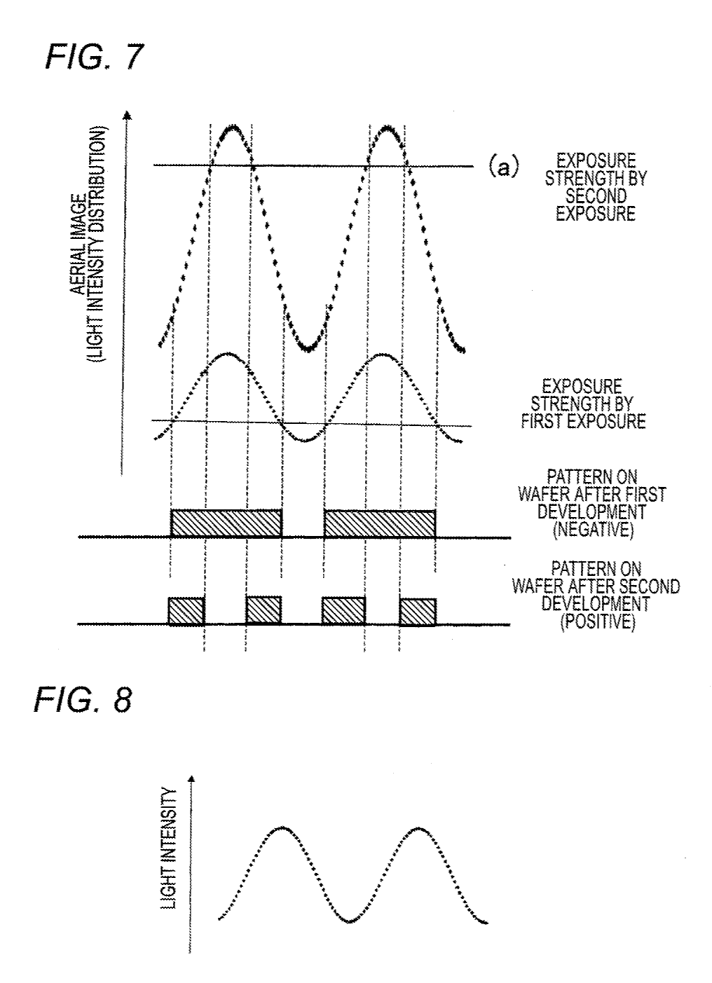

As an example of the computed data, the aerial intensity distribution of an optical image as shown in FIG. 8 can be obtained.

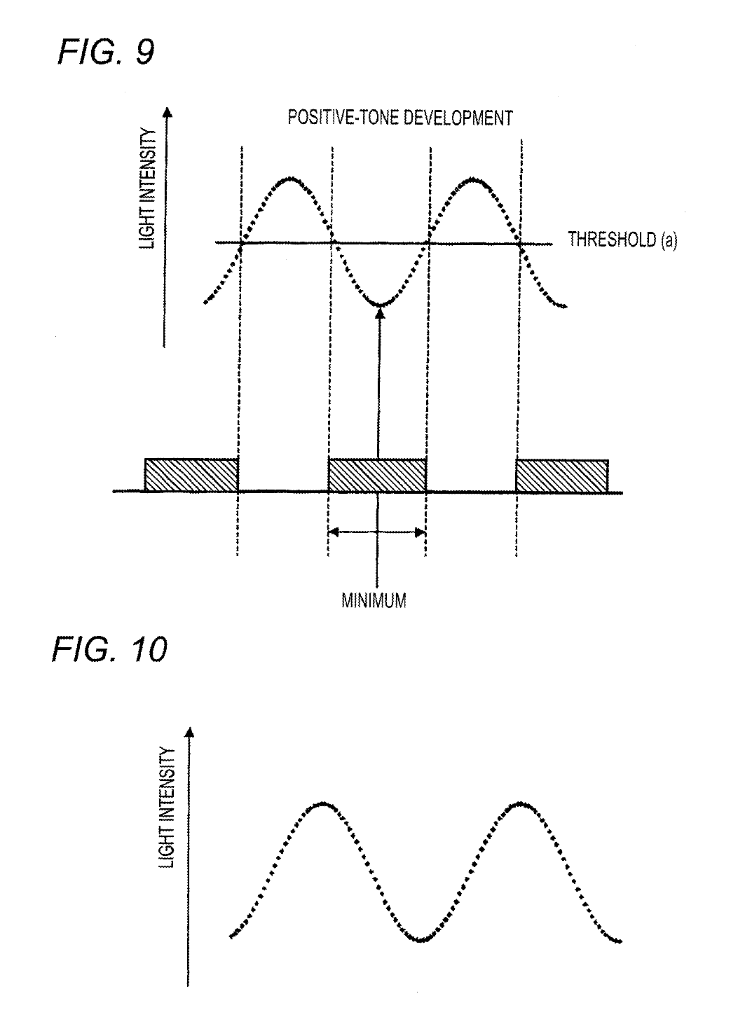

Here, as shown in FIG. 9, the light intensity at the position determined by shifting the aerial position from the minimum of the aerial intensity distribution of the optical image by a half of the obtained pattern line width corresponds to the threshold (a).

In a practical lithography process, the threshold (b) in negative-tone development is as follows.

On a substrate, a film is formed with a resist composition containing a resin capable of increasing the polarity by the action of an acid and showing an increase in the solubility in a positive-tone developer and a decrease in the solubility in a negative-tone developer upon irradiation with an actinic ray or radiation. Next, the film is exposed under desired illumination conditions via a photo-mask having a desired pattern size. In this step, the exposure is conducted while altering the exposure focus at intervals of 0.05 [μm] and the exposure dose at intervals of 0.5 [mJ/cm²]. After the exposure, the film is heated at a desired temperature for a desired period of time and developed with an alkali developer having a desired concentration for a desired period of time. After the development, the pattern line width is measured by using a CD-SEM so that the exposure dose A [mJ/cm²] and focal position at which a desired line width is formed are determined. Subsequently, the film is irradiated at a specific exposure dose A [mJ/cm²] and a specific focal position via the above-described photo-mask and the intensity distribution of the optical image is computed. The computation can be made by using simulation software (Prolith manufactured by KLA).

For example, the aerial intensity distribution of an optical image as shown in FIG. 10 can be obtained.

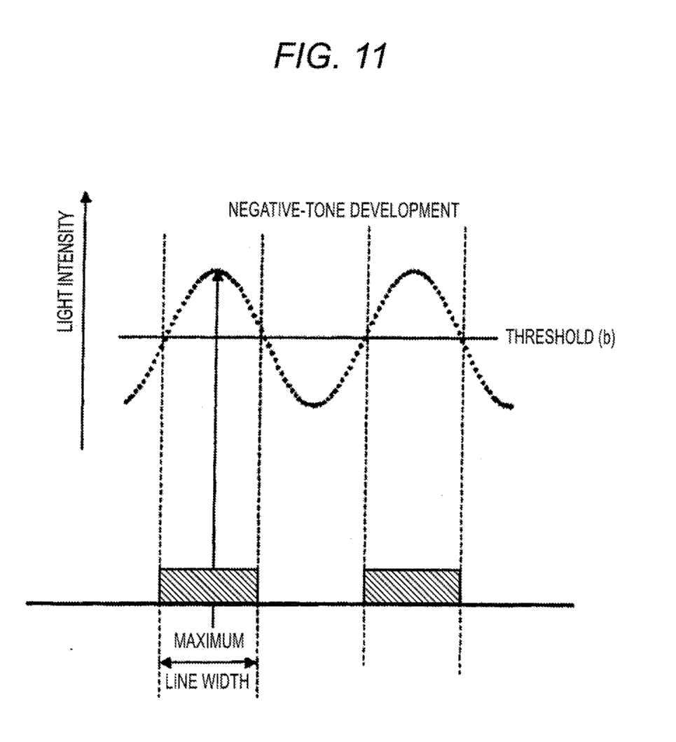

Here, as shown in FIG. 11, the light intensity at the position determined by shifting the aerial position from the maximum of the aerial intensity distribution of the optical image by a half of the obtained pattern line width corresponds to the threshold (b).

The threshold (a) is preferably from 0.1 to 100 [mJ/cm²], more preferably from 0.5 to 50 [mJ/cm²], and still more preferably from 1 to 30 [mJ/cm²]. The threshold (b) is preferably from 0.1 to 100 [mJ/cm²], more preferably from 0.5 to 50 [mJ/cm²], and still more preferably from 1 to 30 [mJ/cm²]. The difference between the threshold (a) and the threshold (b) is preferably from 0.1 to 80 [mJ/cm²], more preferably from 0.5 to 50 [mJ/cm²], and still more preferably from 1 to 30 [mJ/cm²].

In the present invention, the film formed on the substrate is a film which is formed with a resist composition for negative-tone development, which contains (A) a resin having an acid-decomposable repeating unit represented by following general formula (1) (which will be described in detail later) and being capable of decreasing the solubility in a negative developer by the action of an acid.

Next, the resist composition which can be used in the present invention will be described.

(A) Resin Having an Acid-Decomposable Repeating Unit Represented by Following General Formula (1) and being Capable of Decreasing the Solubility in a Negative Developer by the Action of an Acid

The resin capable of decreasing the solubility in a negative developer by the action of an acid, which is used in the resist composition of the present invention, has an acid-decomposable repeating unit represented by following general formula (1). Further, this resin is also a resin capable of increasing the polarity and increasing the solubility in a positive-tone developer by the action of an acid.

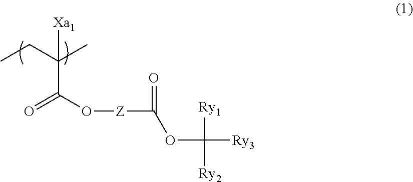

In the general formula (1),

Xa₁ represents a hydrogen atom, an alkyl group, a cyano group, or a halogen atom.

Each of Ry₁ to Ry₃ independently represents an alkyl group or a cycloalkyl group, or at least two of Ry₁ to Ry₃ may be bonded to each other to form a ring structure.

Z represents a divalent linking group.

In the general formula (1), the alkyl group of Xa₁ may be substituted with a hydroxyl group, a halogen atom, or the like.

Xa₁ is preferably a hydrogen atom or a methyl group.

The alkyl group of Ry₁ to Ry₃ may be any one of a linear alkyl group and a branched alkyl group, and may also have a substituent. A preferable linear or branched alkyl group has 1 to 8 carbon atoms, and more preferably 1 to 4 carbon atoms. Examples thereof include a methyl group, an ethyl group, a propyl group, an isopropyl group, a butyl group, an isobutyl group, and a t-butyl group, and preferably a methyl group and an ethyl group.

Examples of the cycloalkyl group of Ry₁ to Ry₃ include a monocyclic cycloalkyl group having 3 to 8 carbon atoms and a polycyclic cycloalkyl group having 7 to 14 carbon atoms, and may also have a substituent. Examples of the preferable monocyclic cycloalkyl group include a cyclopentyl group, a cyclohexyl group, and a cyclopropyl group. Examples of the preferable polycyclic cycloalkyl group include an adamantyl group, a norborane group, a tetracyclododecanyl group, a tricyclodecanyl group, and a diamantyl group.

Examples of the substituent which the alkyl group and the cycloalkyl group of Ry₁ to Ry₃ may contain include a halogen atom, a hydroxyl group, an alkoxy group, a carboxylic group, an alkoxycarbonyl group, and the like. Specific examples of the alkoxy in the alkoxy group and the alkoxycarbonyl group include ones having 1 to 4 carbon atoms, such as a methoxy group, an ethoxy group, a propoxy group, a butoxy group, and the like.

As the monocyclic hydrocarbon structure formed by at least two of Ry₁ to Ry₃ bonded to each other, a cyclopentyl group and a cyclohexyl group are preferable. As the polycyclic hydrocarbon structure formed by at least two of Ry₁ to Ry₃ bonded to each other, an adamantyl group, a norbornyl group, and a tetracyclododecanyl group are preferable. The monocyclic hydrocarbon structure is preferably a 6 or more-membered ring is particularly preferable, which allows the solubility of the resist film in a negative-tone developer (an organic-based developer containing an organic solvent) to be sufficient, and therefore, the unexposed part can be more clearly removed by the negative-tone developer. Since this allows the development pattern to be preciser as desired, superior effects in terms of all of line width roughness (LWR), exposure latitude (EL), and depth of focus (DOF) can be attained.

Z is preferably a divalent linking group having 1 to 20 carbon atoms, and more preferably a chained alkylene group having 1 to 4 carbon atoms and a cyclic alkylene group having 5 to 20 carbon atoms, or a combination thereof.

Examples of the chained alkylene group having 1 to 4 carbon atoms include a methylene group, an ethylene group, a propylene group, and a butylene group, which may be linear or branched. A methylene group is preferred.

Examples of the cyclic alkylene group having 5 to 20 carbon atoms include monocyclic cyclic alkylene groups such as a cyclopentylene group, a cyclohexylene group, and the like, polycyclic cyclic alkylene groups such as a norbornylene group, an adamantylene group, and the like. An adamantylene group is preferred.

The repeating unit represented by the general formula (1) is preferably an acid-decomposable repeating unit represented by the following general formula (2a) or (2b).

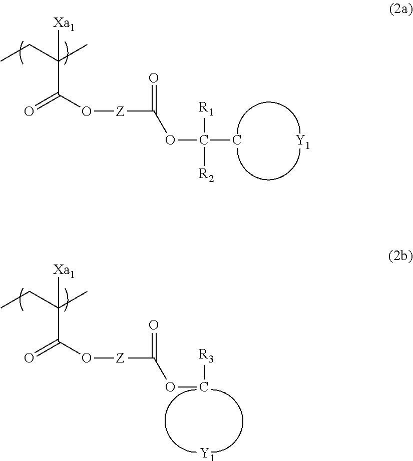

In the general formula (2a) or (2b),

Xa₁ and Z are respectively the same as Xa₁ and Z in the general formula (1).

Y₁ represents a plurality of atoms necessary to complete an alicyclic hydrocarbon group together with the carbon atom as shown.

Y₂ represents a plurality of atoms necessary to complete an alicyclic hydrocarbon group together with the carbon atom as shown.

Each of R₁, R₂, and R₃ independently represents an alkyl group or a cycloalkyl group.

Specific examples and preferable examples of Xa₁ and Z include those which are the same as cited above with respect to Xa₁ and Z in the general formula (1).

Specific examples and preferable examples of the alkyl group and the cycloalkyl group as R₁, R₂, and R₃ include those which are the same as the alkyl group and the cycloalkyl group cited above as Ry₁ to Ry₃ of the general formula (1). The alkyl group and the cycloalkyl group as R₁, R₂, and R₃ may have a substituent, and specific examples of the substituent include those which are the same as the alkyl group and the cycloalkyl group cited above as the substituents which the alkyl group and the cycloalkyl group of Ry₁ to Ry₃ of the general formula (1) may contain.

The alicyclic hydrocarbon group formed by Y₁ or Y₂, and a carbon atom may be monocyclic or polycyclic, and specific examples thereof include groups having a monocyclo-, bicyclo-, tricyclo-, tetracyclo-structure, and the like, having 5 or more carbon atoms. The group preferably has 6 to 30 carbon atoms, and particularly preferably 7 to 25 carbon atoms. These alicyclic hydrocarbon groups may have a substituent.

It is preferable that in the case where the total number of carbon atoms of Y₁, R₁, and R₂ in the general formula (2a) is 6 or less, and in the case where the total number of carbon atoms of Y₂ and R₃ in the general formula (2b) is 6 or less, the resin A does not contain a repeating unit derived from an acrylic acid or an acrylic ester. In other words, in those cases, it is preferable that, with respect to all repeating units derived from an acrylic acid or an acrylic ester in the resin A (including the acid-decomposable repeating unit represented by the general formula (2a) or (2b)), a carbon atom at the α-position in the repeating units (a carbon atom constituting a main chain of the resin and bonding to a —C(═O)— group) is substituted with a substituent other than a hydrogen atom via a bonding moiety not constituting the main chain of the resin and not bonding to the —C(═O)— group. Further, examples of the substituent include an alkyl group, a cyano group, or a halogen atom, as for the Xa of the general formula (1). Specific examples and preferable examples of the alkyl group include the same as described for the alkyl group of Ry₁ to Ryₐ in the general formula (1).

Here, in the resin A, it is particularly preferable that, with respect to all repeating units derived from an acrylic acid or an acrylic ester in the resin A, the carbon atom at the α-position in the repeating units is substituted with a methyl group. In other words, in the resin A, it is particularly preferable that all of the repeating units derived from the ethylenically unsaturated monomers contained in the resin A are the repeating units derived from methacrylic acid or methacrylic ester.

In the case where the total number of carbon atoms of Y₁, R₁, and R₂ in the general formula (2a) is 6 or less and in the case where the total number of carbon atoms of Y₂ and R₃ in the general formula (2b) is 6 or less, when the resin A has the embodiment as described above, the solubility of the resist film in the negative-tone developer (an organic-based developer containing an organic solvent) can be sufficient, and thus, the unexposed part can be clearly removed by the negative-tone developer. Since this allows the development pattern to be preciser as desired, superior effects in terms of all of line width roughness (LWR), exposure latitude (EL), and depth of focus (DOF) can be attained.

The total number of carbon atoms of Y₁, R₁, and R₂ is preferably 35 or less, and the total number of Y₂ and R₃ is preferably 35 or less.

Next, among the alicyclic hydrocarbon groups, structural examples of the alicyclic moiety will be described.

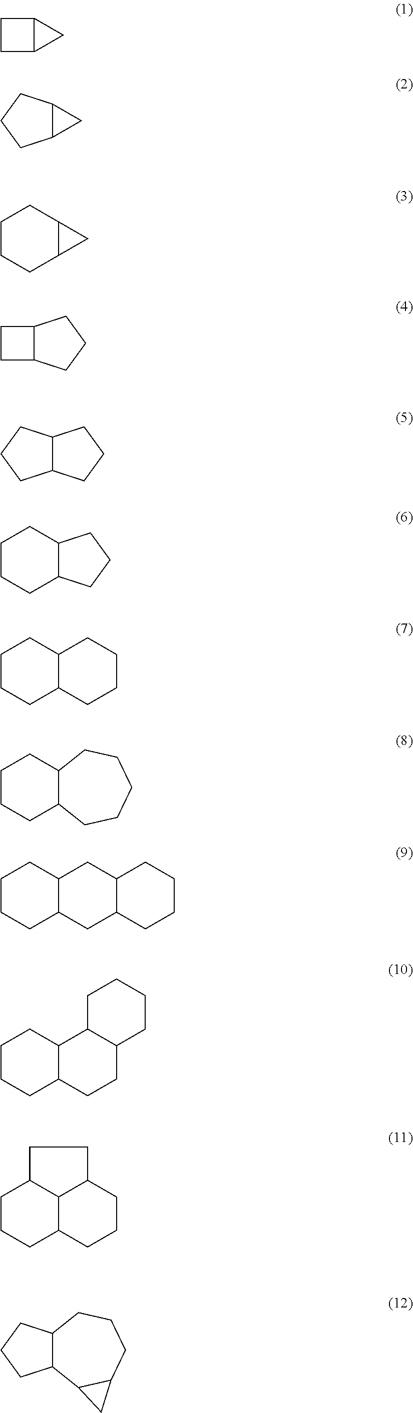

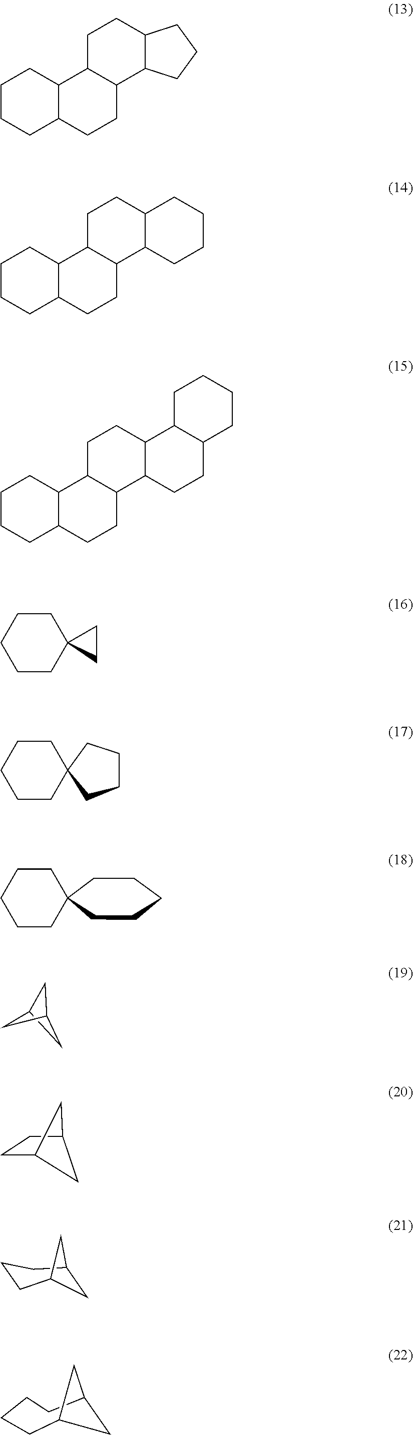

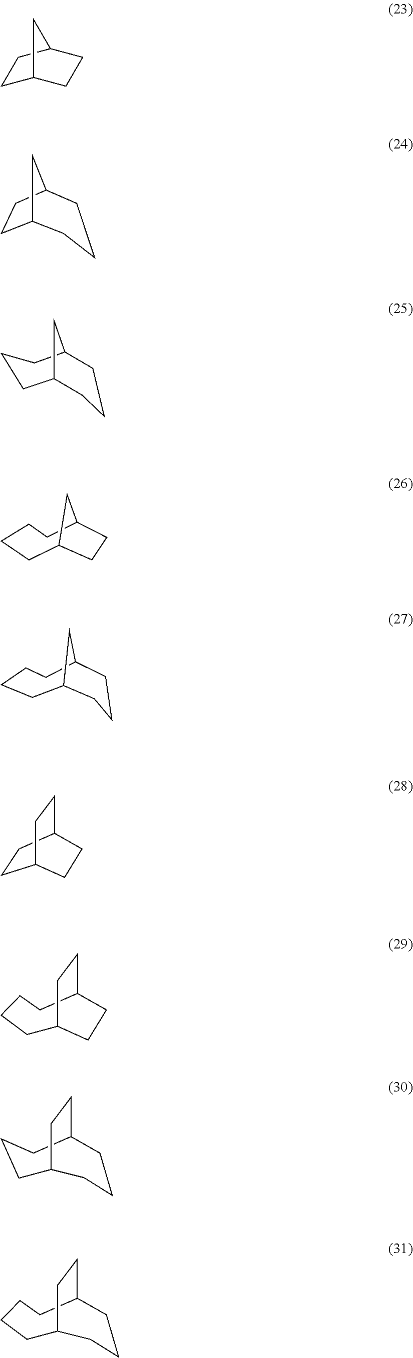

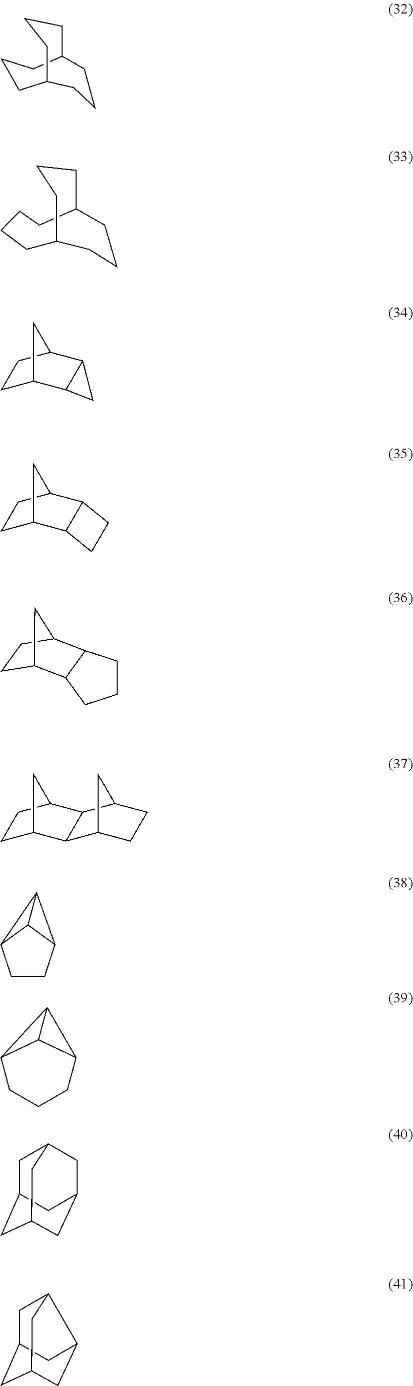

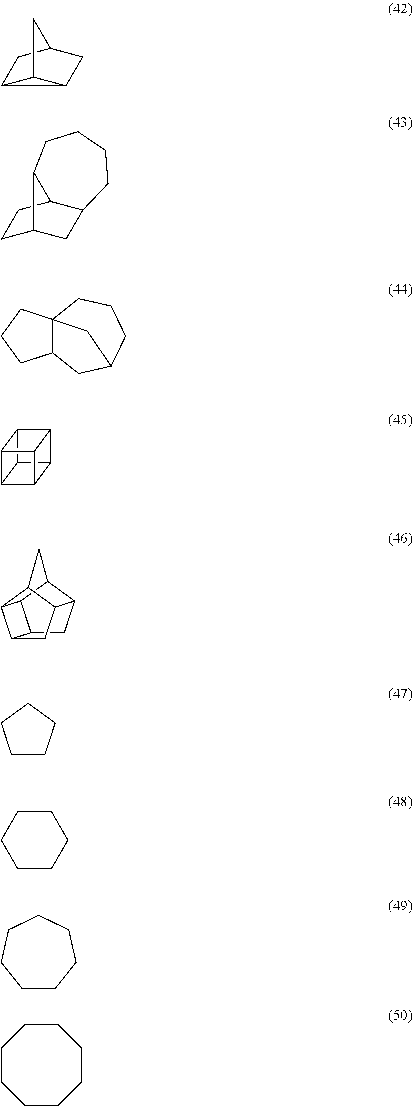

In the present invention, preferable examples of the alicyclic moiety include an adamantyl group, a noradamantyl group, a decaline residue, a tricyclodecanyl group, a tetracyclododecanyl group, a norbornyl group, a cedrol group, a cyclohexyl group, a cycloheptyl group, a cyclooctyl group, a cyclodecanyl group, and a cyclododecanyl group. More preferable examples thereof include an adamantyl group, a decaline residue, a norbornyl group, a cedrol group, a cyclohexyl group, a cycloheptyl group, a cyclooctyl group, a cyclodecanyl group, and a cyclododecanyl group.

Examples of the substituent of the alicyclic hydrocarbon group include an alkyl group, a substituted alkyl group, a halogen atom, a hydroxyl group, an alkoxy group, a carboxylic group, and an alkoxycarbonyl group. Preferable examples of the alkyl group include lower alkyl groups such as a methyl group, an ethyl group, a propyl group, an isopropyl group, a butyl group, and the like, and more preferably, it represents a substituent selected from the group consisting of a methyl group, an ethyl group, a propyl group, and an isopropyl group. Examples of the substituent of the substituted alkyl group include a hydroxyl group, a halogen atom, and an alkoxy group. Examples of the alkoxy group include the alkoxy group having 1 to 4 carbon atoms, such as a methoxy group, an ethoxy group, a propoxy group, a butoxy group, and the like.

The polymerizable compound for forming the repeating unit represented by the general formula (1) can be easily synthesized by a conventional method. See, for example, Synthesis Examples and the like below the paragraph [0108] of JP-A-2005-331918.

Next, preferred specific examples of the repeating unit represented by the general formula (1) will be presented, but the present invention is not limited thereto. Further, Xa₁ is the same as defined in the general formula (1).

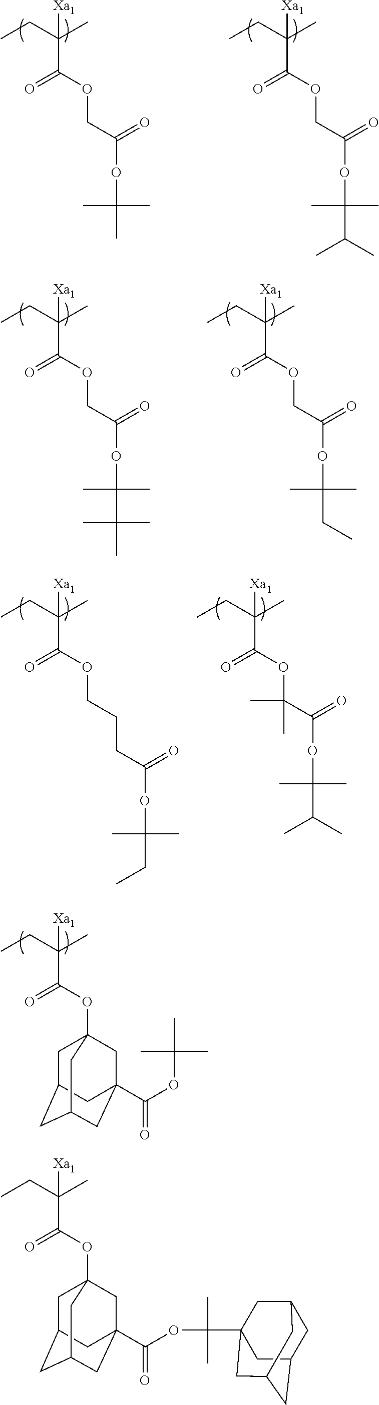

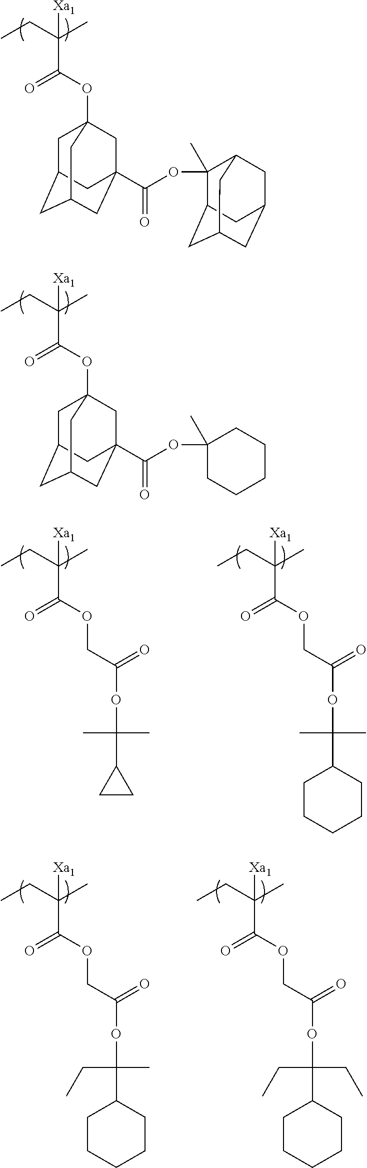

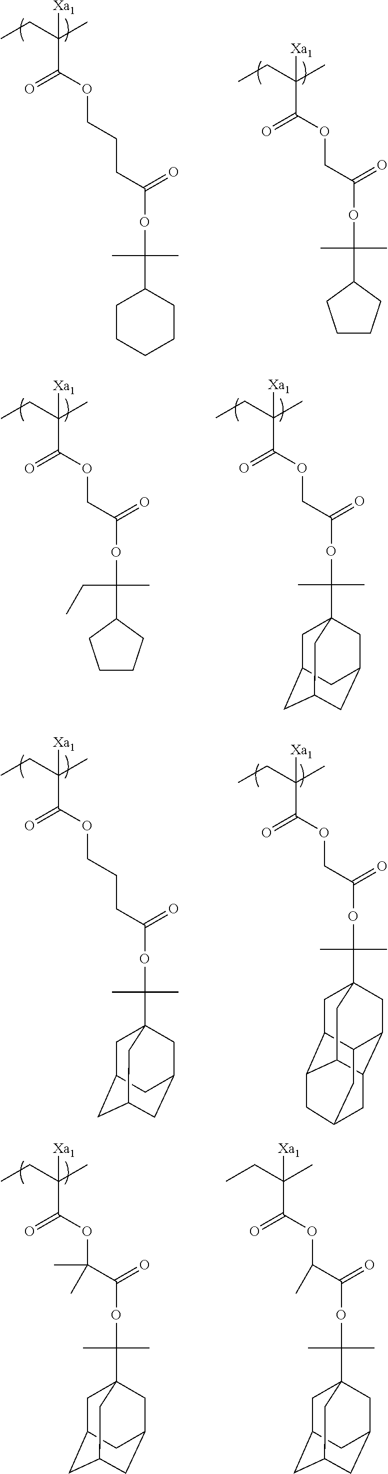

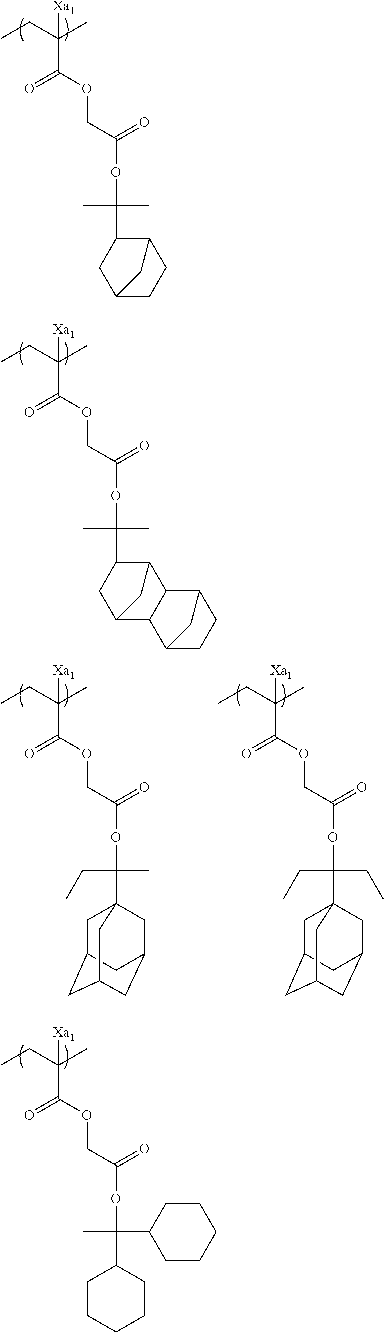

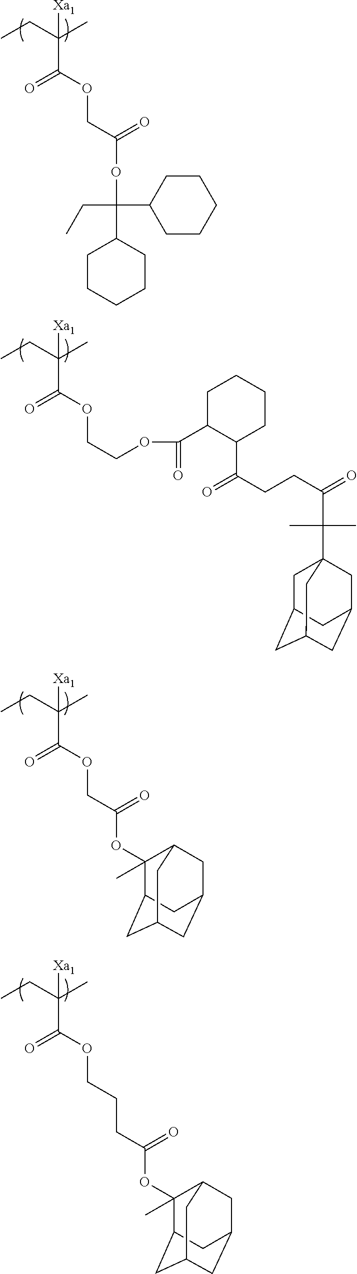

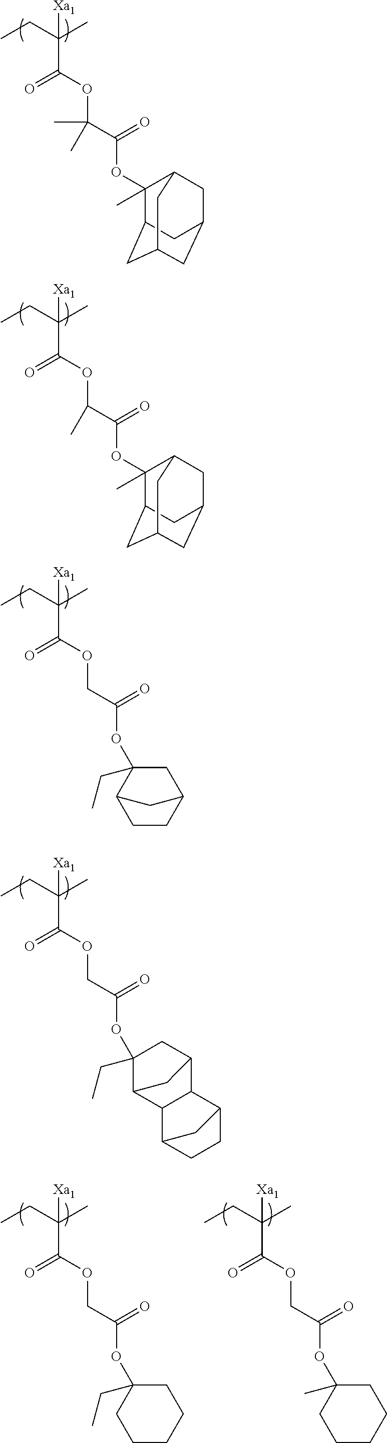

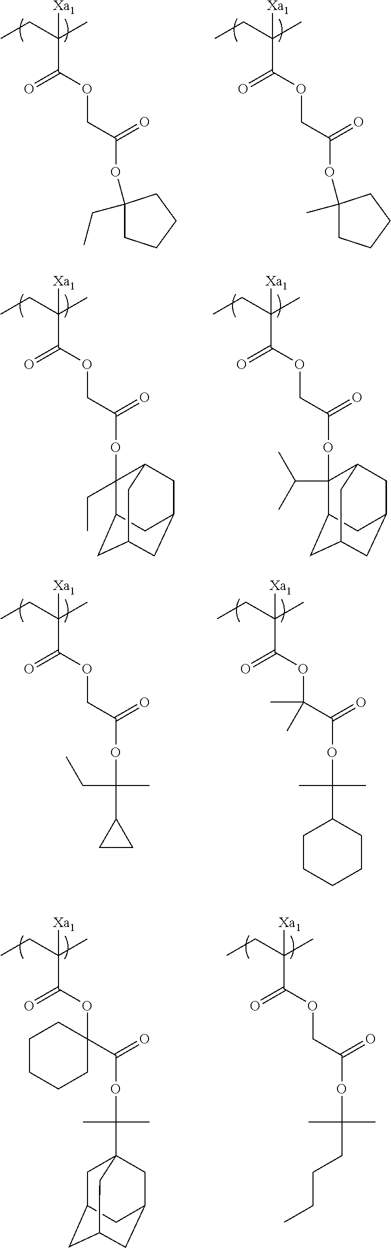

The content of the repeating unit represented by the general formula (1) is preferably from 10 to 60% by mol, and most preferably from 20 to 50% by mol, based on all of the repeating units in the resin.

The repeating unit represented by the general formula (1) is decomposed by the action of an acid to generate a carboxylic group, and shows a decrease in the solubility in a negative developer. Further, the repeating unit represented by the general formula (1) is decomposed by the action of an acid, and increases the dissolution rate in the alkali developer.

The resin of Component (A) may further contain other acid-decomposable repeating units, in addition to the acid-decomposable repeating unit represented by following general formula (1).

The other acid-decomposable repeating units, in addition to the acid-decomposable repeating unit represented by following general formula (1) are preferably the repeating units represented by the following general formula (2).

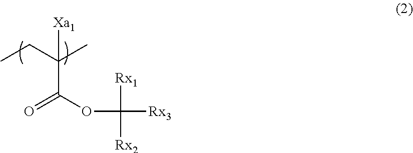

In the general formula (2),

Xa₁ represents a hydrogen atom, an alkyl group, a cyano group, or a halogen atom, and is the same as defined in Xa₁ of the general formula (1).

Each of Rx₁ to Rx₃ independently represents an alkyl group or a cycloalkyl group, or at least two of Rx₁ to Rx₃ may be bonded to each other to form a cycloalkyl group.

As the alkyl group of Rx₁ to Rx₃, alkyl groups having 1 to 4 carbon atoms, such as a methyl group, an ethyl group, an n-propyl group, an isopropyl group, an n-butyl group, an isobutyl group, a t-butyl group, and the like are preferred.

As the cycloalkyl group of Rx₁ to Rx₃, monocyclic cycloalkyl groups such as such as a cyclopentyl group, a cyclohexyl group, and the like, and polycyclic cycloalkyl groups such as a norbornyl group, a tetracyclodecanyl group, a tetracyclododecanyl group, an adamantyl group, and the like are preferred.

As the cycloalkyl group formed by at least two of Rx₁ to Rx₃ bonded to each other, monocyclic cycloalkyl groups such as a cyclopentyl group, a cyclohexyl group, and the like, and polycyclic cycloalkyl groups such as norbornyl group, tetracyclodecanyl group, tetracyclododecanyl group, adamantyl group, and the like are preferred.

An embodiment in which Rx₁ is a methyl group or an ethyl group, and Rx₂ and Rx₃ are bonded to each other to form the monocyclic or polycyclic cycloalkyl group as described above is preferred.

Next, specific examples of the repeating unit which has the preferable acid-decomposable group contains will be presented, but the present invention is not limited thereto.

(In the formulae, Rₓ represents H, CH₃, CF₃ or CH₂OH, and each of Rₓₐ and R_{xb} represents an alkyl group having from 1 to 4 carbon atoms.)

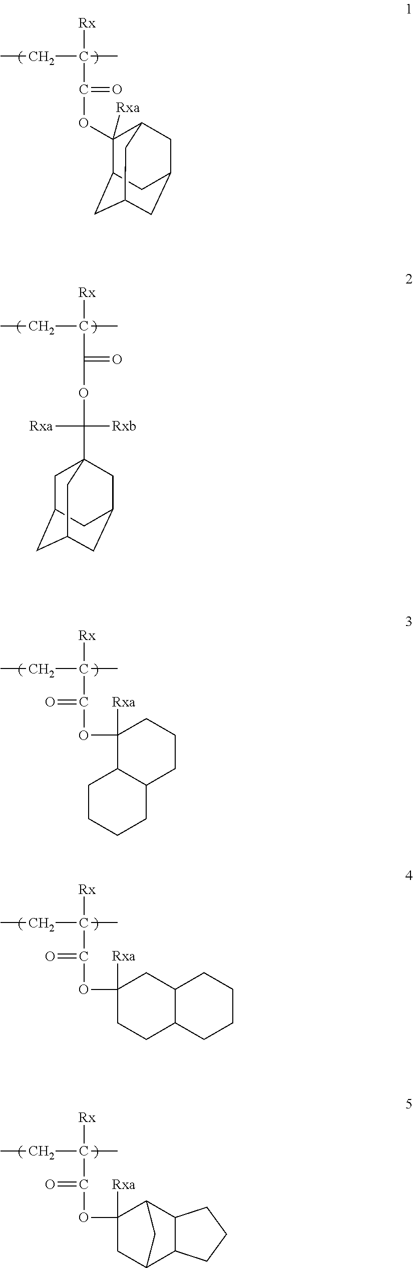

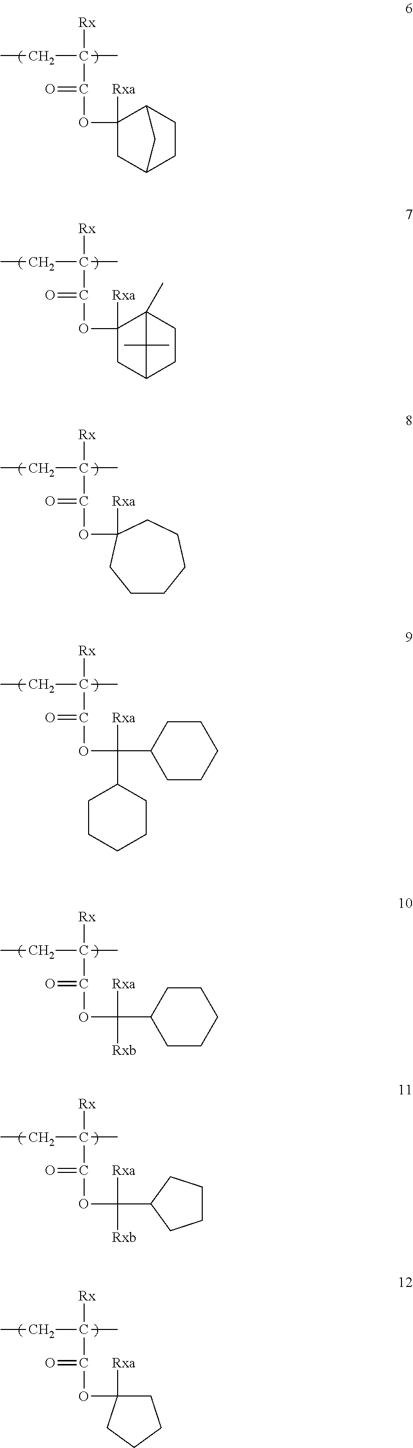

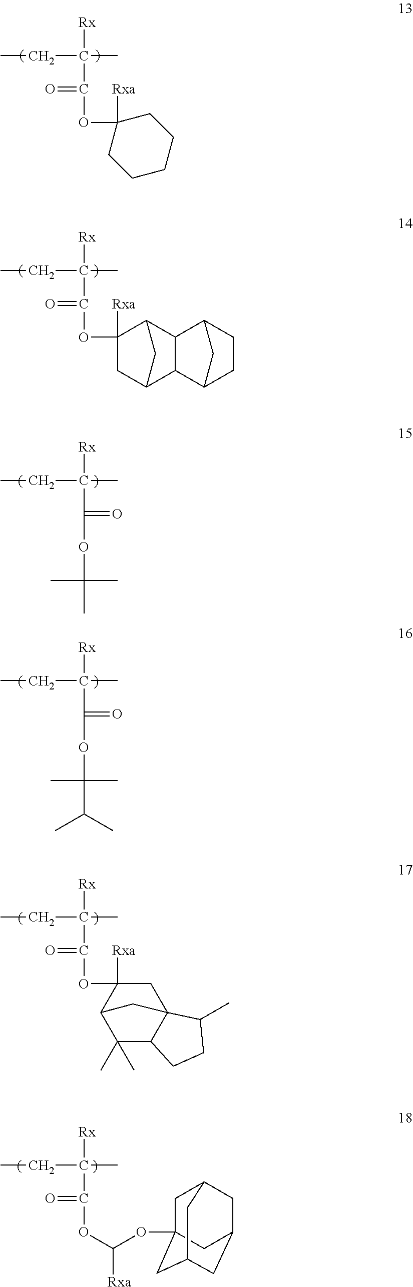

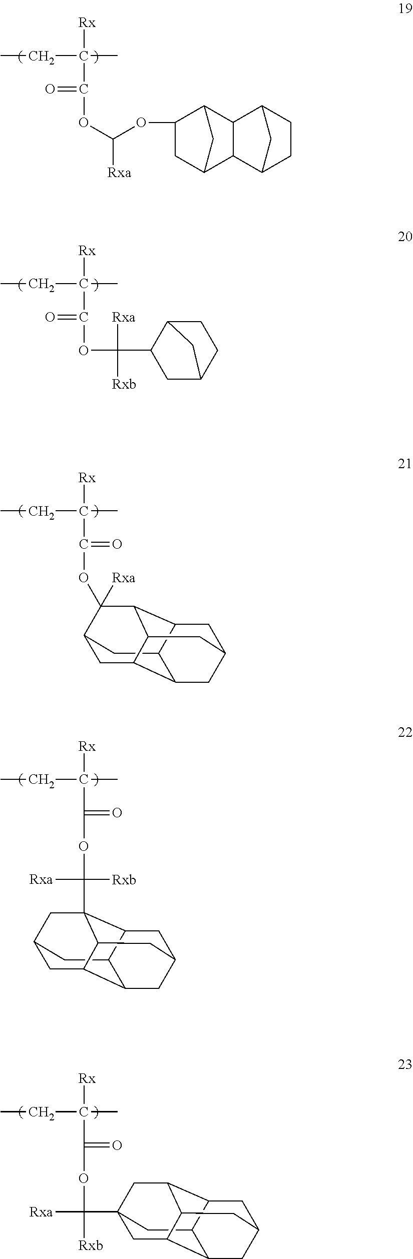

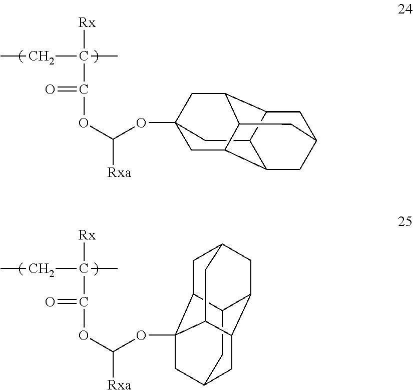

The preferable repeating units represented by the general formula (2) are Repeating units 1, 2, 10, 11, 12, 13, and 14 in the specific examples as above.

In the case where the acid-decomposable group-containing the repeating unit represented by the general formula (I), is used in combination with another acid-decomposable group-containing repeating unit (preferably, the repeating unit represented by the general formula (II)), a molar ratio of the acid-decomposable group-containing repeating unit represented by the formula (I) to the another acid-decomposable-group-containing repeating unit is from 90:10 to 10:90, and more preferably from 80:20 to 20:80.

The content of all of the acid-decomposable group-containing repeating units in the resin of Component (A) is preferably from 5 to 70% by mol, and more preferably from 10 to 60% by mol, based on all of the repeating units in the resin.

The resin of Component (A) further preferably has a repeating unit having at least one selected from a lactone group, a hydroxyl group, a cyano group, and an alkali-soluble group.

The resin of Component (A) preferably has a repeating unit having a lactone structure. Although the lactone structure is not limited at all, a 5- to 7-membered ring lactone structure is preferred, with a 5- to 7-membered ring lactone structure cyclocondensed with another cyclic structure to form a bicyclostructure or spirostructure is preferred. The resin having a repeating unit having a lactone structure represented by any one of the following general formulae (LC1-1) to (LC1-17) is more preferred. The lactone structure may be bonded directly to the main chain. Preferred lactone structures include (LC1-1), (LC1-4), (LC1-5), (LC1-6), (LC1-13), (LC1-14), and (LC1-17). Use of a specific lactone structure reduces line edge roughness and development defects.

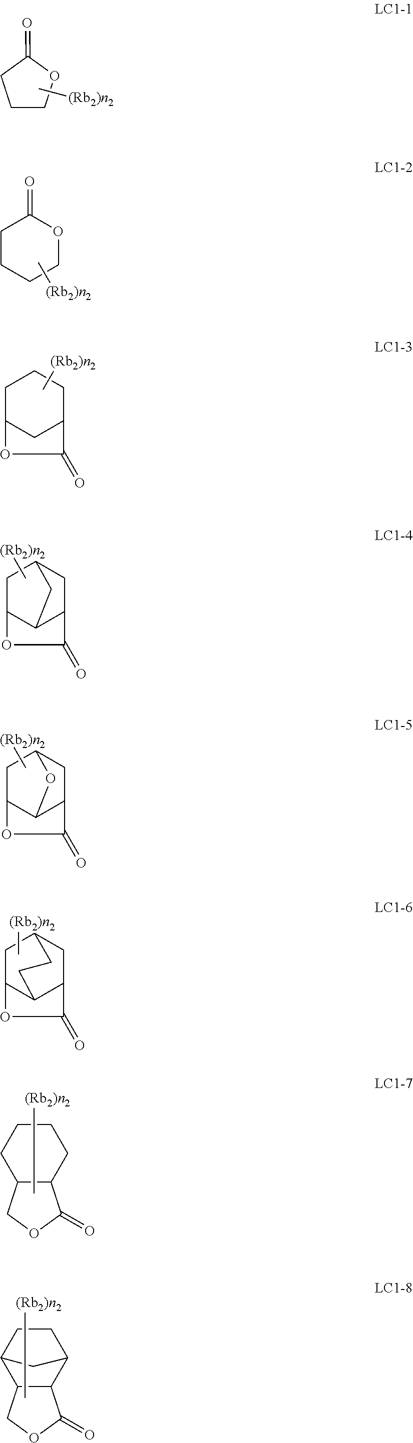

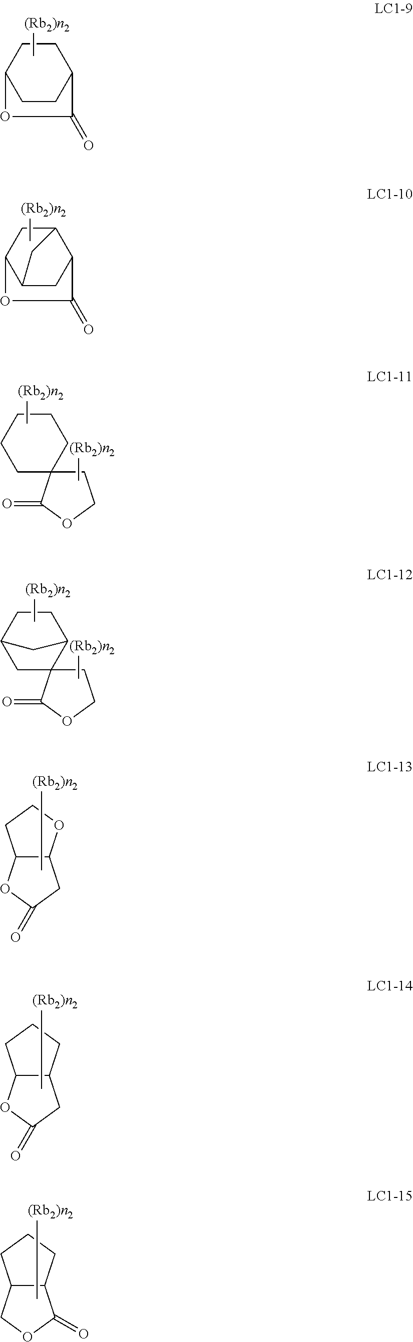

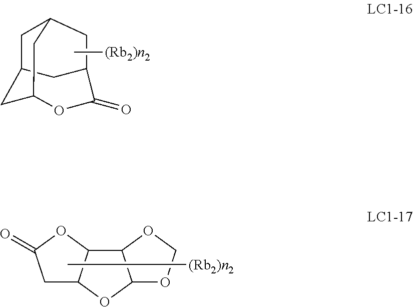

The lactone structure portion may have a substituent (Rb₂) or may have no substituent. Preferable examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, an acid-decomposable group, and the like. More preferable examples thereof include an alkyl group having 1 to 4 carbon atoms, a cyano group, and an acid-decomposable group. Most preferable substituent is a cyano group, whereby superior effects in terms of all of line width roughness (LWR), exposure latitude (EL), and depth of focus (DOF) can be obtained. n2 stands for an integer of 0 to 4. When n2 is 2 or more, Rb₂'s which are present in a plurality may be the same or different, or the Rb₂'s which are present in a plurality may be bonded to each other to form a ring.

Examples of the repeating unit having a lactone structure represented by any one of the general formulae (LC1-1) to (LC1-17) include repeating units represented by the following general formula (AI).

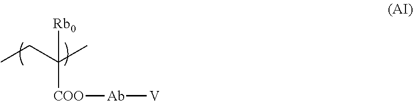

In the general formula (AI), Rbₒ represents a hydrogen atom, a halogen atom, or an alkyl group having 1 to 4 carbon atoms. Examples of the preferable substituent which the alkyl group of Rbₒ may have include a hydroxyl group and a halogen atom. Examples of the halogen atom of Rbₒ include a fluorine atom, a chlorine atom, a bromine atom, and an iodine atom. Rbₒ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent linking group containing a combination thereof. It is preferably a single bond or a divalent linking group represented by -Ab₁-CO₂—. Ab₁- is a linear or branched alkylene group, or a monocyclic or polycyclic cycloalkylene group, and preferably a methylene group, an ethylene group, a cyclohexylene group, an adamantylene group, or a norbornylene group.

V represents a group having a structure represented by any one of the general formulae (LC-1) to (LC-17).

The repeating unit having a lactone structure typically exists in the form of optical isomers, but any of these optical isomers may be used. The optical isomers may be used either singly or in combination of two or more kinds thereof. When one optical isomer is mainly used, it preferably has an optical impurity (ee) of 90 or more, and more preferably 95 or more.

The content of the repeating unit having a lactone structure is preferably from 15 to 60% by mol, more preferably from 20 to 50% by mol, and still more preferably from 30 to 50% by mol, based on all of the repeating units in the polymer.

Next, specific examples of the repeating unit having a lactone structure will be presented, but the present invention is not limited thereto. In the specific examples, Rx represents H, CH₃, CH₂OH, or CF₃.

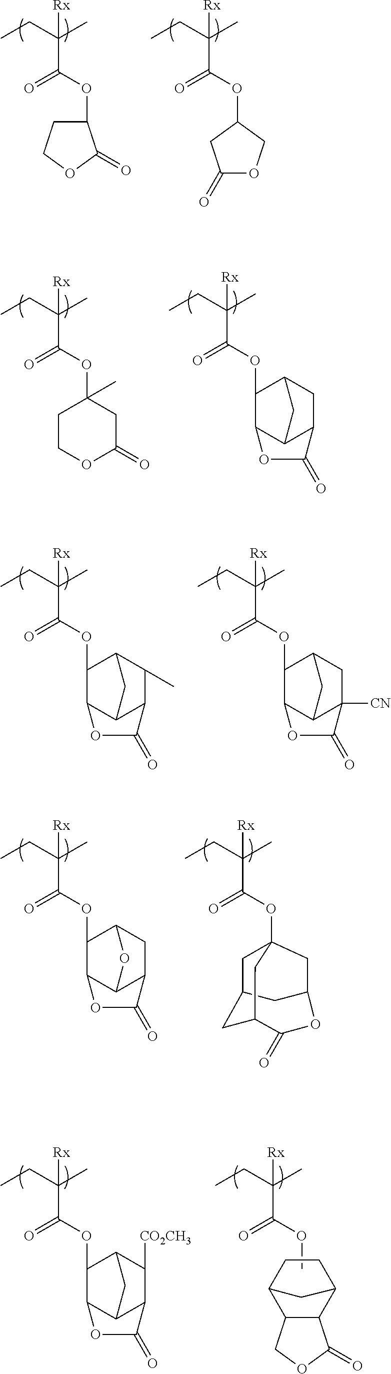

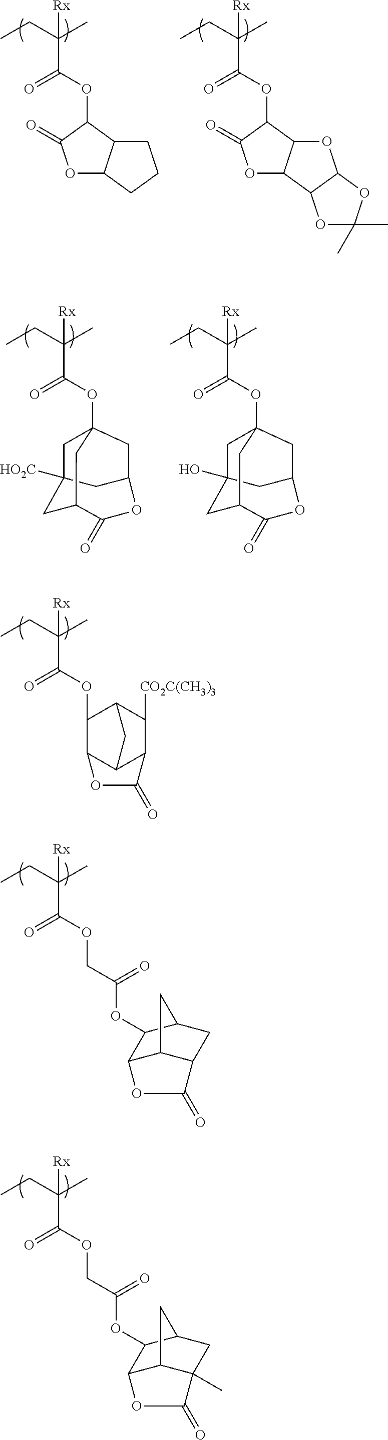

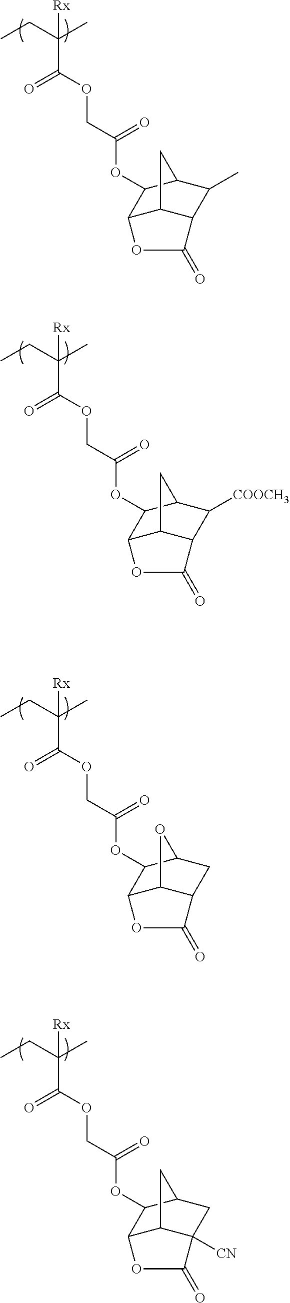

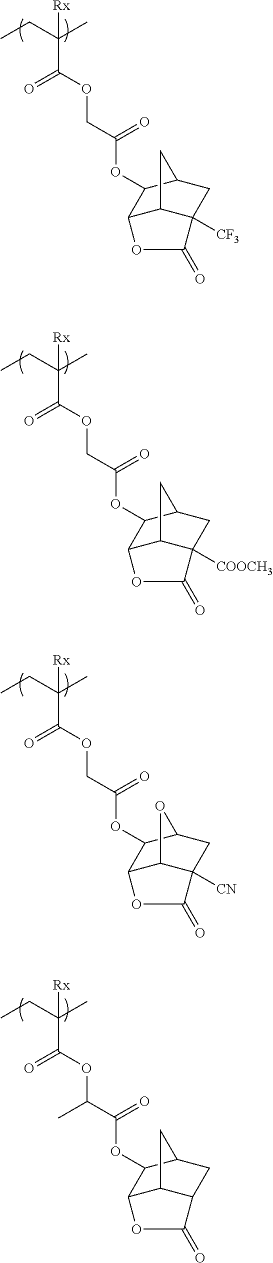

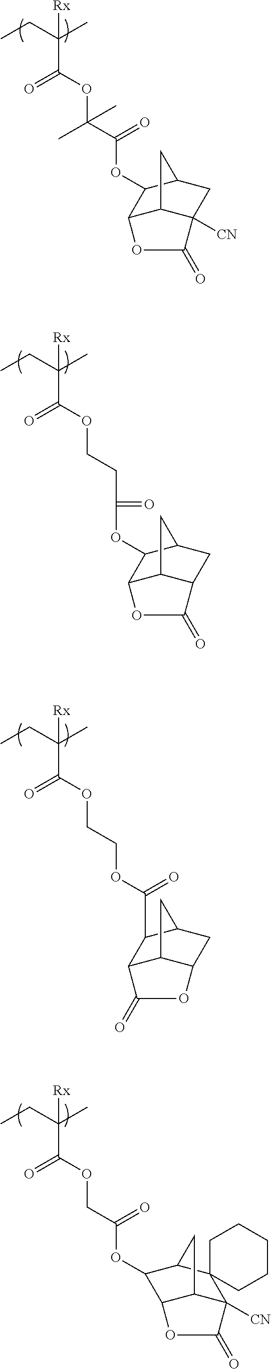

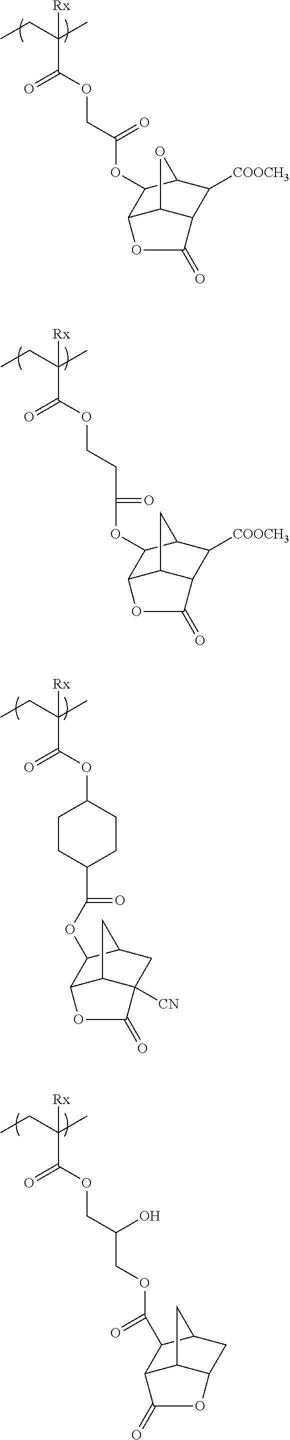

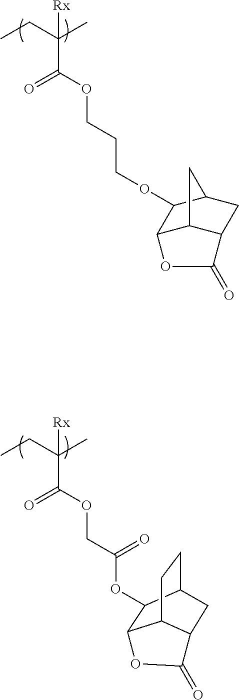

The resin of Component (A) preferably has a repeating unit having a hydroxyl group or a cyano group, which improves the adhesion to a substrate and the affinity for the developer is improved. The repeating unit having a hydroxyl group or a cyano group is preferably a repeating unit having an alicyclic hydrocarbon structure substituted with a hydroxyl group or a cyano group. Examples of the structure include the repeating units represented by the following general formulae (AIIa) to (AIId).

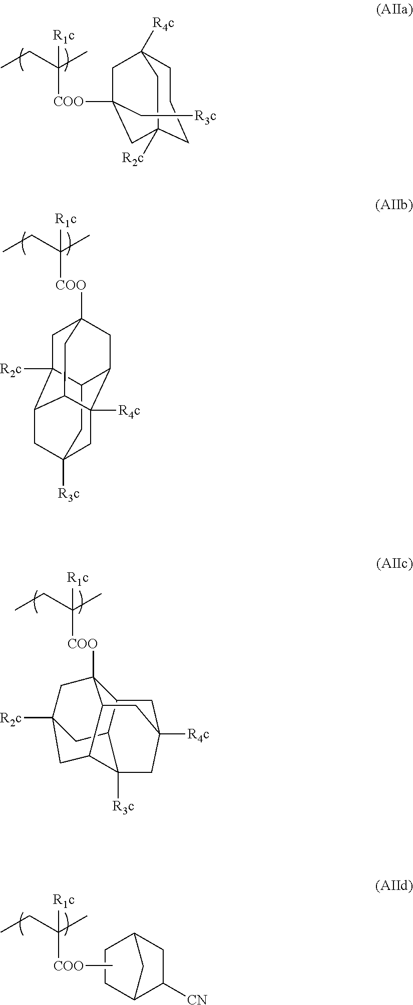

In the general formulae (AIIa) to (AIIb),

R₁c represents a hydrogen atom, a methyl group, a trifluoromethyl group, or a hydroxymethyl group.

Each of R₂c to R₄c independently represents a hydrogen atom, a hydroxyl group, or a cyano group. However, at least one of R₂c to R₄c represents a hydroxyl group or a cyano group. Preferably, one or two of R₂c to R₄c are hydroxyl groups, and the remainder(s) is a hydrogen atom.

The content of the repeating unit having the alicyclic hydrocarbon structure substituted with a hydroxyl group or a cyano group having is preferably from 5 to 40% by mol, more preferably from 5 to 30% by mol, and still more preferably from 10 to 25% by mol, based on all of the repeating units in the polymer.

Next, specific examples of the repeating unit having a hydroxyl group or a cyano group will be presented, but the present invention is not limited thereto.

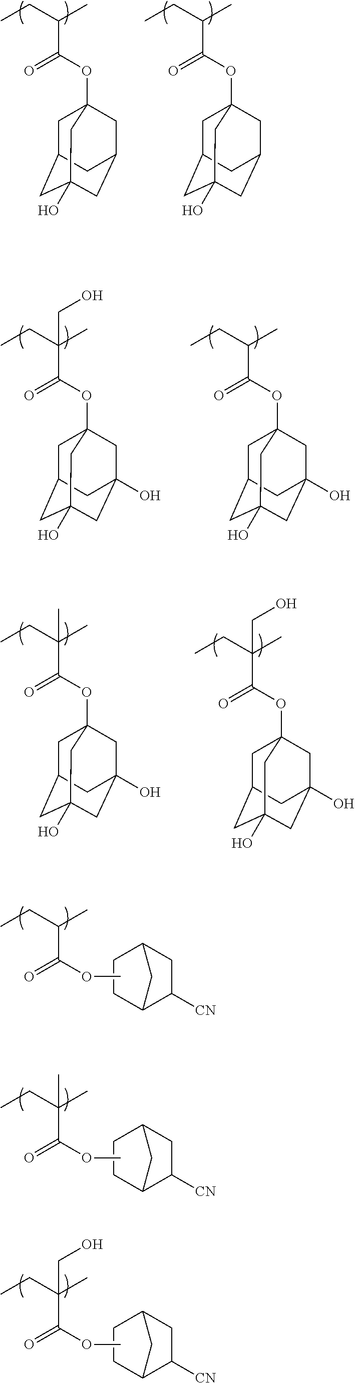

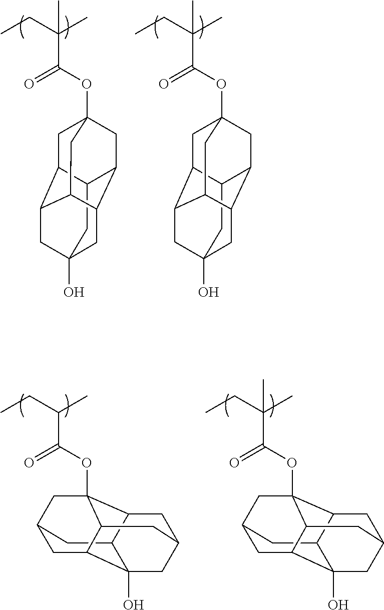

The resin of Component (A) preferably has a repeating unit having an alkali-soluble group. Examples of the alkali-soluble group include a carboxyl group, a sulfonamide group, a sulfonylimide group, a bissulfonylimide group, and an aliphatic alcohols (for example, a hexafluoroisopropanol group) substituted, at the α-position thereof, an electron withdrawing group. The resin having a carboxyl-containing repeating unit is more preferred. When the resin has the repeating unit having an alkali-soluble group, resolution at the time of formation of contact holes is enhanced. As the repeating unit having an alkali-soluble group, any of repeating units having an alkali-soluble group bonded directly to the main chain of the resin such as repeating units by an acrylic acid or a methacrylic acid, repeating units having an alkali-soluble group bonded to the main chain of the resin via a linking group, and repeating units having an alkali-soluble group introduced into the end of the polymer chain at the time of polymerization by using an alkali-soluble-group-containing polymerization initiator or chain transfer agent is preferred. The linking group may have a monocyclic or polycyclic hydrocarbon structure. The repeating unit by acrylic acid or methacrylic acid is particularly preferred.

The content of the repeating unit having an alkali-soluble group is preferably from 1 to 20% by mol, more preferably from 3 to 15% by mol, and still more preferably from 5 to 10% by mol, based on all of the repeating units in the polymer.

Next, specific examples of the repeating unit having an alkali-soluble group will be presented, but the present invention is not limited to them. In the specific examples, Rx represents H, CH₃, CH₂OH, or CF₃.

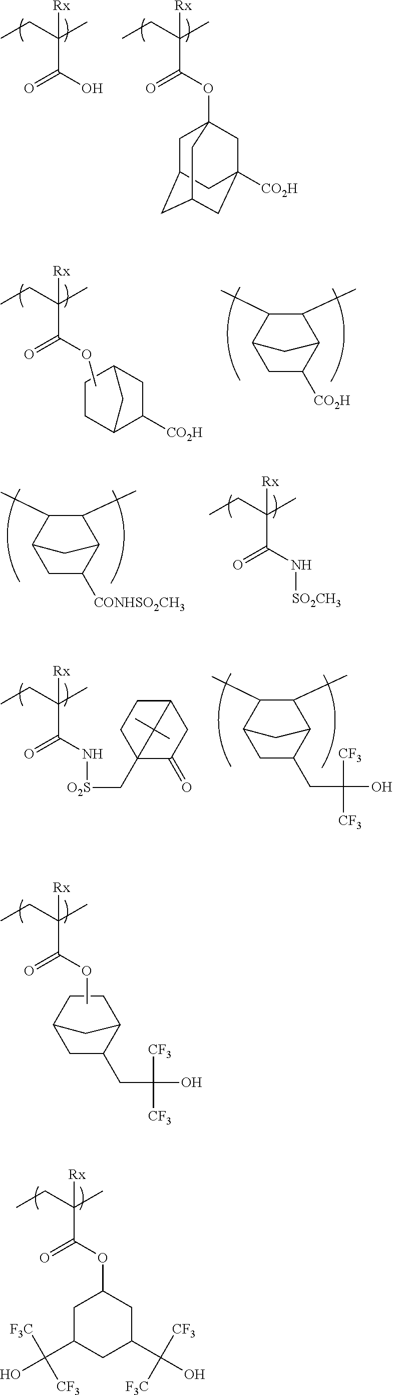

The repeating unit having at least one group selected from a lactone group, a hydroxyl group, a cyano group, and alkali-soluble groups is more preferably a repeating unit having at least two groups selected from a lactone group, a hydroxyl group, a cyano group, and an alkali-soluble group, and still more preferably a repeating units having both a cyano group and a lactone group. It is particularly preferably a repeating unit having a lactone structure of LCI-4 substituted with a cyano group.

The resin of Component (A) may further have a repeating unit which has an alicyclic hydrocarbon structure but shows no acid-decomposability. Thus, the elution of low-molecular components from a resist film into an immersion liquid can be prevented during immersion exposure.

Specifically, the repeating unit having an alicyclic hydrocarbon-based structure preferably contains a repeating unit containing neither a hydroxyl group nor a cyano group, represented by the general formula (3).

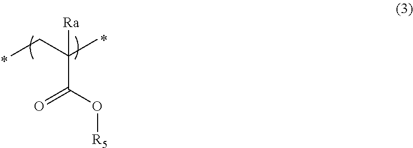

In the general formula (3), R₅ represents a hydrocarbon group having at least one cyclic structure and containing neither a hydroxyl group nor a cyano group.

Ra represents a hydrogen atom, an alkyl group, or a —CH₂—O-Ra₂ group. In the formula, Ra₂ represents a hydrogen atom, an alkyl group, or an acyl group. Examples of Ra include a hydrogen atom, a methyl group, a trifluoromethyl group, a hydroxymethyl group, and the like, and preferably a hydrogen atom and a methyl group.

Examples of the cyclic structure that R₅ has include a monocyclic hydrocarbon group and a polycyclic hydrocarbon group. Examples of the monocyclic hydrocarbon group include a cycloalkyl group having 3 to 12 carbon atoms and a cycloalkenyl group having 3 to 12 carbon atoms. Examples of the preferable monocyclic hydrocarbon group include a monocyclic hydrocarbon group having 3 to 7 carbon atoms, and more preferably a cyclopentyl group and a cyclohexyl group.

The polycyclic hydrocarbon group includes an assembled-ring hydrocarbon group and a bridged-ring hydrocarbon group, and examples of the assembled-ring hydrocarbon group include a bicyclic hydrocarbon ring, a tricyclic hydrocarbon ring, a tetracyclic hydrocarbon ring, and the like. Further, the bridged-ring hydrocarbon ring also includes a condensed hydrocarbon ring formed by fusing together two or more of 5- to 8-membered cycloalkane rings. Examples of the preferable bridged-ring hydrocarbon include a nornornyl group and an adamantyl group.

Examples of the preferable bridged-ring hydrocarbon ring include a norbornyl group, an adamantyl group, a bicyclooctanyl group, a tricyclo[5.2.1.0^{2,6}]decanyl group, and the like, and more preferably a norbornyl group and an adamantyl group.

These alicyclic hydrocarbon groups may have a substituent, and examples of the preferable substituent include a halogen atom, an alkyl group, a hydroxyl group protected by a protective group, an amino group protected by a protective group, and the like. Examples of the preferable halogen atom include bromine, chlorine and fluorine atoms, and examples of the preferable alkyl group include methyl, ethyl, butyl, and t-butyl groups. These alkyl groups each may have a substituent. Examples of the substituent include a halogen atom, an alkyl group, a hydroxyl group protected by a protective group, and an amino group protected by a protective group.

Examples of the protective groups include an alkyl group, a cycloalkyl group, an aralkyl group, a substituted methyl group, a substituted ethyl group, an acyl group, an alkoxycarbonyl group, and an aralkyloxycarbonyl group. Examples of the preferable alkyl group include an alkyl group having 1 to 4 carbon atoms, examples of the preferable substituted methyl group include a methoxymethyl, a methoxythiomethyl group, a benzyloxymethyl group, a t-butoxymethyl group, and a 2-methoxyethoxymethyl group, examples of the preferable substituted ethyl group include a 1-ethoxyethyl group and a 1-methyl-1-methoxyethyl group, examples of the preferable acyl group include aliphatic acyl groups having 1 to 6 carbon atoms such as a formyl group, an acetyl group, a propionyl group, a butyryl group, an isobutyryl group, a valeryl group, and a pivaloyl group, and examples of the alkoxycarbonyl group include an alkoxycarbonyl group having 1 to 4 carbon atoms, and the like.

The content of the repeating units represented by the general formula (3), which have neither a hydroxyl group nor a cyano group is preferably from 0 to 40 mole %, and more preferably from 0 to 20 mole %, based on all of the repeating units in the resin of Component (A).

Next, specific examples of a repeating unit represented by the general formula (3) will be presented, but the present invention is not limited thereto. In the formulae, Ra represents H, CH₃, CH₂OH or CF₃.

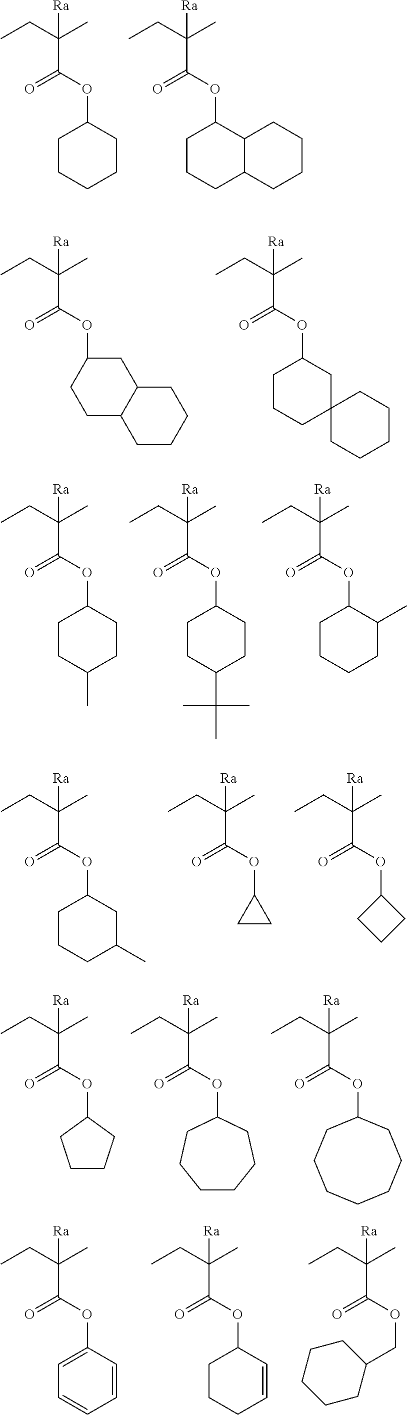

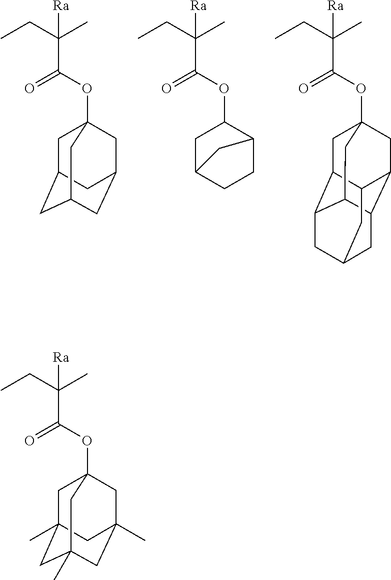

The resin of Component (A) may have various repeating structural units, in addition to the above-described repeating structural units, in order to adjust dry etching resistance, suitability for a standard developer, adhesion to substrates, resist profile, and properties generally required for a resist, such as resolution, heat resistance, sensitivity, and the like.

Examples of such repeating structural units include, but not limited to, repeating units corresponding to the following monomers.

Addition of such a repeating unit enables fine adjustment of the performances required for the resin of Component (A), particularly

(1) solubility in a coating solvent, (2) film forming properties (glass transition point), (3) alkali development properties, (4) film loss (selection of hydrophilic, hydrophobic or alkali-soluble groups), (5) adhesion to an unexposed portion of a substrate, (6) dry etching resistance, and the like.

Examples of such a monomer include compounds having an addition polymerizable unsaturated bond, which is selected from acrylates, methacrylates, acrylamides, methacrylamides, allyl compounds, vinyl ethers, vinyl esters, and the like.

In addition, an additional polymerizable unsaturated compound copolymerizable with a monomer corresponding to the above-described various repeating structural units may be copolymerized therewith.

In the resin of Component (A), the molar ratio of the repeating structural units contained by the resin is determined as needed so as to control the dry etching resistance, suitability for standard developer, adhesion to substrate, and resist profile of the resist, and performances generally required for a resist, such as resolution, heat resistance, sensitivity, and the like.

When the resist composition of the present invention is used for ArF exposure, the resin of Component (A) is preferably free of an aromatic group from the viewpoint of transparency to ArF light.

Further, from the viewpoint of the compatibility with the resin (D), the resin of Component (A) is preferably free from a fluorine atom and a silicon atom.

The resin of Component (A) can be synthesized by the conventional process (for example, radical polymerization). Examples of the common synthesis process include simultaneous polymerization process of dissolving monomer species and an initiator in a solvent and heating the resulting solution; dropwise addition polymerization process of adding a solution of monomer species and an initiator dropwise to a heated solvent over from 1 to 10 hours; and the like. Of these, the dropwise addition polymerization is preferred. Examples of the reaction solvent include ethers such as tetrahydrofuran, 1,4-dioxane, diisopropyl ether, and the like, ketones such as methyl ethyl ketone, methyl isobutyl ketone, and the like, ester solvents such as ethyl acetate and the like, amide solvents such as dimethylformamide, dimethylacetamide, and the like, and solvents, which will be described later, for dissolving the composition of the present invention therein such as propylene glycol monomethyl ether acetate, propylene glycol monomethyl ether, cyclohexanone, and the like. Polymerization using the same solvents as those used for the positive-tone photosensitive composition of the present invention is more preferred. This makes it possible to inhibit the generation of particles during storage.

The polymerization reaction is preferably performed under an inert gas atmosphere such as nitrogen, argon, and the like. Polymerization is started using, as a polymerization initiator, a commercially available radical initiator (such as an azo initiator or peroxide, and the like). As the radical initiator, an azo initiator is preferred, and an azo initiator having an ester group, a cyano group, or a carboxyl group is more preferred. Examples of the preferable initiator include azobisisobutyronitrile, azobidimethyl valeronitrile, dimethyl 2,2′-azobis(2-methylpropionate), and the like. If desired, the initiator may be added further or added in portions. After completion of the reaction, the reaction mixture is charged in a solvent and the desired polymer is collected, for example, by a method employed for collecting powders or solids, and the like. The reaction concentration is from 5 to 50% by mass, and preferably from 10 to 30% by mass. The reaction temperature is typically from 10 to 150° C., preferably from 30 to 120° C., and more preferably from 60 to 100° C.

The resin of Component (A) has a weight average molecular weight of preferably from 1,000 to 200,000, more preferably from 2,000 to 20,000, still more preferably from 3,000 to 15,000, and particularly preferably from 3,000 to 10,000, as determined by a GPC method in terms of polystyrene. The weight average molecular weight to from 1,000 to 200,000 can be adjusted to prevent deterioration of heat resistance or dry etching resistance, and at the same time to prevent deterioration of developability and deterioration of film forming properties which will otherwise occur due to thickening.

The dispersity (molecular weight distribution) is typically in the range from 1 to 3, preferably from 1 to 2.6, more preferably from 1 to 2, and particularly preferably from 1.4 to 1.7. When the molecular weight distribution is smaller, the resolution and the resist shape are excellent, and further, the resist pattern has smooth side walls, and the roughness properties are excellent.

In the resin composition of the present invention, the blending amount of the resin of Component (A) is preferably from 50 to 99.9% by mass, and more preferably from 60 to 99.0% by mass in the total solids of the entire composition. Further, in the present invention, the resins of Component (A) may be used either singly or in combination of two or more kinds thereof.

(B) Compound Capable of Generating an Acid Upon Irradiation with an Actinic Ray or Radiation

The resist composition according to the invention contains a compound capable of generating an acid upon irradiation with an actinic ray or radiation (hereinafter also referred to as a “photo-acid-generator” or “Component (B)”):

As the photo-acid generator, a photo initiator for photo cation polymerization, a photo initiator for photo radical polymerization, a photodecoloring agent for dyes, a photo color changing agent, and a publicly known compound capable of generating an acid upon irradiation with an actinic ray or radiation, which is employed in microresists and the like, and a mixture thereof can be appropriately selected and used.

Examples thereof include a diazonium salt, a phosphonium salt, a sulfonium salt, an iodonium salt, imidosulfonate, oxime sulfonate, diazodisulfone, disulfone, and o-nitrobenzyl sulfonate.

As preferable compounds among the compounds capable of generating an acid upon irradiation with an actinic ray or radiation, the compounds represented by the following general formulae (ZI), (ZII), and (ZIII) may be cited.

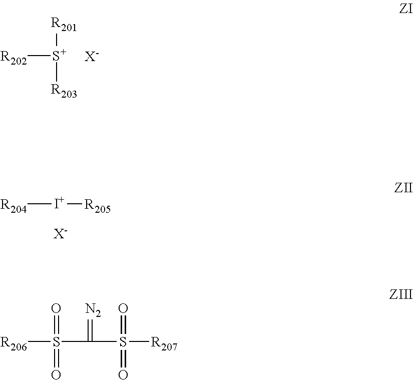

In the general formula (ZI), each of R₂₀₁, R₂₀₁, and R₂₀₃ independently represents an organic group. X⁻ represents a non-nucleophilic anion, and preferably a sulfonate anion, a carboxylate anion, a bis(alkylsulfonyl)amide anion, a tris(alkylsulfonyl)methide anions BF⁴—, PF⁶—, SbF⁶—, and the like. An organic anion having a carbon atom is preferred.

Examples of the preferable organic anion include the organic anions represented by the following formulae.

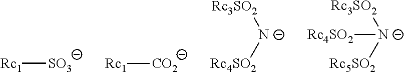

In the formulae,

Rc₁ represents an organic group.

As the organic group Rc₁, one having 1 to 30 carbon atoms may be cited. Preferable examples thereof include an optionally substituted alkyl group, an aryl group and a group wherein a plurality of these groups are bonded via a single bond or a linking group such as —O—, —CO₂—, —S—, —SO₃—, —SO₂N(Rd₁)-, and the like. Rd₁ represents a hydrogen atom or an alkyl group.

Each of Rc₃, Rc₄ and Rc₅ independently represents an organic group. Preferable examples of the organic groups Rc₃, Rc₄ and Rc₅ include the same ones as those cited above as preferable examples of Rc₁. Perfluoroalkyl group having 1 to 4 carbon atoms is most preferred.

Rc₃ and Rc₄ may be bonded to each other to form a ring. Examples of the ring formed by Rc₃ and Rc₄ bonded to each other include an alkylene group and an arylene group, and a perfluoroalkylene group having 2 to 4 carbon atoms is preferred.

The organic groups of Rc₁, and Rc₃ to Rc₅ are particularly preferably an alkyl group substituted at the 1-position by a fluorine atom or a fluoroalkyl group and, a phenyl group substituted by a fluorine atom or a fluoroalkyl group. Owing to the presence of a fluorine atom or a fluoroalkyl group, the acidity of the acid generated by light irradiation increases, and thus the sensitivity is elevated. When Rc₃ and Rc₄ are bonded to each other to form a ring, the acidity of the acid generated by light irradiation increases, and thus the sensitivity is elevated.

Each of the organic acids represented by R₂₀₁, R₂₀₂, and R₂₀₃ generally has from 1 to 30 carbon atoms, and preferably from 1 to 20 carbon atoms.

Further, two of R₂₀₁, R₂₀₂, and R₂₀₃ may be bonded to each other to form a cyclic structure which may contain an oxygen atom, a sulfur atom, an ester bond, an amide bond or a carbonyl group in the ring. Examples of the group formed by two of R₂₀₁, R₂₀₂, and R₂₀₃ bonded to each other include an alkylene group (for example, a butylene group and a pentylene group).

Examples of the organic group of R₂₀₁, R₂₀₂, and R₂₀₃ include an aryl group (preferably having 6 to 15 carbon atoms), a linear or branched alkyl group (preferably having 1 to 10 carbon atoms), a cycloalkyl group (preferably having 3 to 15 carbon atoms), and the like.

It is preferable that at least one of R₂₀₁, R₂₀₂, and R₂₀₃ is an aryl group, and it is more preferable that all the three are aryl groups. As the aryl group, hetero aryl groups such as an indole residue, a pyrrole residue, and the like can be used, in addition to a phenyl group, a naphthyl group, and the like. These aryl groups may further have a substituent. Examples of the substituent include, but not limited to, a nitro group, a halogen atom such as fluorine atom and the like, a carboxylic group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), and the like.

Furthermore, two groups selected from R₂₀₁, R₂₀₂, and R₂₀₃ may be bonded to each other via a single bond or a linking group. Examples of the linking group include, but not limited to, an alkylene group (preferably having 1 to 3 carbon atoms), —O—, —S—, —CO—, —SO₂—, and the like.

Examples of the preferable structure in the case where one of R₂₀₁, R₂₀₂, and R₂₀₃ is not an aryl group include cation structures such as the compounds exemplified in the paragraphs 0047 and 0048 of JP-A-2004-233661, and the paragraphs 0040 to 0046 of JP-A-2003-35948, and represented by the formulae (I-1) to (1-70) in the specification of US 2003/0224288 A1, the compounds represented by the formulae (IA-1) to (IA-54), and the formulae (IB-1) to (IB-24) in the specification of US 2003/0077540 A1, and the like.

Furthermore, specific examples of the organic groups as R₂₀₁, R₂₀₂, and R₂₀₃ include the corresponding groups in the compounds (ZI-1), (ZI-2) and (ZI-3) as will be described hereinafter.

Also, use may be made of a compound having a plurality of the structures represented by the general formula (ZI). For example, use may be made of a compound having a structure wherein at least one of R₂₀₁ to R₂₀₃ in the compound represented by the general formula (ZI) is bonded to at least one of R₂₀₁ to R₂₀₃ in another compound represented by the general formula (ZI).

Examples of the more preferable component (ZI) include the compounds (ZI-1), (ZI-2), and (ZI-3) as will be described hereinafter.

The compound (ZI-1) is an arylsulfonium compound wherein at least one of R₂₀₁ to R₂₀₃ in the general formula (ZI) is an aryl group, i.e., a compound having arylsulfonium as a cation.

In the arylsulfonium compound, all of R₂₀₁ to R₂₀₃ may be aryl groups. Alternatively, a part of R₂₀₁, R₂₀₂, and R₂₀₃ may be aryl group(s) while the remainder(s) may be an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound, an aryldicycloalkylsulfonium compound, and the like.

As the aryl group in the arylsulfonium compound, aryl groups such as a phenyl group, a naphthyl group, and the like, and heteroaryl groups such as an indole residue, a pyrrole residue, and the like are preferable, and a phenyl group or an indole residue is more preferable. In the case where the arylsulfonium compound has two or more aryl groups, these two or more aryl groups may be either the same as or different from each other.

As the alkyl group contained, if necessary, in the arylsulfonium compound, a linear or branched alkyl group having 1 to 15 carbon atoms is preferred. Examples thereof include a methyl group, an ethyl group, a propyl group, an n-butyl group, a sec-butyl group, a t-butyl group, and the like.

As the cycloalkyl group carried, if necessary, by the arylsulfonium compound, a cycloalkyl group having 3 to 15 carbon atoms is preferred. Examples thereof include a cyclopropyl group, a cyclobutyl group, a cyclohexyl group, and the like.

The aryl group, the alkyl group, and the cycloalkyl group represented by R₂₀₁ to R₂₀₃ may have a substituent such as an alkyl group (for example, one having 1 to 15 carbon atoms), a cycloalkyl group (for example, one having 3 to 15 carbon atoms), an aryl group (for example, one having 6 to 14 carbon atoms), an alkoxy group (for example, one having 1 to 15 carbon atoms), a halogen atom, a hydroxyl group, or a phenylthio group. Examples of the preferable substituent include a linear or branched alkyl group having 1 to 12 carbon atoms, a cycloalkyl group having 3 to 12 carbon atoms and a linear, branched, or cyclic alkoxy group having 1 to 12 carbon atoms. An alkyl group having 1 to 4 carbon atoms or an alkoxy group having 1 to 4 carbon atoms is still preferred. Such a substituent may be attached to either one of R₂₀₁ to R₂₀₃ or all of them. Further, in the case where R₂₀₁ to R₂₀₃ are aryl groups, the substituent is preferably attached to the p-position of the aryl group.

Next, the compound (ZI-2) will be described. The compound (ZI-2) is a compound wherein each of R₂₀₁ to R₂₀₃ in the formula (ZI) independently represents an organic group having no aromatic ring. The “aromatic ring” as used herein also includes an aromatic ring having a hetero atom.

The organic group having no aromatic ring represented by R₂₀₁ to R₂₀₃ generally has from 1 to 30 carbon atoms, and preferably from 1 to 20 carbon atoms.

Each of R₂₀₁ to R₂₀₃ independently is preferably an alkyl group, a cycloalkyl group, an alkyl group, or a vinyl group, more preferably a linear, branched, or cyclic 2-oxoalkyl group or an alkoxycarbonylmethyl group, and more preferably a linear or branched 2-oxoalkyl group.

The alkyl groups as R₂₀₁ to R₂₀₃ may be either linear or branched. Preferable examples thereof include linear or branched alkyl groups having 1 to 10 carbon atoms (for example, a methyl group, an ethyl group, a propyl group, a butyl group, and a pentyl group). As the alkyl group as R₂₀₁ to R₂₀₃, a linear or branched 2-oxoalkyl group or an alkoxycarbonylmethyl group is preferable.

Preferable examples of the cycloalkyl groups as R₂₀₁ to R₂₀₃ include cycloalkyl groups having 3 to 10 carbon atoms (a cyclopentyl group, a cyclohexyl group, and a norbonyl group). As the cycloalkyl group as R₂₀₁ to R₂₀₃, a cyclic 2-oxoalkyl group is preferred.

Preferable examples of the linear, branched, or cyclic 2-oxoalkyl group as R₂₀₁ to R₂₀₃ include the alkyl and cycloalkyl groups as described above having >C═O attached to the 2-position thereof.

Preferable examples of the alkoxy group in the alkoxycarbonylmethyl group as R₂₀₁ to R₂₀₃ include an alkoxy group having 1 to 5 carbon atoms (a methoxy group, an ethoxy group, a propoxy group, a butoxy group, and a pentoxy group).

R₂₀₁ to R₂₀₃ may be further substituted by a halogen atom, an alkoxy group (for example, one having 1 to 5 carbon atoms), a hydroxyl group, a cyano group, or a nitro group.

The compound (ZI-3) refers to a compound represented by the following general formula (ZI-3), which is a compound having a phenacylsuflonium salt structure.

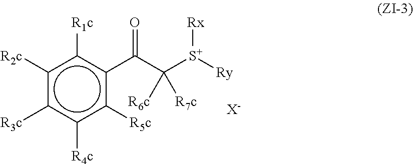

In the general formula (ZI-3),

each of R₁c to R₅c independently represents a hydrogen atom, an alkyl group, a cycloalkyl group, an alkoxy group, or a halogen atom.

Each of R₆c and R₇c independently represents a hydrogen atom, an alkyl group, or a cycloalkyl group.

Each of Rₓ and R_{y} independently represents an alkyl group, a cycloalkyl group, an allyl group, or a vinyl group.

Any two or more of R₁c to R₇c , and Rₓ and R_{y} may be bonded to each other to thereby respectively form cyclic structures. Such a cyclic structure may contain an oxygen atom, a sulfur atom, an ester bond or an amide bond. Examples of the rings formed by any two or more of R₁c to R₇c , and Rₓ and R_{y} bonded to each other include a butylene group, a pentylene group, and the like.

X⁻ represents a non-nucleophilic anion that is the same as the non-nucleophilic anion X⁻ in the general formula (ZI).

The alkyl groups as R₁c to R₇c may be either linear or branched. Examples thereof include linear or branched alkyl groups having 1 to 20 carbon atoms, and preferably a linear or branched alkyl group having 1 to 12 carbon atoms (for example, a methyl group, an ethyl group, a linear or branched propyl group, a linear or branched butyl group, and a linear or branched pentyl group).

Preferable examples of the cycloalkyl groups as R₁c to R₇c include cycloalkyl groups having 3 to 8 carbon atoms (for example, a cyclopentyl group and a cyclohexyl group).

The alkoxy groups represented by R₁c to R₅c may be linear, branched or cyclic. For example, there can be enumerated an alkoxy group having 1 to 10 carbon atoms, preferably a linear or branched alkoxy group having 1 to 5 carbon atoms (for example, methoxy, ethoxy, linear or branched propoxy, linear or branched butoxy and linear or branched pentoxy groups) and a cyclic alkoxy group having 3 to 8 carbon atoms (for example, cyclopentyloxy and cyclohexyloxy groups).

It is preferable that any one of R₁c to R₅c is preferably a linear or branched alkyl group, a cycloalkyl group, or a linear, branched, or cyclic alkoxy group. It is more preferable that the sum of the carbon atoms in R₁c to R₅c amounts to 2 to 15. Thus, the solubility in a solvent can be elevated and the occurrence of particles can be prevented during preservation.

Examples of the alkyl groups as Rₓ and R_{y} include those which are the same as the alkyl groups cited above as R₁c to R₇c . As the alkyl groups Rₓ and R_{y}, a linear or branched 2-oxoalkyl group or an alkoxycarbonylmethyl group is preferred.

Examples of the cycloalkyl groups as Rₓ and R_{y} include those which are the same as the cycloalkyl groups cited above as R₁c to R₇c . As the cycloalkyl groups Rₓ and R_{y}, a cyclic 2-oxoalkyl group is preferred.

Preferable examples of the linear, branched, or cyclic 2-oxoalkyl group include the alkyl and cycloalkyl groups having >C═O attached to the 2-position thereof as described above as R₁c to R₇c .

Preferable examples of the alkoxy group in the alkoxycarbonylmethyl group include those which are the same as the alkoxy groups cited above as R₁c to R₅c .

It is preferable that Rₓ and R_{y} are an alkyl group having 4 or more carbon atoms, more preferably an alkyl group having 6 or more carbon atoms, and still more preferably an alkyl group having 8 or more carbon atoms.

In the general formulae (ZII) and (ZIII), each of R₂₀₄ to R₂₀₇ independently represents an aryl group, an alkyl group, or a cycloalkyl group. Specific examples of these groups include those which are the same as the groups specifically cited above as R₂₀₁, R₂₀₂, and R₂₀₃.

X⁻ represents a non-nucleophilic anion, and examples thereof include those which are the same as the non-nucleophilic anion of X⁻ in the general formula (ZI).

Examples of the preferable compound capable of generating an acid upon irradiation with an actinic ray or radiation further include the compounds represented by the following general formulae (ZIV), (ZV), and (ZVI).

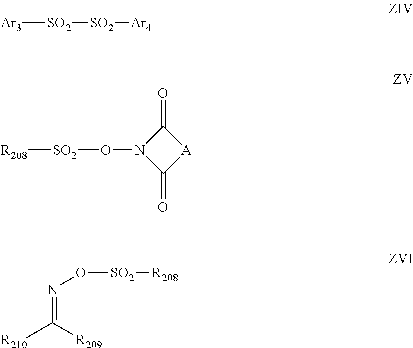

In the general formulae (ZIV) to (ZVI),

each of Ar₃ and Ar₄ independently represents an aryl group.

R₂₀₈ represents an alkyl group or an aryl group.

Each of R₂₀₉ and R₂₁₀ independently represents an alkyl group, an aryl group, or an electron-withdrawing group. R₂ is preferably an aryl group.

R₂₁₀ is preferably an electron-withdrawing group, and more preferably a cyano group or a fluoroalkyl group.

A represents an alkylene group, an alkenylene group, or an arylene group.

As the compound capable of generating an acid upon irradiation with an actinic ray or radiation, the compounds represented by the general formulae (ZI) to (ZIII) are preferred.

The compound (B) is preferably a compound capable of generating a fluorine-containing aliphatic sulfonic acid or a fluorine-containing benzenesulfonic acid upon irradiation with an actinic ray or radiation.

The compound (B) preferably has a triphenylsulfonium structure.

The compound (B) is preferably a triphenylsulfonium compound having an alkyl group or a cycloalkyl group, which has no fluorine, in the cation moiety.

Next, particularly preferable examples of the compound capable of generating an acid upon irradiation with an actinic ray or radiation will be presented.

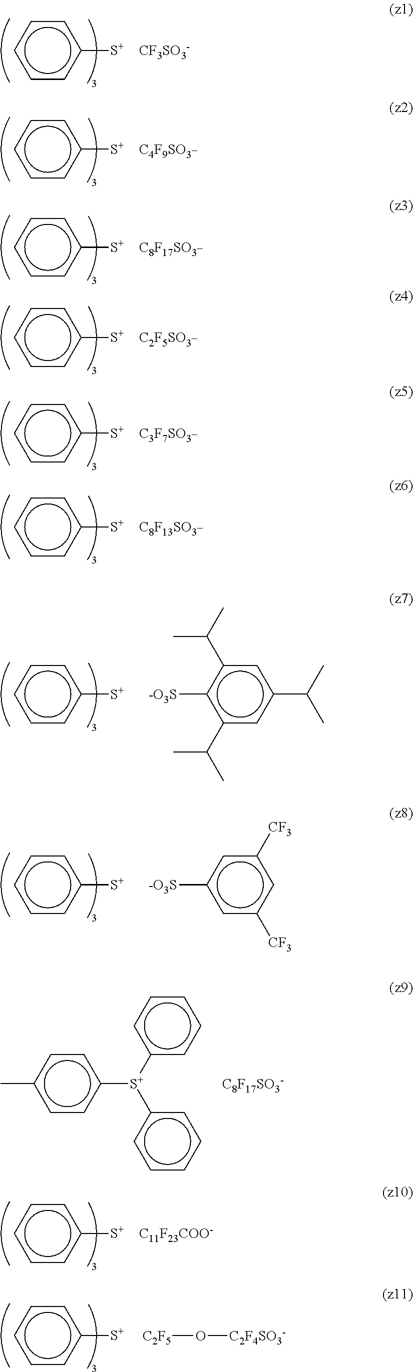

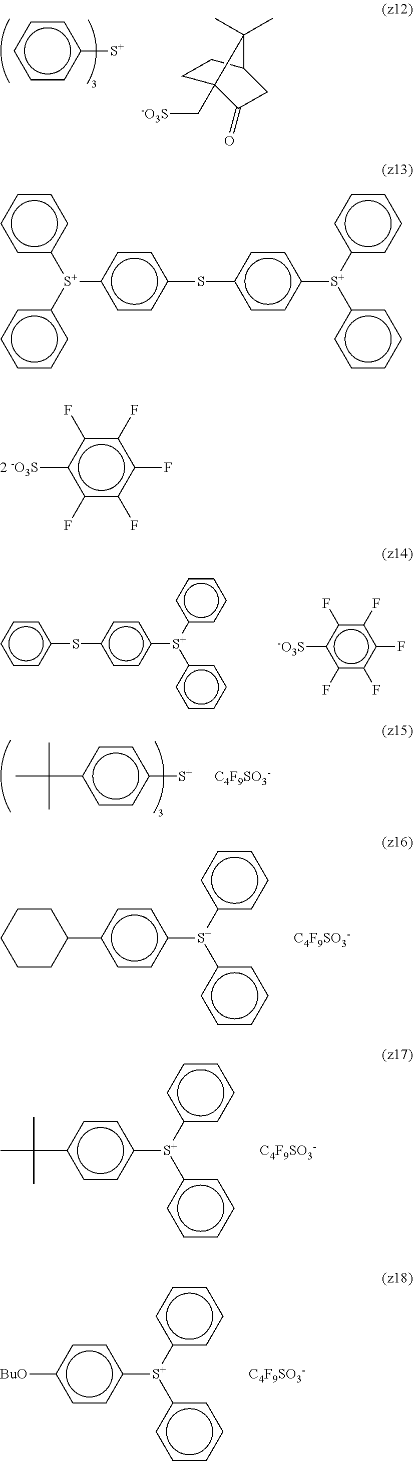

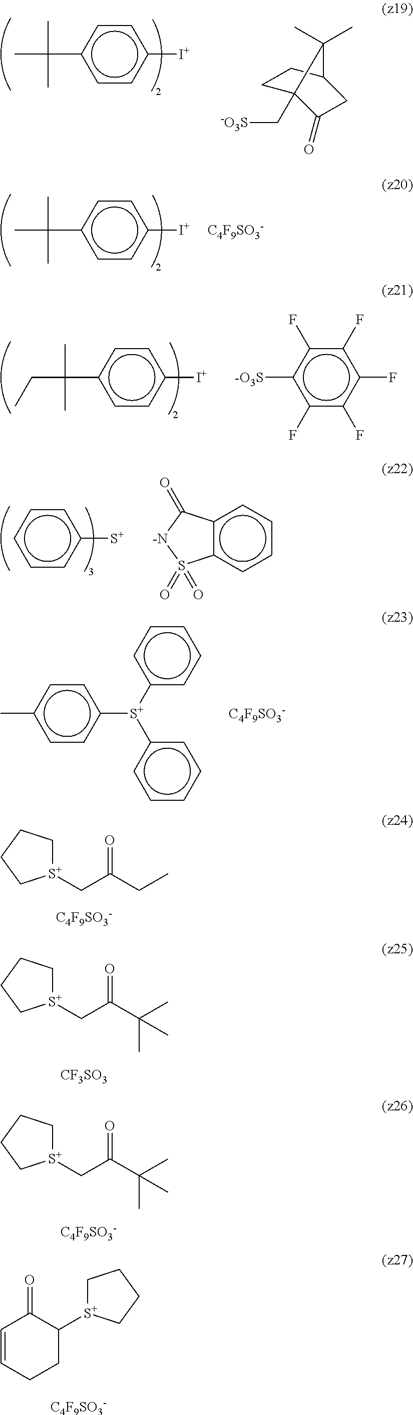

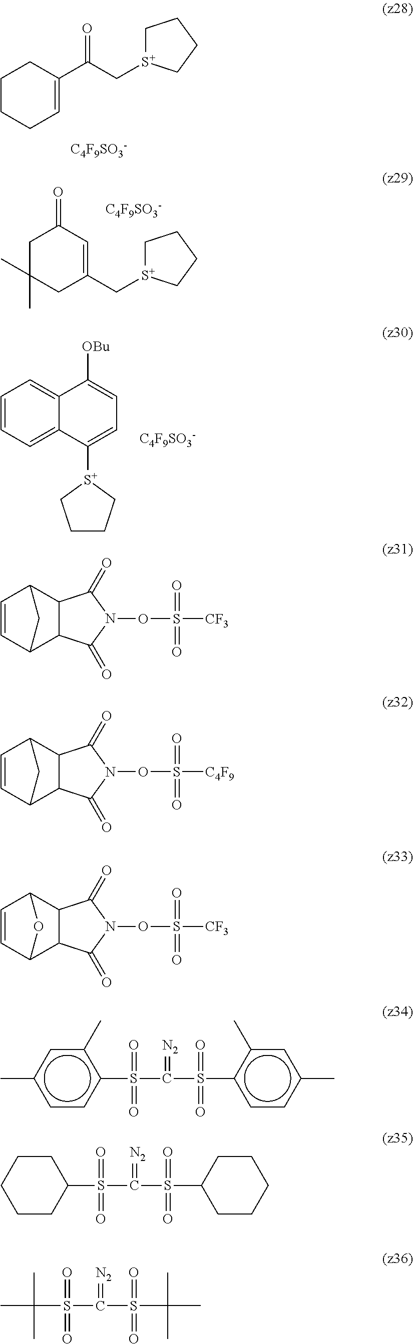

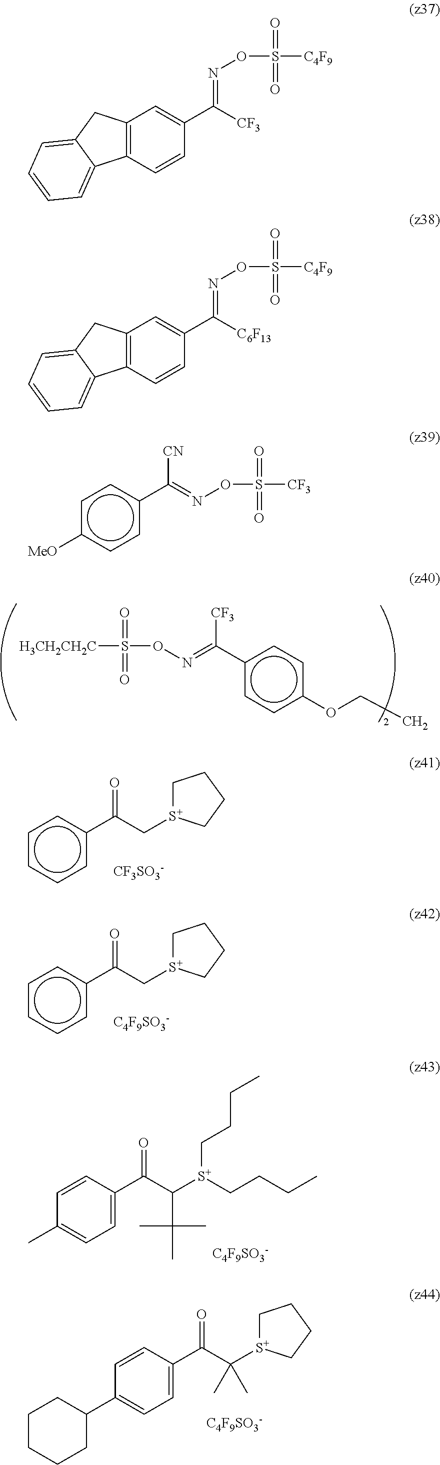

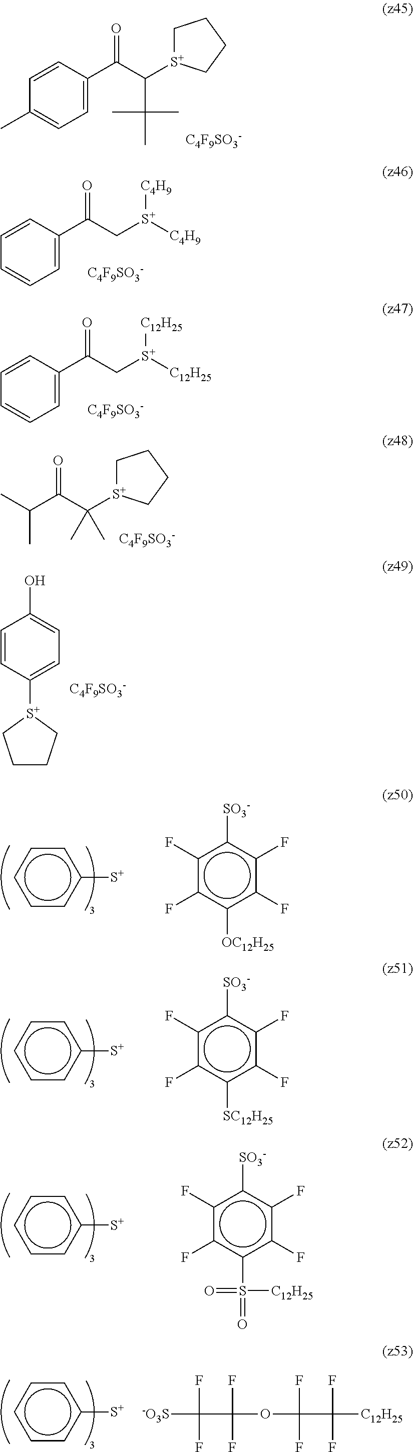

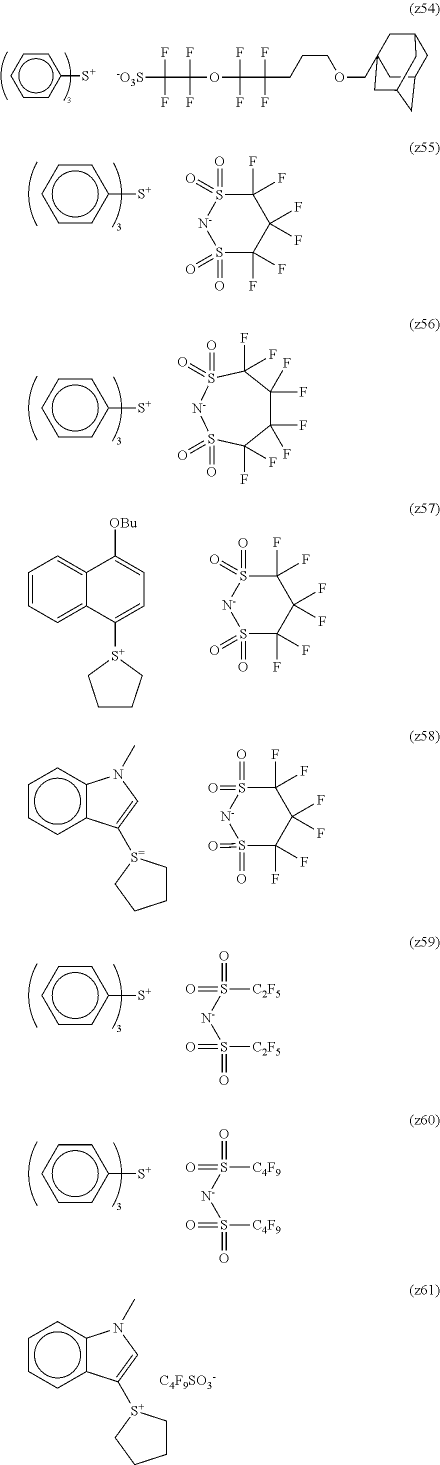

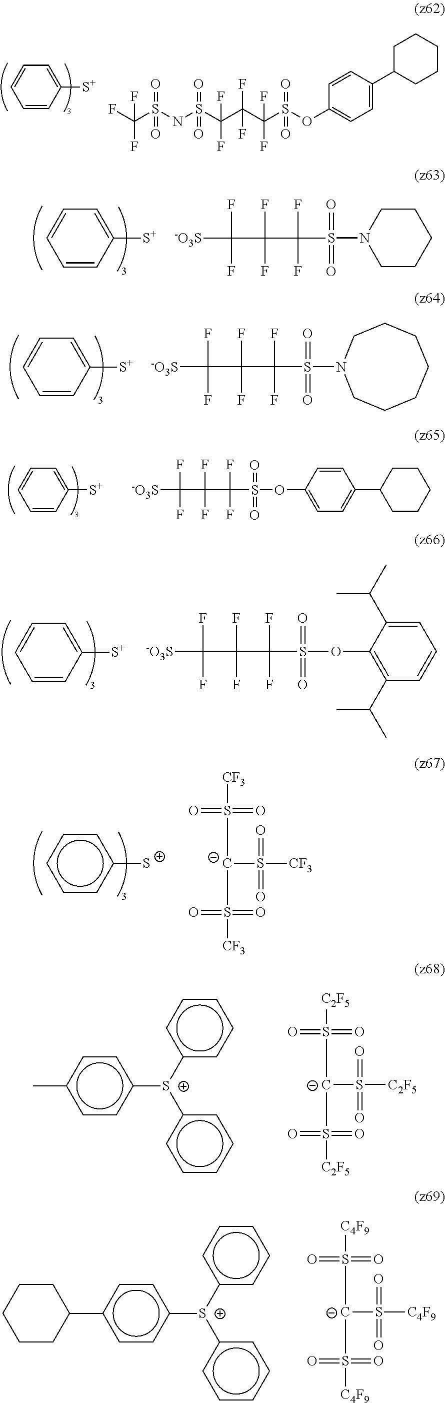

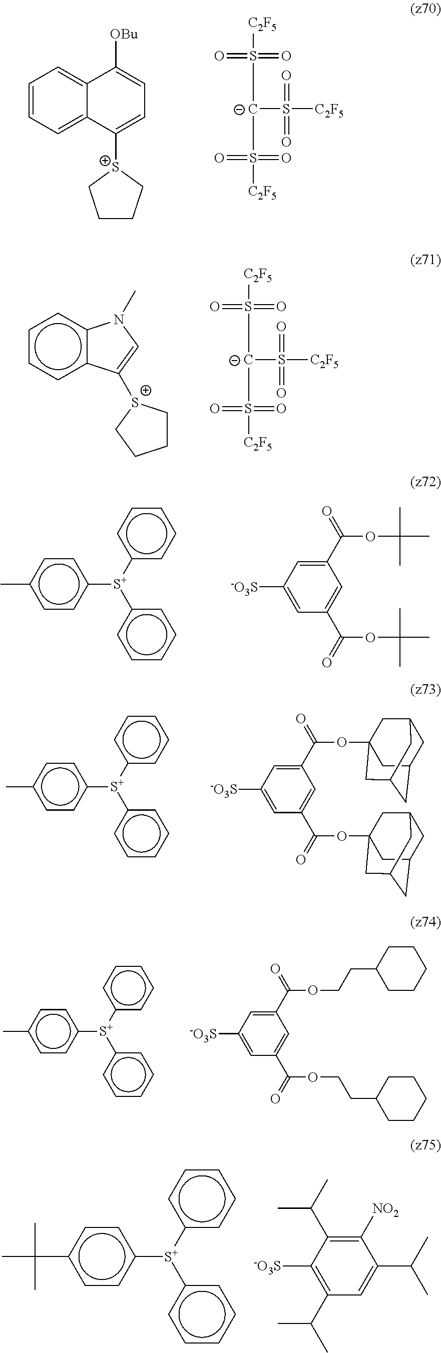

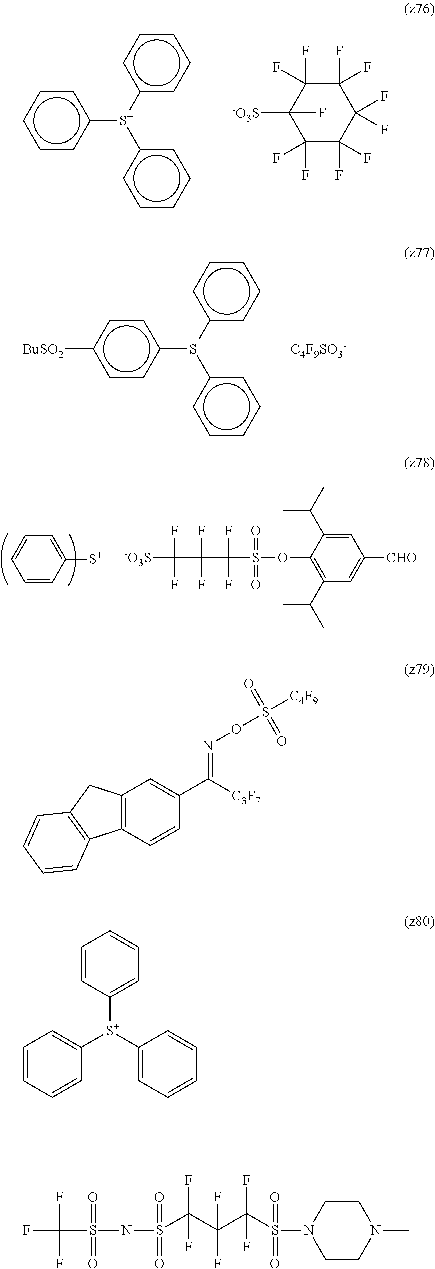

Furthermore, in the general formula (ZI), the case where Z⁻ is an anion represented by the following general formula (A′) is also preferred.

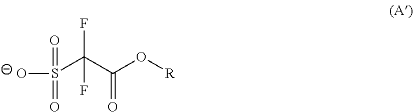

In the general formula (A′), R represents a hydrogen atom or an organic group, preferably an organic group having 1 to 40 carbon atoms, more preferably an organic group having 3 to 20 carbon atoms, and most preferably an organic group represented by the following general formula (B).

The organic group of R may have one or more carbon atoms, in which the atom bonding to the oxygen atom in an ester bond represented by the general formula (A′) is preferably a carbon atom. Examples of the organic group include an alkyl group, a cycloalkyl group, an aryl group, an aralkyl group, and a group having a lactone structure, which may have a hetero atom such as an oxygen atom, a sulfur atom, and the like in the chain. Further, these may have a substituent, and may have a substituent such as a hydroxyl group, an acyl group, an acyloxy group, an oxy group (═O), a halogen atom, and the like.

—(CH₂)ₙ-Rc-(Y)ₘ (B)

In the general formula (B), Rc represents a cyclic ether, a cyclic thioether, a cyclic ketone, a cyclic carbonic ester, lactone, or a monocyclic or polycyclic cyclic organic group having 3 to 30 carbon atoms, which may have a lactam structure.

Y represents a hydroxyl group, a halogen atom, a cyano group, a carboxylic group, a hydrocarbon group having 1 to 10 carbon atoms, a hydroxyalkyl group having 1 to 10 carbon atoms, an alkoxy group having 1 to 10 carbon atoms, an acyl group having 1 to 10 carbon atoms, an alkoxycarbonyl group having 2 to 10 carbon atoms, an acyloxy group having 2 to 10 carbon atoms, an alkoxyalkyl group having 2 to 10 carbon atoms, or a halogenated alkyl group having 1 to 8 carbon atoms.

m is an integer of 0 to 6, and if a plurality of Y's are present, they may be the same as or different from each other. n is an integer of 0 to 10.

The total number of carbon atoms constituting the organic group represented by the general formula (B) is preferably 40 or less. Further, in the organic group represented by the general formula (B), n is an integer of 0 to 3, and Rc is preferably a monocyclic or polycyclic cyclic organic group having 7 to 16 carbon atoms.

As specific examples of the anion-containing compound represented by the general formula (A′), the following compounds are exemplified, but not limited thereto.

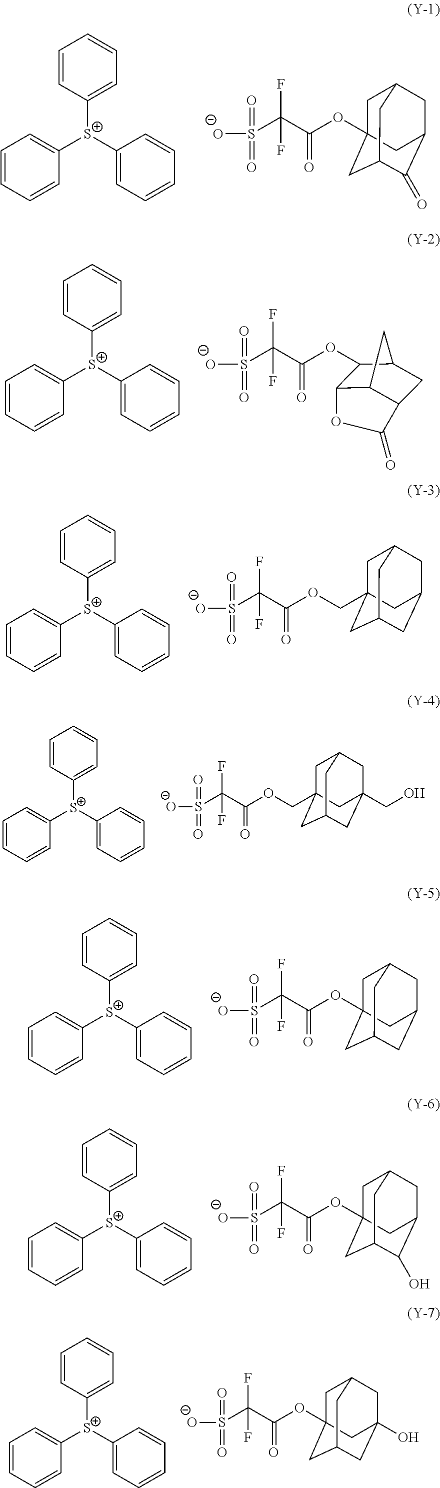

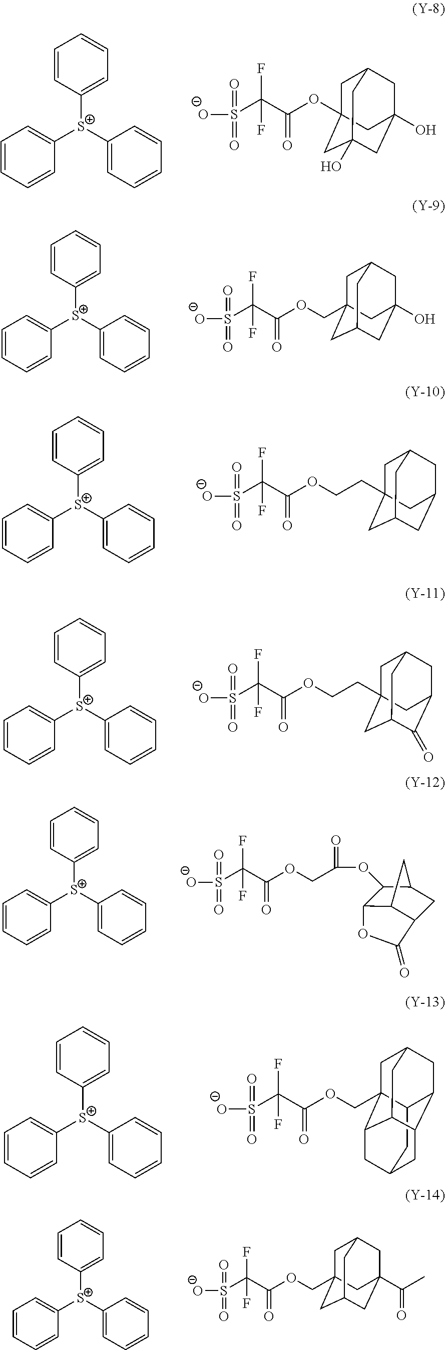

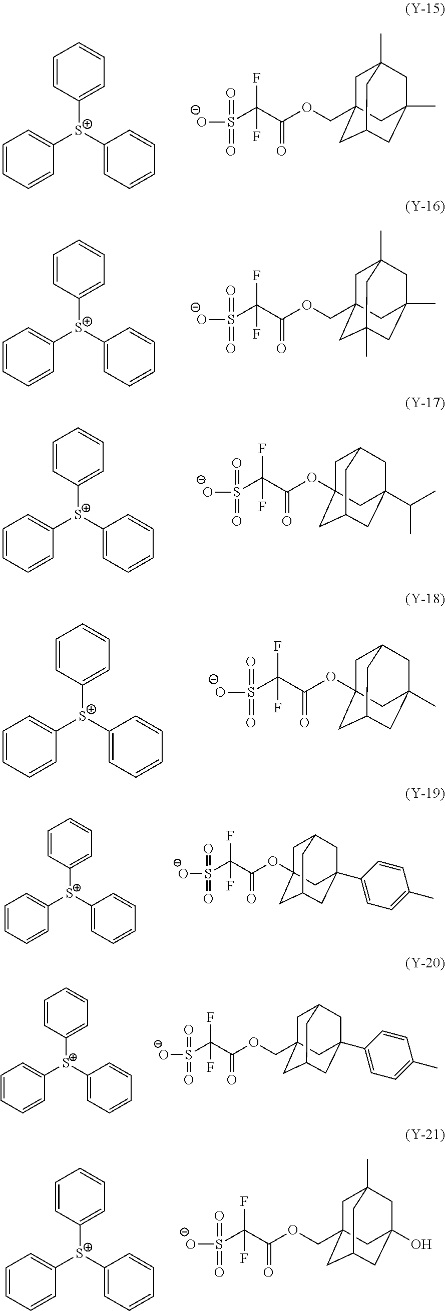

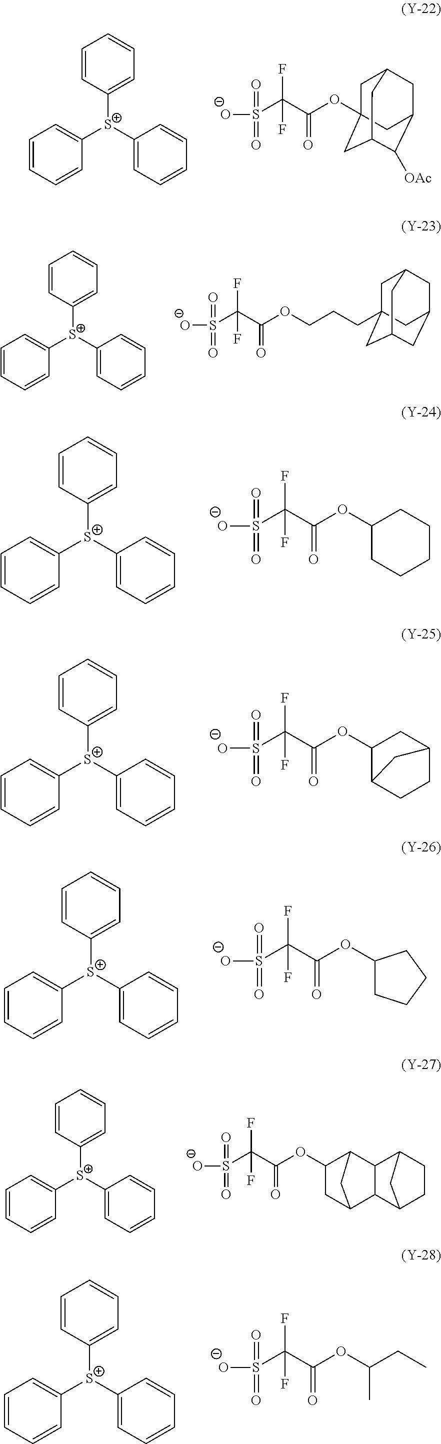

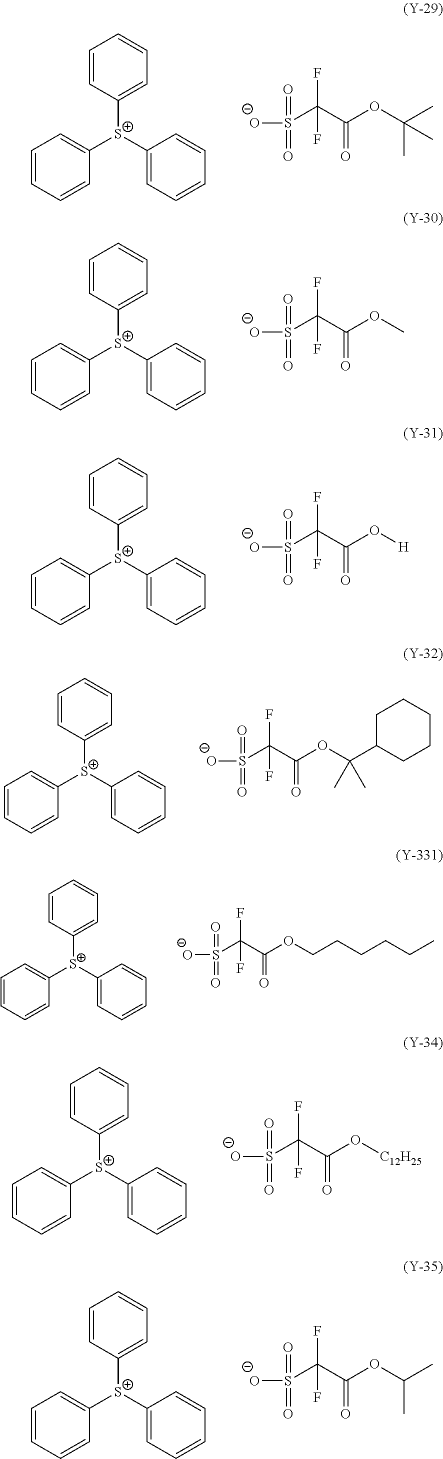

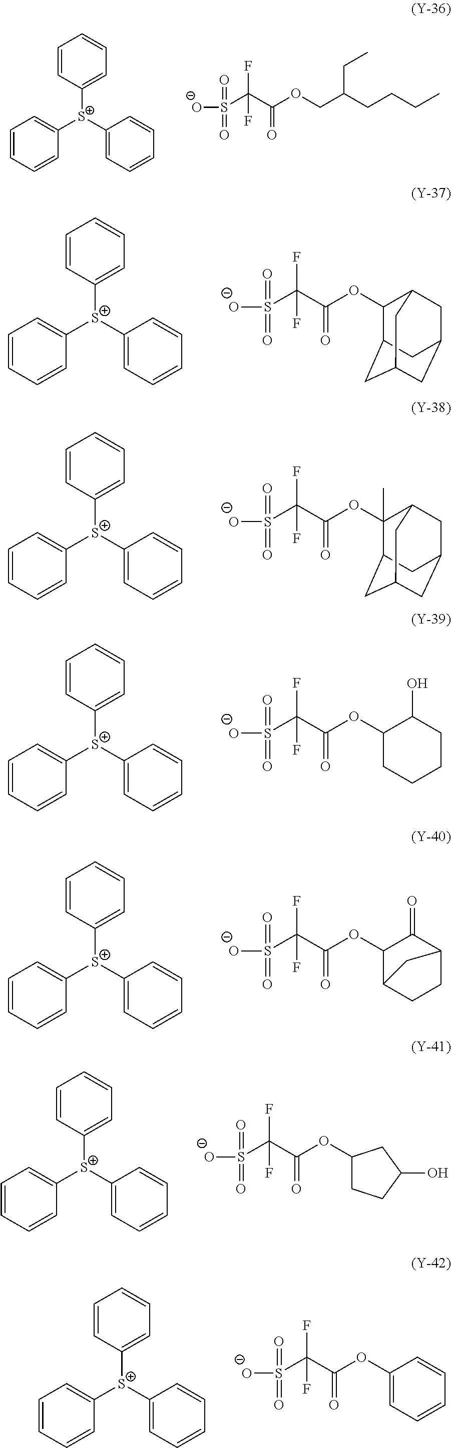

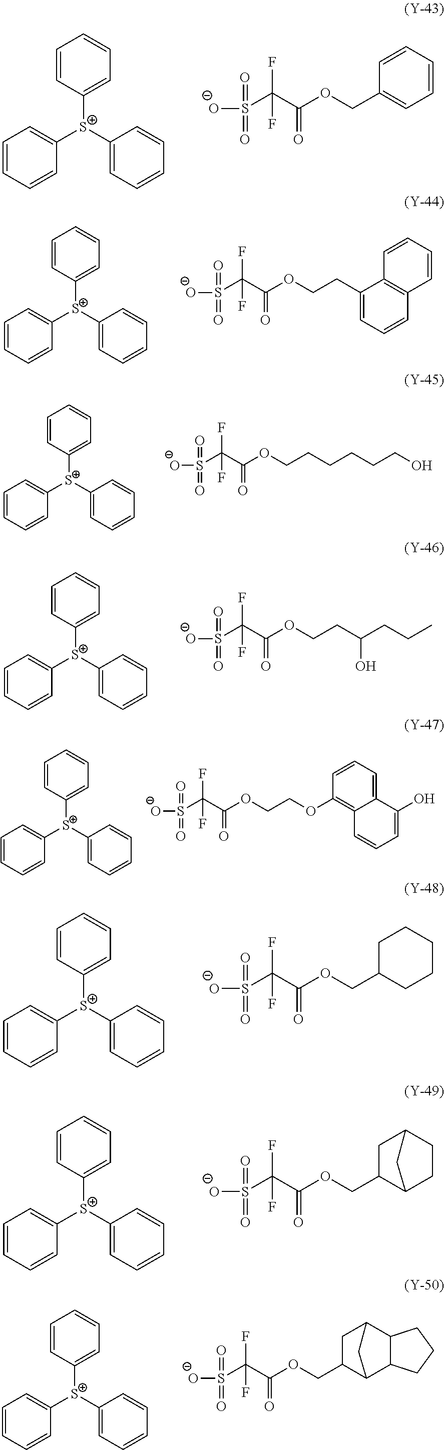

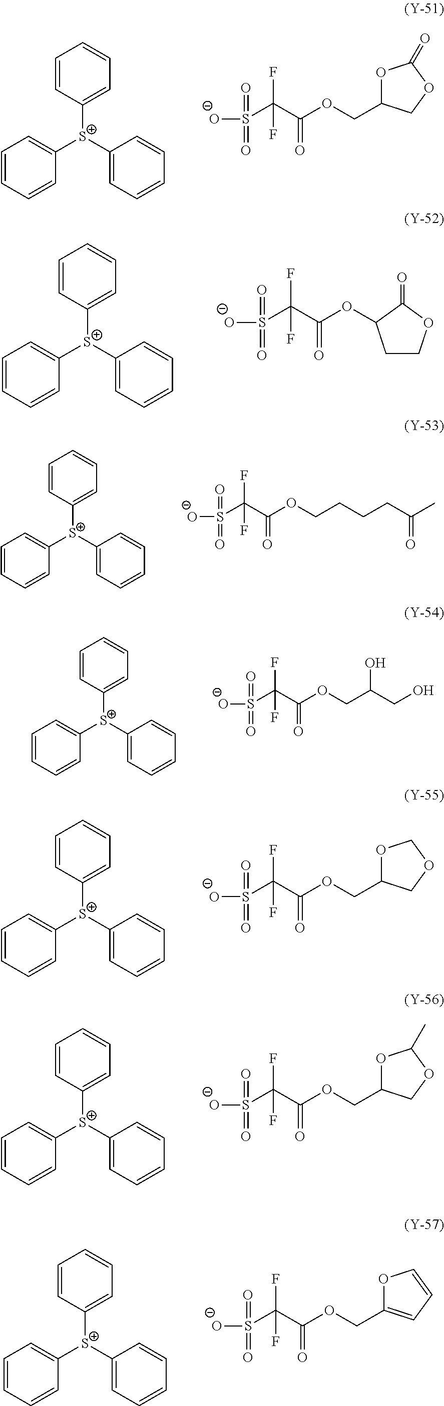

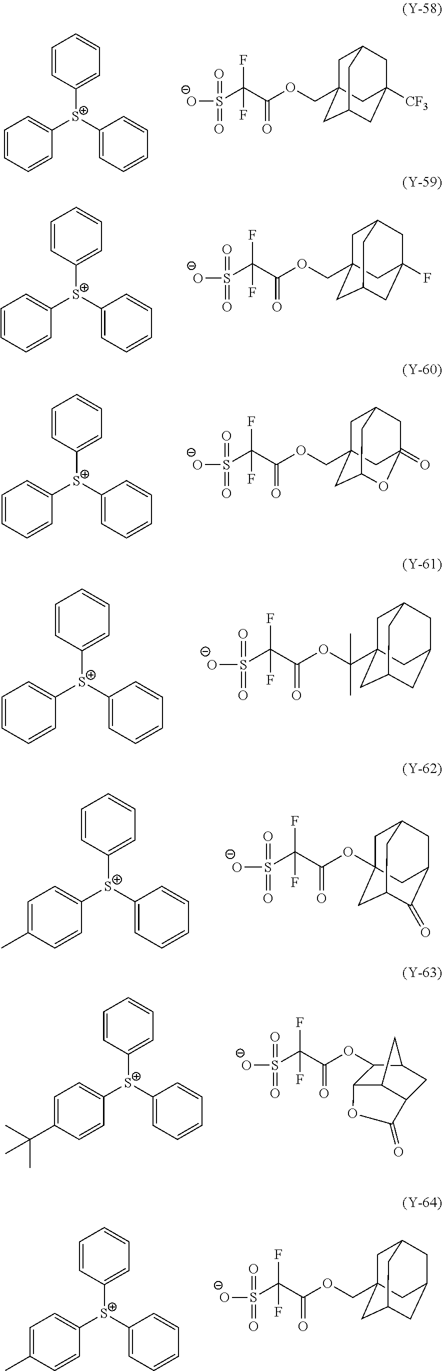

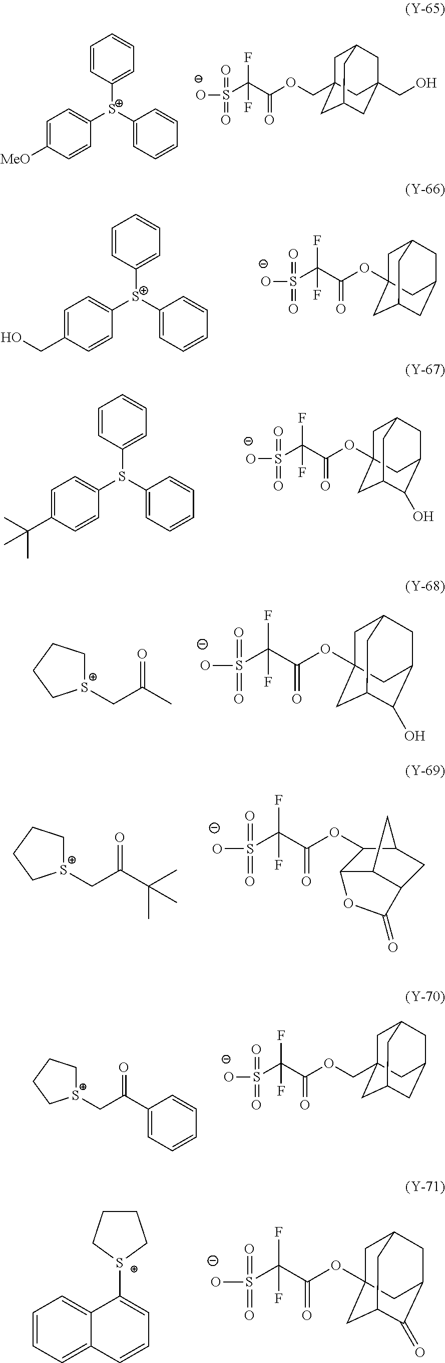

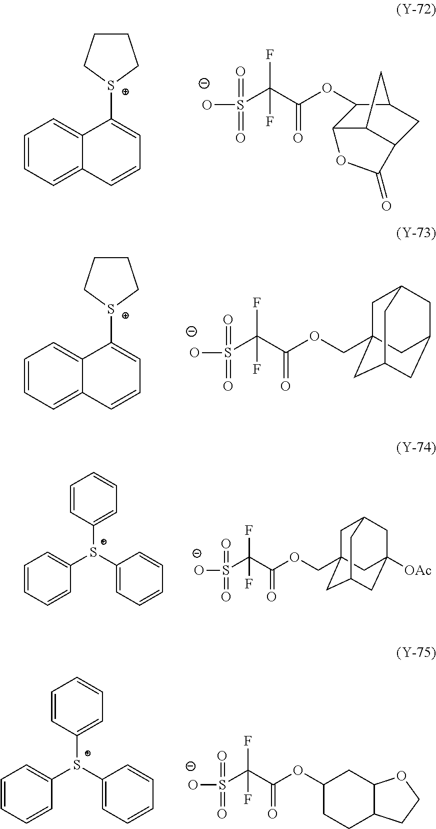

The compound represented by the general formula (A′) can be synthesized by a known method, for example, in accordance with the method as set forth in JP-A-2007-161707.

The photo-acid generators may be used either singly or in combination of two or more kinds thereof. In the case of using a combination of two or more thereof, it is preferable to photo-acid generators generating two different organic acids having a difference in the total number of atoms excluding hydrogen atoms by two or more.

The total amount of the photo-acid generator is preferably from 0.1 to 20% by mass, more preferably from 0.5 to 10% by mass, and still more preferably from 1 to 7% by mass, based on the total solids in the resist composition.

Furthermore, other preferable examples of the acid generator include the compounds capable of generating sulfonic acids represented by the following general formula (I) or (I′).

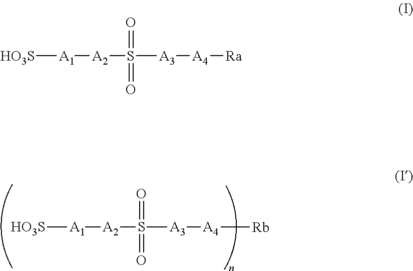

In the general formulae (I) and (I′),

A₁ represents a divalent linking group.

Each of A₂ and A₃ independently represents a single bond, oxygen atom or —N(Rxb)-.

Rxb represents a hydrogen atom, an aryl group, an alkyl group, or a cycloalkyl group.

A₄ represents a single bond or —C(═O)—.

Ra represents a hydrogen atom or an organic group,

n represents 2 or 3.

Rb represents a n-valent linking group.

When A₃ is —N(Rxb)-, Ra and Rxb or Rb and Rxb may be bonded to each other to form a ring.

The divalent linking group as A₁ is preferably an organic group having 1 to 20 carbon atoms, and more preferably an alkylene group (having preferably 1 to 10 carbon atoms, more preferably 2 to 6 carbon atoms, and still more preferably 3 to 4 carbon atoms). The alkylene chain may have a linking group such as an oxygen atom, a sulfur atom, a —C(═O)— group, an ester group, and the like.

The divalent linking group as A₁ is more preferably an alkylene group substituted with a fluorine atom, and particularly preferably an alkylene group in which 30 to 100% of the number of the hydrogen atoms are substituted with a fluorine atom. In the case of an alkylene group substituted with a fluorine atom, it is preferable that the carbon atom bonded with a —SO₃H group has a fluorine atom. Further, a perfluoroalkylene group is preferred, and a perfluoroethylene group, a perfluoropropylene group, and a perfluorobutylene group are most preferred.

The aryl group in Rxb may have a substituent, is preferably an aryl group having 6 to 14 carbon atoms.

The alkyl group as Rxb may have a substituent, and preferably a linear and branched alkyl group having 1 to 20 carbon atoms, and may have an oxygen atom in the alkyl chain.

Further, examples of the alkyl group having a substituent particularly include groups in which a linear or branched alkyl group is substituted with a cycloalkyl group (for example, an adamantylmethyl group, an adamantylethyl group, a cyclohexylethyl group, a camphor residue, and the like).

The cycloalkyl group as Rxb may have a substituent, and a cycloalkyl group having 3 to 20 carbon atoms is preferred.

Ra represents a hydrogen atom or a mono-value organic group.

The mono-value organic group as Ra preferably has 1 to 20 carbon atoms, and examples thereof include an alkyl group, a cycloalkyl group, an aryl group, an aralkyl group, an alkenyl group, and the like.

The alkyl group, the cycloalkyl group, or the aryl group as Ra is the same as those cited above as Rxb.

Examples of the aralkyl group as Ra preferably include an aralkyl group having 7 to 20 carbon atoms.

Examples of the alkenyl group as Ra include the groups having a double bond at any position of an alkyl group cited as Rxb.

The n-valent linking group as Rb preferably has 1 to 20 carbon atoms. Examples of the divalent linking group as Rb in the case of n=2 in the general formula (I′) include an alkylene group (preferably having 1 to 20 carbon atoms), an arylene group (preferably having 6 to 10 carbon atoms), an aralkylene group (preferably having 7 to 13 carbon atoms), and an alkenylene group (preferably having 2 to 12 carbon atoms). These may have a substituent.

Examples of the tri-valent linking group as Rb in the case of n=3 include tri-valent groups excluding any hydrogen atom of the divalent linking group.

When A₃ is —N(Rxb)-, the ring formed by Ra and Rxb or Rb and Rxb bonded to each other is a ring having 4 to 10 carbon atoms including a nitrogen atom, and may be monocyclic or polycyclic. Further, an oxygen atom may be contained in the ring.

Examples of the substituent which each of the groups may have include a halogen atom, a hydroxyl group, a nitro group, a cyano group, a carboxyl group, a cycloalkyl group (preferably having 3 to 20 carbon atoms), an aryl group (preferably having 6 to 14 carbon atoms), an alkoxy group (preferably having 1 to 20 carbon atoms), an acyl group (preferably having 2 to 20 carbon atoms), an acyloxy group (preferably carbon atoms 2 to 20 carbon atoms), and the like. For the cyclic structure in the aryl group, the cycloalkyl group, and the like, examples of the substituent further include an alkyl group (preferably having 1 to 20 carbon atoms).

The sulfonic acid of the general formulae (I) and (I′) is preferably sulfonic acids represented by the following general formulae (IA) to (IC) and (I′A) to (I′C).

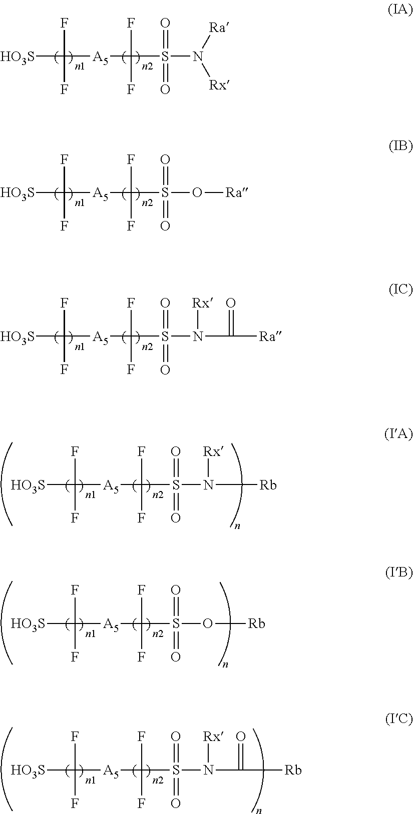

In the general formulae (IA) to (IC) and (I′A) to (IC),

Ra′ has the same meaning as Ra in the general formula (I).

Rb and n have the same meaning as Rb and n in the general formula (I′).

Ra″ represents an alkyl group, an aryl group, an aralkyl group, or an alkenyl group.

Rx′ has the same meaning as Rxb the general formulae (I) and (I′).

n1 represents an integer of 1 to 10.

n2 represents an integer of 0 to 10.

A₅ represents a single bond, —O—, an alkylene group, a cycloalkylene group, or an arylene group.

The alkylene group or the cycloalkylene group as A₅ is preferably an alkylene group or a cycloalkylene group, which is not substituted with fluorine.

In the general formula (IA), it is preferable that Ra′ and Rx′ may be bonded to each other to form a ring. By forming a ring structure, the stability is improved, and thus, the storage stability of the composition using the same is improved. The formed ring preferably has 4 to 20 carbon atoms, may be monocyclic or polycyclic, and may further contain an oxygen atom.

Examples of the alkyl group, the aryl group, the aralkyl group, or the alkenyl group as Ra″ include the same as the alkyl group, the aryl group, the aralkyl group, or the alkenyl group as Ra.

n1+n2 is preferably from 2 to 8, and more preferably from 2 to 6.

Other preferred embodiments include the compounds capable of generating a sulfonic acid represented by the following general formula (II).

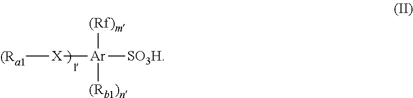

In the general formula (II),

Rf represents a fluorine atom or a fluorine atom-containing organic group.

Each of Rₐ₁ and R_{b1} independently represents an organic group.

Ar represents an aromatic group.

X represents —SO—, —SO₂—, —S—, or —O—.

l′ represents an integer of 0 to 6.

m′ represents an integer of 0 to 5.

n′ represents an integer of 0 to 5.

In the general formula (II), examples of the organic group of Rₐ₁ and R_{b1} include an alkyl group, an aryl group, a cycloalkyl group, an alkoxy group, an aryloxy group, an aralkyl group, an aralkyloxy group, a cycloalkoxy group, an alkoxycarbonyl group, an aryloxycarbonyl group, an acyloxy group, an alkylthio group, an arylthio group, an acyl group, an acylamino group, an alkenyl group, an alkenyloxy group, an arylcarbonyloxy group, an alkylcarbonyloxy group, an alkylaminocarbonyl group, an alkylcarbonylamino group, an alkylsilyloxy group, a cyano group, and the like. A plurality of these organic groups may be bonded via a single bond, an ether bond, an ester bond, an amide bond, a sulfide bond, an urea bond, and the like. The organic group of Rₐ₁ and R_{b1} preferably has 2 to 30 carbon atoms, more preferably 4 to 30 carbon atoms, still more preferably 6 to 30 carbon atoms, and particularly preferably 8 to 24 carbon atoms.

The alkyl group in the organic group of Rₐ₁ and R_{b1} is preferably a linear or branched alkyl group having 1 to 30 carbon atoms.

Examples of the aryl group in the organic group of Rₐ₁ and R_{b1} include a phenyl group, a tolyl group, a mesityl group, a naphthyl group, and the like.

The cycloalkyl group in the organic group of Rₐ₁ and R_{b1} is preferably a monocyclic or polycyclic cycloalkyl group having 3 to 30 carbon atoms.

The alkoxy group in the organic group of Rₐ₁ and R_{b1} is preferably a linear or branched alkoxy group having 1 to 30 carbon atoms.

The aryloxy group in the organic group of Rₐ₁ and R_{b1} is preferably a linear or branched aryloxy group having 6 to 20 carbon atoms.

The aralkyl group in the organic group of Rₐ₁ and R_{b1} is preferably an aralkyl group having 7 to 12 carbon atoms.

The aralkyloxy group in the organic group of Rₐ₁ and R_{b1} is preferably an aralkyloxy group having 6 to 20 carbon atoms.

The cycloalkoxy group in the organic group of Rₐ₁ and R_{b1} is preferably a cycloalkoxy group having 3 to 30 carbon atoms.

The alkoxycarbonyl group in the organic group of Rₐ₁ and R_{b1} is preferably an alkoxycarbonyl group having 1 to 30 carbon atoms.

The aryloxycarbonyl group in the organic group of Rₐ₁ and R_{b1} is preferably an aryloxycarbonyl group having 6 to 20 carbon atoms.

The acyloxy group in the organic group of Rₐ₁ and R_{b1} is preferably an acyloxy group having 1 to 30 carbon atoms.

The alkylthio group in the organic group of Rₐ₁ and R_{b1} is preferably an alkylthio group having 1 to 30 carbon atoms.

The arylthio group in the organic group of Rₐ₁ and R_{b1} is preferably an arylthio group having 6 to 20 carbon atoms.

The acyl group in the organic group of Rₐ₁ and R_{b1} is preferably an acyl group having 1 to 30 carbon atoms.

The acylamino group in the organic group of Rₐ₁ and R_{b1} is preferably an acylamino group having 1 to 30 carbon atoms.

The alkenyl group in the organic group of Rₐ₁ and R_{b1} is preferably an alkenyl group having 1 to 30 carbon atoms.

The alkenyloxy group in the organic group of Rₐ₁ and R_{b1} is preferably an alkenyloxy group having 1 to 30 carbon atoms.

The arylcarbonyloxy group in the organic group of Rₐ₁ and R_{b1} is preferably an arylcarbonyloxy group having 6 to 20 carbon atoms.

The alkylcarbonyloxy group in the organic group of Rₐ₁ and R_{b1} is preferably an alkylcarbonyloxy group having 1 to 30 carbon atoms.

The alkylaminocarbonyl group in the organic group of Rₐ₁ and R_{b1} is preferably an alkylaminocarbonyl group having 1 to 30 carbon atoms.

The alkylcarbonylamino group in the organic group of Rₐ₁ and R_{b1} is preferably an alkylcarbonylamino group having 1 to 30 carbon atoms.

The alkylsilyloxy group in the organic group of Rₐ₁ and R_{b1} preferably has 1 to 30 carbon atoms.

The organic group of Rₐ₁ and R_{b1} as described above may be substituted with a substituent. Examples of the substituent include, but not limited to, an alkyl group, an alkoxy group, a cycloalkyl group, an acyl group, an acyloxy group, a chlorine atom, a bromine atom, an iodine atom, a hydroxyl group, a carboxylic group, and the like.

Furthermore, the alkyl group and the cycloalkyl group contained in the alkyl group, the cycloalkyl group, and alkoxy group, the aralkyloxy group, the cycloalkoxy group, the alkoxycarbonyl group, the acyloxy group, the alkylthio group, the acyl group, and the acylamino group of Rₐ₁ and R_{b1} may have one or two or more linking groups such as an oxygen atom, a sulfur atom, an ester group, and the like in the alkyl chain and the cycloalkyl chain.

Examples of the preferable Rₐ₁ and R_{b1} include an alkyl group, an aryl group, a cycloalkyl group, alkoxy, an aryloxy group, an aralkyl group, an aralkyloxy group, a cycloalkoxy group, an alkylthio group, an arylthio group, an acyl group, an acylamino group, an alkenyl group, an alkenyloxy group, an arylcarbonyloxy group, an alkylcarbonyloxy group, an alkylcarbonylamino group, an alkylsilyloxy group, and the like. Examples of the preferable Rₐ₁ and R_{b1} include an alkyl group, an aryl group, a cycloalkyl group, an alkoxy group, an aryloxy group, an aralkyl group, an aralkyloxy group, a cycloalkoxy group, an alkylthio group, an arylthio group, an acyl group, an acylamino group, an alkenyl group, an alkenyloxy group, an arylcarbonyloxy group, and an alkylcarbonylamino group, and more preferably an alkyl group, an aryl group, a cycloalkyl group, an alkoxy group, an aryloxy group, an aralkyl group, an aralkyloxy group, a cycloalkoxy group, an acylamino group, an alkenyl group, an alkenyloxy group, an arylcarbonyloxy group, and an alkylcarbonylamino group.

In the case where l′ and n′ are each an integer of 2 or more, a plurality of Rₐ₁ and R_{b1} may be the same as or different from each other.

Rf represents a fluorine atom or a fluorine atom-containing organic group, and examples of the fluorine atom-containing organic group include those in which a part or all of the hydrogen atoms of the organic group in Rₐ₁ and R_{b2} are substituted with fluorine atoms. In the case where m′ is 2 or more, a plurality of Rf's may be the same as or different from each other.

The total number of carbon atoms of Rf, Rₐ₁ and R_{b1} is preferably from 4 to 34, more preferably from 6 to 30, and still more preferably from 8 to 24. Adjustment of the number of carbon atoms of Rf, Rₐ₁ and R_{b1} enables adjustment of diffusivity of an acid, and thus improvement of resolution.

The aromatic group of Ar is preferably an aromatic group having 6 to 20 carbon atoms, and examples thereof include a phenyl group, a naphthyl group, and the like. The aromatic group may further contain a substituent. Examples of the further preferred substituent of the aromatic group include a nitro group, a sulfonlyamino group, a chlorine atom, a bromine atom, an iodine atom, carboxy, and the like.

l′ is preferably from 0 to 3, more preferably from 0 to 2, and still more preferably 1 or 2.

n′ is preferably from 0 to 3, more preferably from 0 to 2, and still more preferably 0 or 1.

m′ is preferably from 2 to 5, more preferably 3 or 4, and still more preferably 4.

The sulfonic acid represented by the general formula (II) is preferably represented by the following general formula (IIa), more preferably represented by the general formula (IIb), and still more preferably represented by the general formula (IIc). Here, Rₐ₁, Rf, X, l′, m′, and n′ have the same meaning as Rₐ₁, Rf, X, l′, m′, and n′ in the general formula (II). R has the same meaning as Rₐ₁.

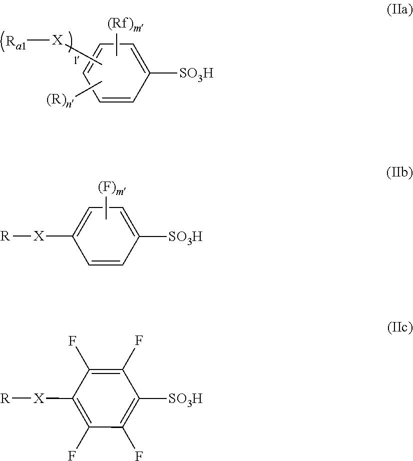

The compound capable of generating a sulfonic acid represented by the general formula (I), (I′) or (II) upon irradiation with an actinic ray or radiation is preferably at least one selected from a sulfonium salt compound and an iodonium salt compound represented by the general formula (I), (I′) or (II), or at least one selected from the ester compounds of the sulfonic acids represented by the general formula (I), (I′), or (II), and still more preferably a compound represented by the general formulae (B1) to (B5).

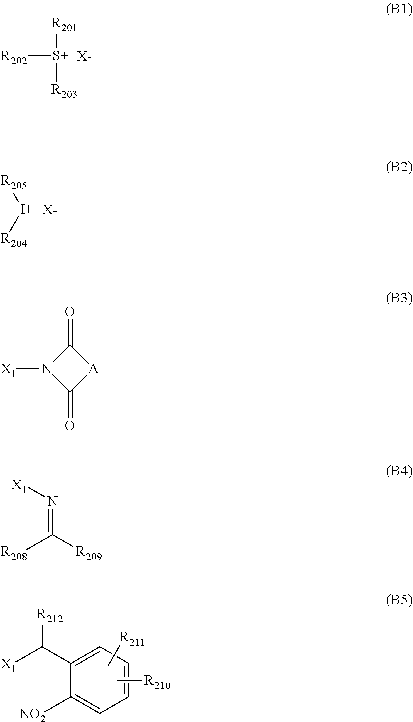

In the general formula (B1), each of R₂₀₁, R₂₀₂, and R₂₀₃ independently represents an organic group.

X⁻ represents an anion of the sulfonic acid in which a hydrogen atom of a sulfonic acid (—SO₃H) of the general formula (I), (I′), or (II) leaves.

Specific examples and preferable examples of the organic group as R₂₀₁, R₂₀₂, and R₂₀₃ are the same as cited above with respect to R₂₀₁, R₂₀₂, and R₂₀₃ in the general formula (ZI).

In the general formula (B2), each of R₂₀₄ and R₂₀₅ independently represents an aryl group, an alkyl group, or a cycloalkyl group.

X⁻ represents an anion of the sulfonic acid in which a hydrogen atom of a sulfonic acid (—SO₃H) of the general formula (I), (I′), or (II) leaves.

R₂₀₄ and R₂₀₅ in the general formula (B2) are the same as described above as R₂₀₄ and R₂₀₅ in the general formula (ZII).

In the general formula (B3), A represents a substituted or unsubstituted alkylene group, alkenylene group, or allylene group.

X₁ represents a mono-valent group in which a hydrogen atom of a sulfonic acid (—SO₃H) of the general formula (I), (I′), or (II) leaves.

In the general formula (B4), R₂₀₈ represents a substituted or unsubstituted alkyl group, cycloalkyl group, or aryl group.

R₂₀₉ represents an alkyl group, a cyano group, an oxoalkyl group, or an alkoxycarbonyl group, and preferably a halogen substituted alkyl group or a cyano group.

X₁ represents a mono-valent group in which a hydrogen atom of a sulfonic acid (—SO₃H) of the general formula (I), (I′), or (II) leaves.

In the general formula (B5), each of R₂₁₀ and R₂₁₁ independently represents a hydrogen atom, an alkyl group, a cyano group, a nitro group, or an alkoxycarbonyl group, and preferably a halogen-substituted alkyl group, a nitro group, or a cyano group.

R₂₁₂ represents a hydrogen atom, an alkyl group, a cyano group, or an alkoxycarbonyl group.

X₁ represents a mono-valent group in which a hydrogen atom of a sulfonic acid (—SO₃H) of the general formula (I), (I′), or (II) leaves.

A compound represented by the general formula (B1) is preferred, and a compound represented by the general formulae (B1a) to (B1c) is more preferred.

The compound (B) preferably has a triphenylsulfonium structure.

The compound (B) is preferably a triphenylsulfonium salt compound having an alkyl group or a cycloalkyl group which has no fluorine substitution in the cation moiety.

Preferable examples of the compound (B) generating an acid upon irradiation with an actinic ray or radiation include the followings, but the present invention is not limited thereto.

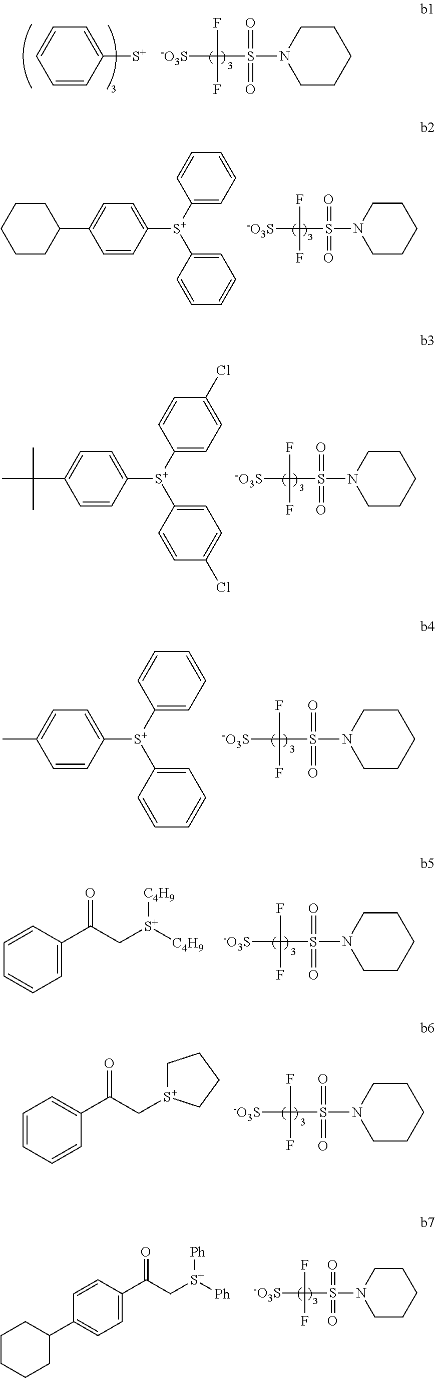

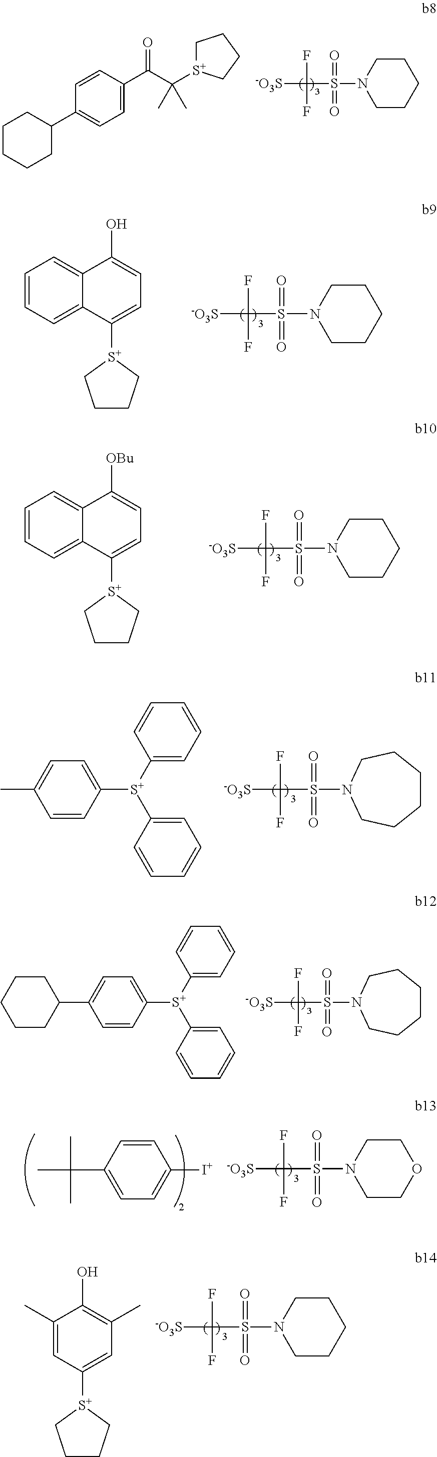

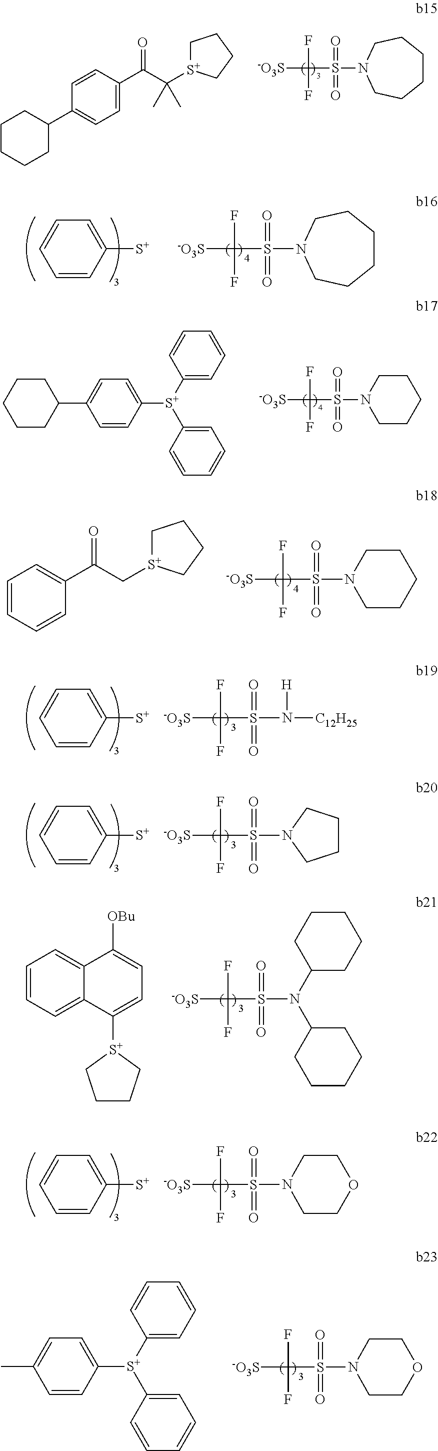

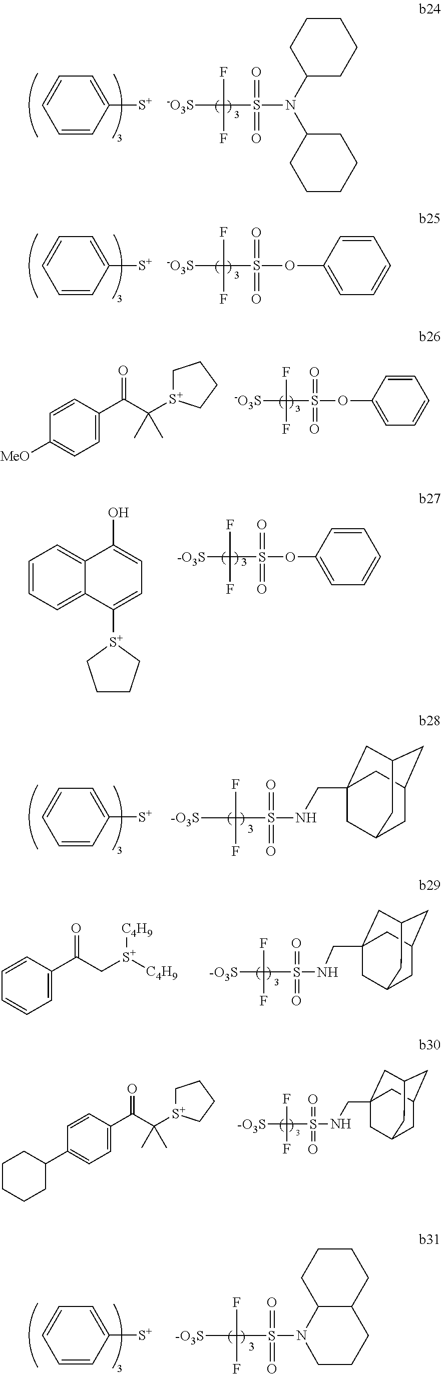

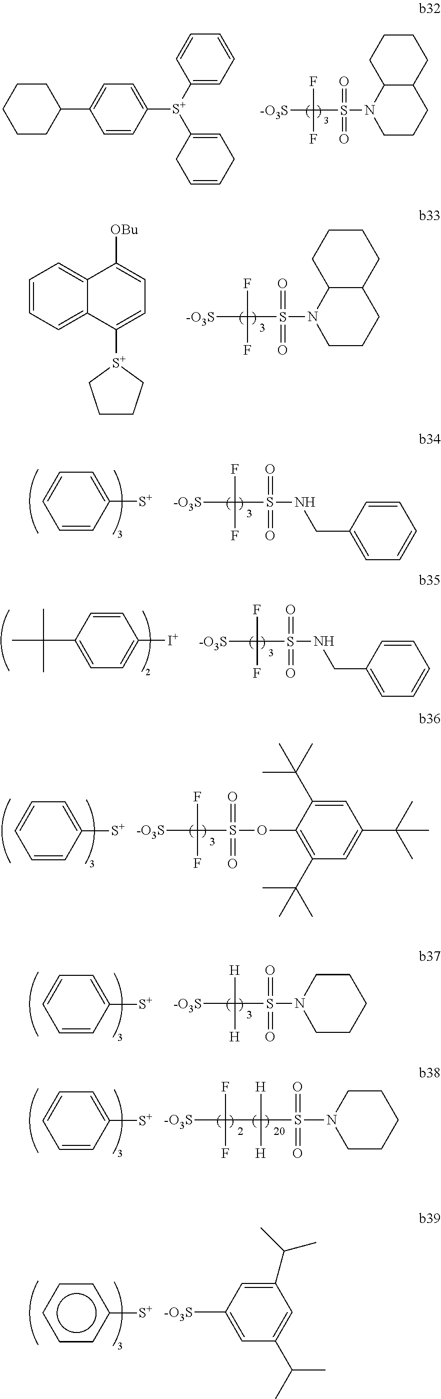

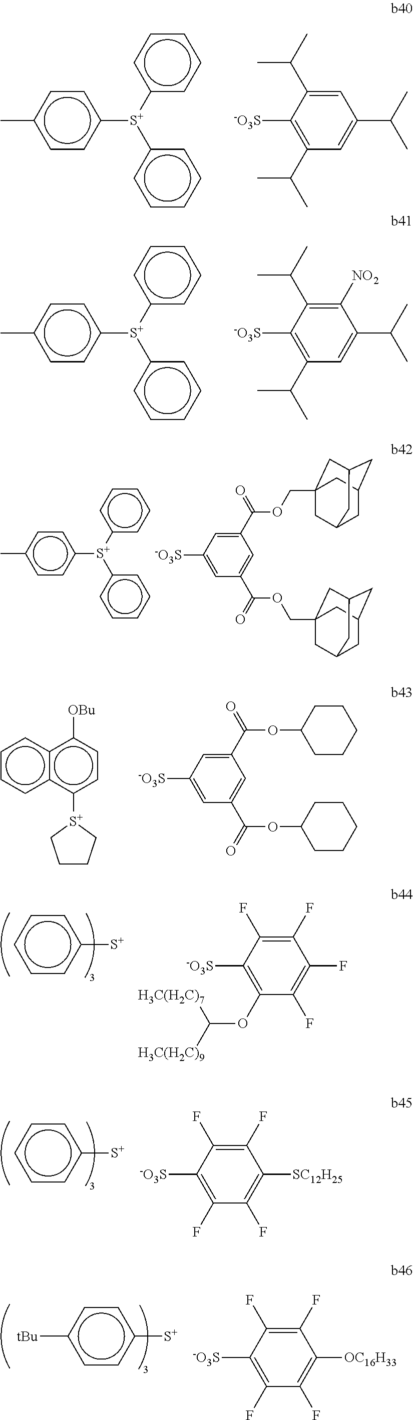

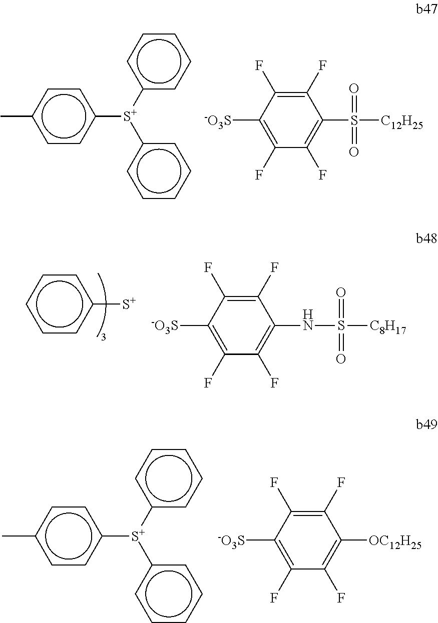

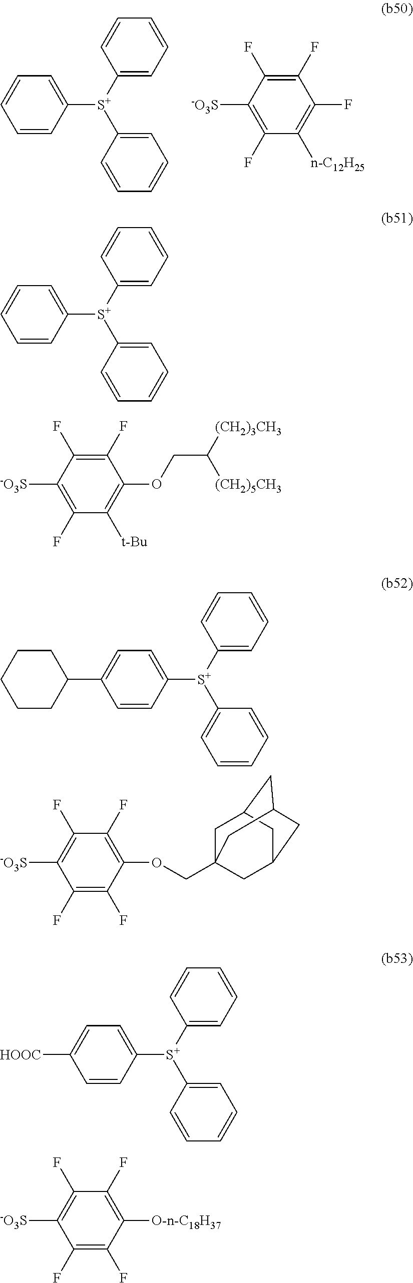

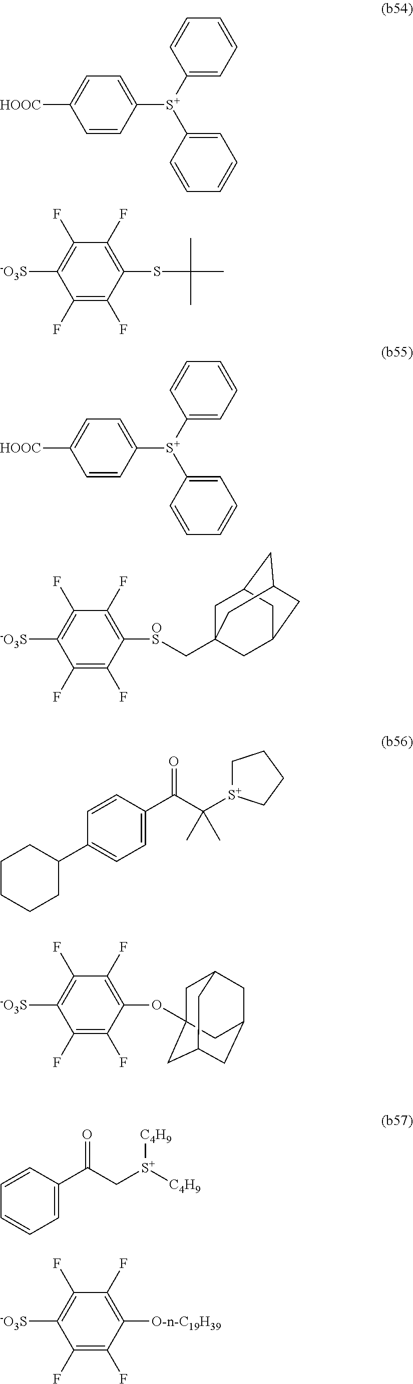

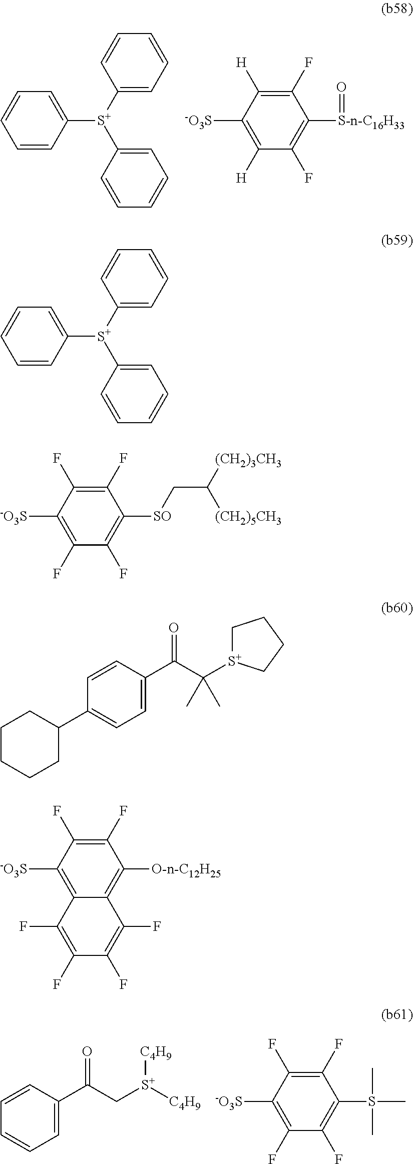

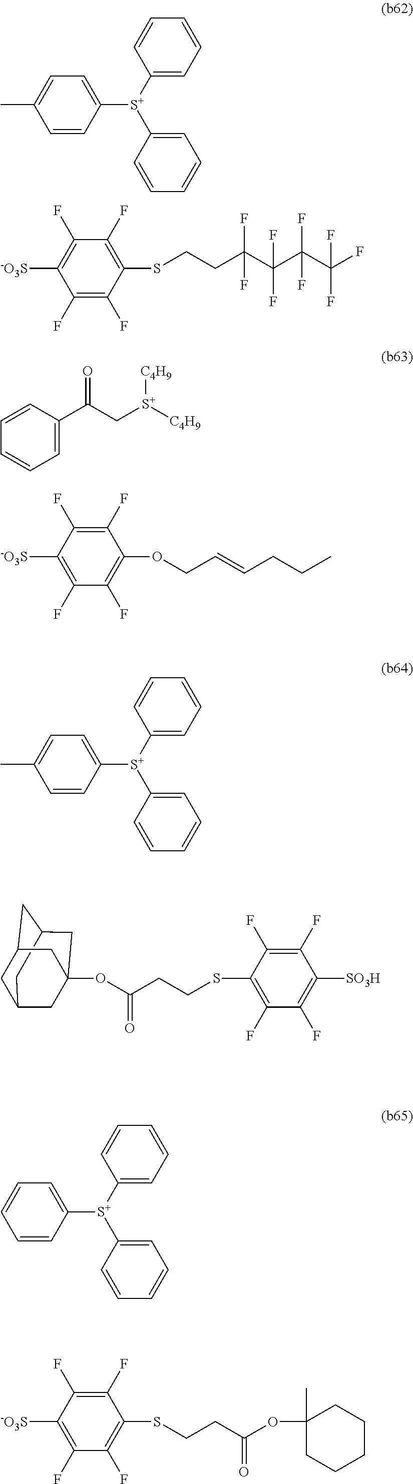

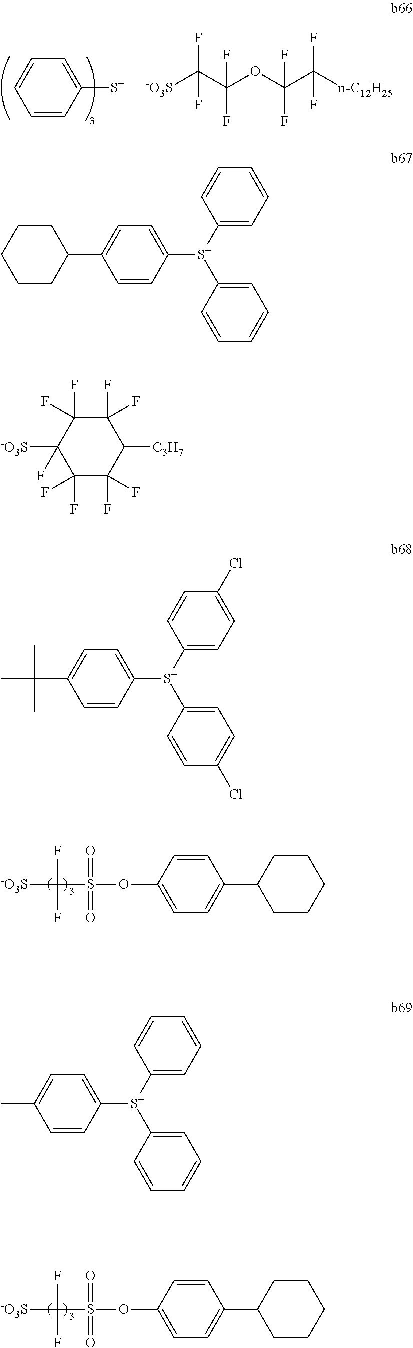

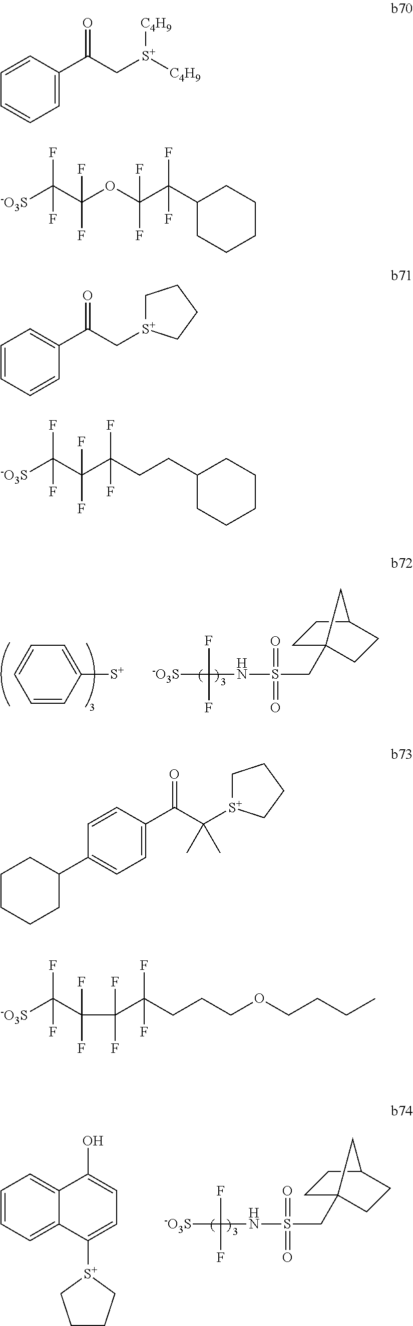

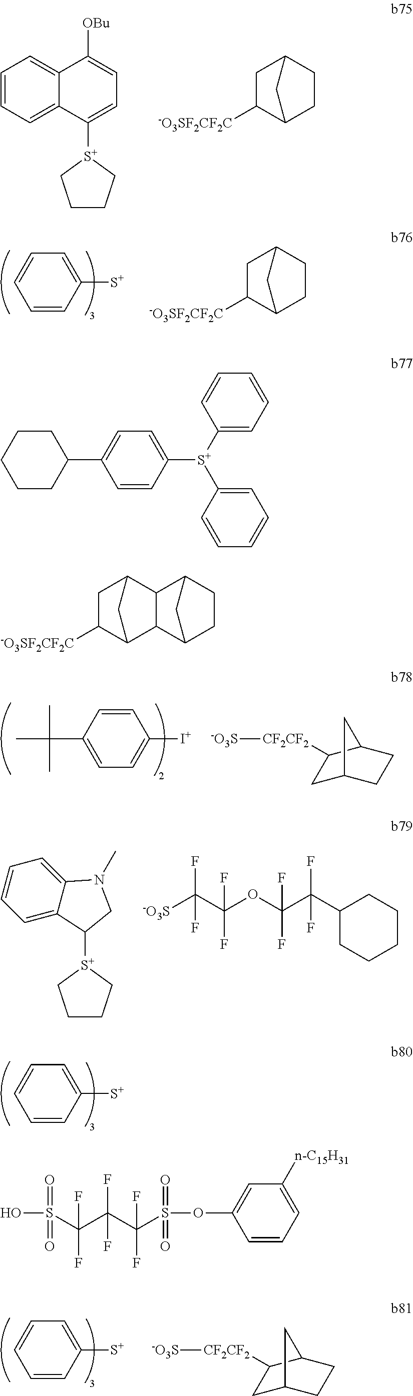

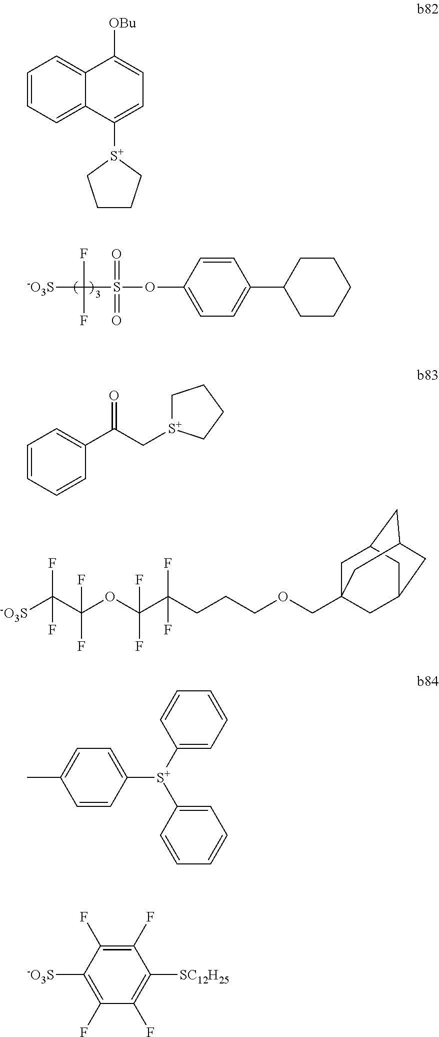

When using a combination of two or more kinds, the compound (B) and another acid generator may be used in combination.

The amount of the acid generator in the case of using a combination of two or more kinds is, in terms of the molar ratio (compound (B)/another acid generator), usually from 99/1 to 20/80, preferably from 99/1 to 40/60, and still more preferably from 99/1 to 50/50.

The acid generator which can be used in combination may be appropriately selected from a photo-initiator for photocationic polymerization, a photo-initiator for photoradical polymerization, a photodecoloring agent for dyes, a photodiscoloring agent, a compound known to generate an acid upon irradiation with an actinic ray or radiation, which is used for a microresist or the like, and a mixture thereof.

Examples thereof include a diazonium salt, a phosphonium salt, a sulfonium salt, an iodonium salt, an imidosulfonate, an oxime sulfonate, a diazodisulfone, a disulfone, and an o-nitrobenzyl sulfonate.

(C) Solvent

Examples of the solvent which can be used to dissolve the above components to prepare a resist composition include organic solvents such as alkylene glycol monoalkyl ether carboxylate, alkylene glycol monoalkyl ether, alkyl lactate, alkyl alkoxypropionate, cyclic lactone (preferably having 4 to 10 carbon atoms), a monoketone compound (preferably having 4 to 10 carbon atoms) which may contain a ring, alkylene carbonate, alkyl alkoxyacetate, alkyl pyruvate, and the like.

Specific examples of these solvents include those as set forth in [0244] to [0249] of JP-A-2008-292975.

The solvent is preferably a mixed solvent of two or more kinds, including propylene glycol monomethyl ester acetate (PGMEA, also called 1-methoxy-2-acetoxypropane).

(D) Resin Having at Least Either One of a Fluorine Atom and a Silicon Atom

The resist composition of the present invention preferably contains (D) a resin having at least either one of a fluorine atom and a silicon atom.

The fluorine atom or silicon atom of the resin (D) may be present in the main chain of the resin or may be substituted to the side chain thereof.

The hydrophobic resin (D) is preferably a resin having a fluorine atom-containing alkyl group, a fluorine atom-containing cycloalkyl group or a fluorine atom-containing aryl group, as a fluorine atom-containing partial structure.

The fluorine atom-containing alkyl group (preferably having 1 to 10 carbon atoms, and more preferably 1 to 4 carbon atoms) is a linear or branched alkyl group in which at least one hydrogen atom is substituted by a fluorine atom, and may further have another substituent.

The fluorine atom-containing cycloalkyl group is a monocyclic or polycyclic cycloalkyl group in which at least one hydrogen atom is substituted by a fluorine atom, and may further have another substituent.

The fluorine atom-containing aryl group is an aryl group such as a phenyl group, a naphthyl group, and the like, in which at least one hydrogen atom is substituted by a fluorine atom, and may further have another substituent.

Next, specific examples of a fluorine atom-containing alkyl group, a fluorine atom-containing cycloalkyl group, or a fluorine atom-containing aryl group will be presented, but the present invention is not limited thereto.

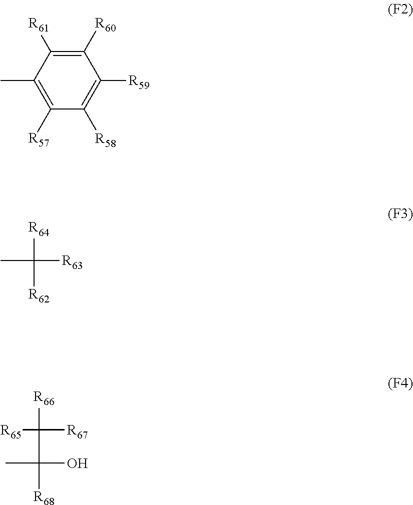

In the general formulae (F2) to (F4),

each of R₅₇ to R₆₈ independently represents a hydrogen atom, a fluorine atom, or an alkyl group, provided that at least one of R₅₇ to R₆₁, at least one of R₆₂ to R₆₄ and at least one of R₆₅ to R₆₈ are a fluorine atom or an alkyl group (preferably having 1 to 4 carbon atoms) in which at least one hydrogen atom is substituted by a fluorine atom. It is preferred that R₅₇ to R₆₁ and R₆₅ to R₆₇ all are a fluorine atom. R₆₂, R₆₃, and R₆₈ each is preferably an alkyl group (preferably having 1 to 4 carbon atoms) in which at least one hydrogen atom is substituted by a fluorine atom, more preferably a perfluoroalkyl group having 1 to 4 carbon atoms. R₆₂ and R₆₃ may combine with each other to form a ring.

Specific examples of the group represented by the general formula (F2) include a p-fluorophenyl group, a pentafluorophenyl group, a 3,5-di(trifluoromethyl)phenyl group, and the like.

Specific examples of the group represented by the general formula (F3) include trifluoroethyl group, a pentafluoropropyl group, a pentafluoroethyl group, a heptafluorobutyl group, a hexafluoro-isopropyl group, a heptafluoroisopropyl group, a hexafluoro(2-methyl)isopropyl group, a nonafluorobutyl group, an octafluoroisobutyl group, a nonafluorohexyl group, a nonafluoro-tert-butyl group, a perfluoroisopentyl group, a perfluorooctyl group, a perfluoro(trimethyl)hexyl group, a 2,2,3,3-tetrafluorocyclobutyl group, a perfluorocyclohexyl group, and the like. A hexafluoroisopropyl group, a heptafluoroisopropyl group, a hexafluoro(2-methyl)isopropyl group, an octafluoroisobutyl group, a nonafluoro-tert-butyl group, and a perfluoroisopentyl group are preferred, and a hexafluoroisopropyl group and a heptafluoroisopropyl group are more preferred.

Specific examples of the group represented by formula (F4) include —C(CF₃)₂OH, —C(C₂F₅)₂OH, —C(CF₃)(CH₃)OH, —CH(CF₃)OH, and the like, with —C(CF₃)₂OH being preferred.

The resin (D) is preferably a resin having an alkylsilyl structure (preferably a trialkylsilyl group) or a cyclic siloxane structure, as a silicon atom-containing partial structure.

Specific examples of the alkylsilyl structure and the cyclic siloxane structure include the groups represented by the following general formulae (CS-1) to (CS-3), and the like.

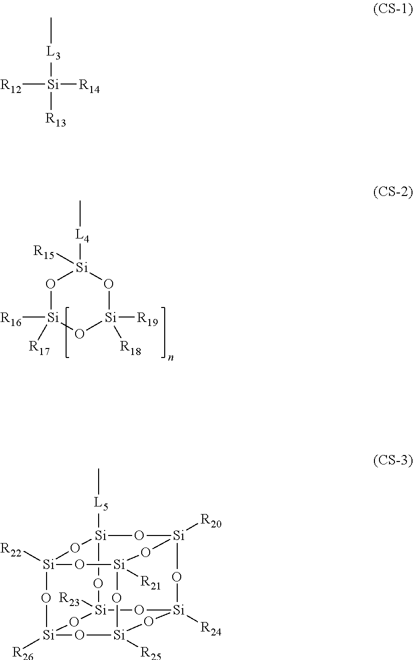

In the general formulae (CS-1) to (CS-3),

each of R₁₂ to R₂₆ independently represents a linear or branched alkyl group (preferably having 1 to 20 carbon atoms) or a cycloalkyl group (preferably having 3 to 20 carbon atoms).

L₃ to L₅ represent a single bond or a divalent linking group. Examples of the divalent linking group include a sole group or a combination of two or more groups selected from the group consisting of an alkylene group, a phenyl group, an ether group, a thioether group, a carbonyl group, an ester group, an amide group, a urethane group, and an urea group.

n represents an integer of 1 to 5.

As the resin (D), a resin having at least one repeating units selected from the group consisting of the repeating units represented by the following general formulae (C-I) to (C-V) can be mentioned.

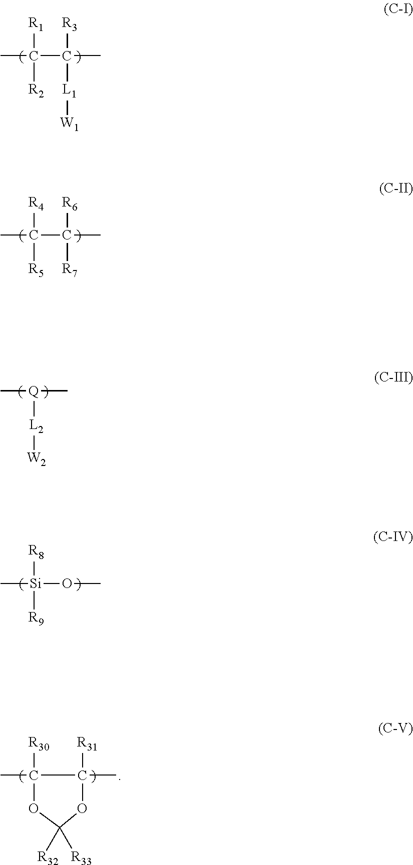

In the general formulae (C-I) to (C-V),

each of R₁ to R₃ independently represents a hydrogen atom, a fluorine atom, a linear or branched alkyl group (preferably having 1 to 4 carbon atoms), or a linear or branched fluorinated alkyl group (preferably having 1 to 4 carbon atoms).

Each of W₁ and W₂ independently represents an organic group having at least either one of a fluorine atom and a silicon atom.

Each of R₄ to R₇ independently represents a hydrogen atom, a linear or branched alkyl group (preferably having 1 to 4 carbon atoms), or a linear or branched fluorinated alkyl group (preferably having 1 to 4 carbon atoms), provided that at least one of R₄ to R₇ represents a fluorine atom. R₄ and R₅ or R₆ and R₇ may be combined with each other to form a ring.

R₈ represents a hydrogen atom or a linear or branched alkyl group (preferably having 1 to 4 carbon atoms).

R₉ represents a linear or branched alkyl group (preferably having 1 to 4 carbon atoms) or a linear or branched fluoroalkyl group (preferably having 1 to 4 carbon atoms).

Each of L₁ and L₂ independently represents a single bond or a divalent linking group, which is the same as L₃ to L₅.

Q represents a monocyclic or polycyclic aliphatic group. That is, it represents an atomic group containing two carbon atoms bonded to each other (C—C) to form an alicyclic structure.

Each of R₃₀ and R₃₁ independently represents a hydrogen atom or a fluorine atom.

Each of R₃₂ and R₃₃ independently represents an alkyl group, a cycloalkyl group, a fluoroalkyl group, or a fluorocycloalkyl group,

provided that the repeating unit represented by the general formula (C-V) has at least one fluorine atom in at least one of R₃₀, R₃₁, R₃₂, and R₃₃.

The resin (D) preferably has a repeating unit represented by the general formula (C-I), and more preferably a repeating unit represented by any of the following general formulae (C-Ia) to (C-Id).

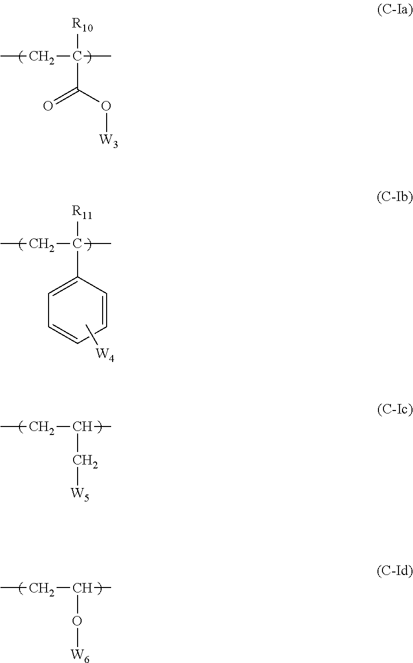

In the general formulae (C-Ia) to (C-Id),

R₁₀ and R₁₁ represent a hydrogen atom, a fluorine atom, a linear or branched alkyl group (preferably having 1 to 4 carbon atoms), or a linear or branched fluorinated alkyl group (preferably having 1 to 4 carbon atoms).

W₃ to W₆ represent an organic group having at least either one of a fluorine atom and a silicon atom.

In the case where W₁ to W₆ are a fluorine atom-containing organic group, a linear or branched fluorinated alkyl group (preferably having 1 to 20 carbon atoms), a fluorinated cycloalkyl group (preferably having 3 to 20 carbon atoms), or a linear, branched, or cyclic fluorinated alkyl ether group (preferably having 1 to 20 carbon atoms) are preferred.

Examples of the fluoroalkyl group represented by W₁ to W₆ include a trifluoroethyl groups a pentafluoropropyl group, a hexafluoroisopropyl group, a hexafluoro(2-methyl)isopropyl group, a heptafluorobutyl group, a heptafluoroisopropyl group, an octafluoroisobutyl group, a nonafluorohexyl group, a nonafluoro-t-butyl group, a perfluoroisopentyl group, a perfluorooctyl group, a perfluoro(trimethyl)hexyl group, and the like.

In the case where W₁ to W₆ are a silicon atom-containing organic group, the groups having an alkylsilyl structure or a cyclic siloxane structure are preferred. Specific examples thereof include those groups represented by the general formulae (CS-1) to (CS-3), and the like.

Next, specific examples of the repeating unit represented by the general formula (C-1) will be presented, but the present invention is not limited thereto. In the formulae, X represents a hydrogen atom, —CH₃, —F, or —CF₃.

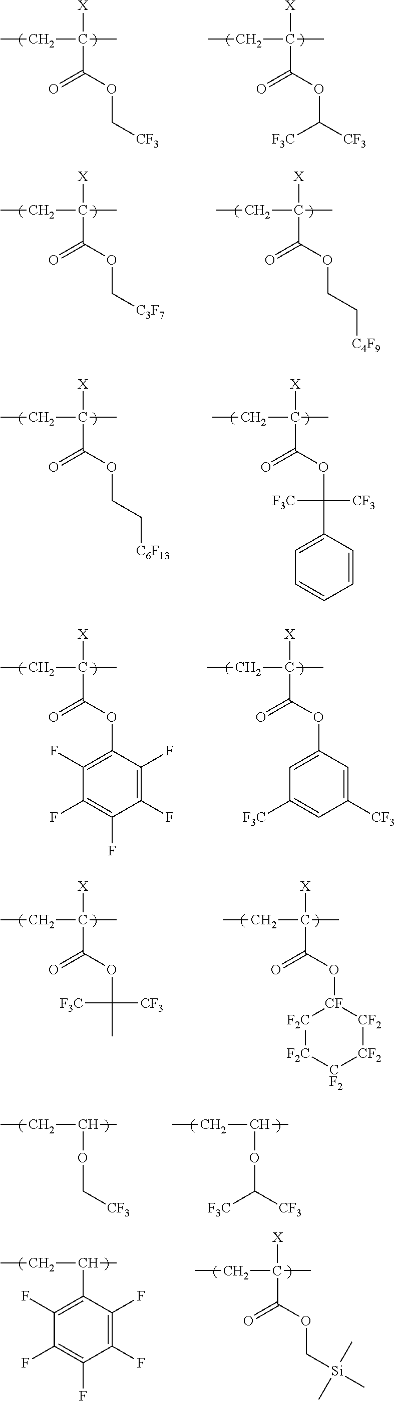

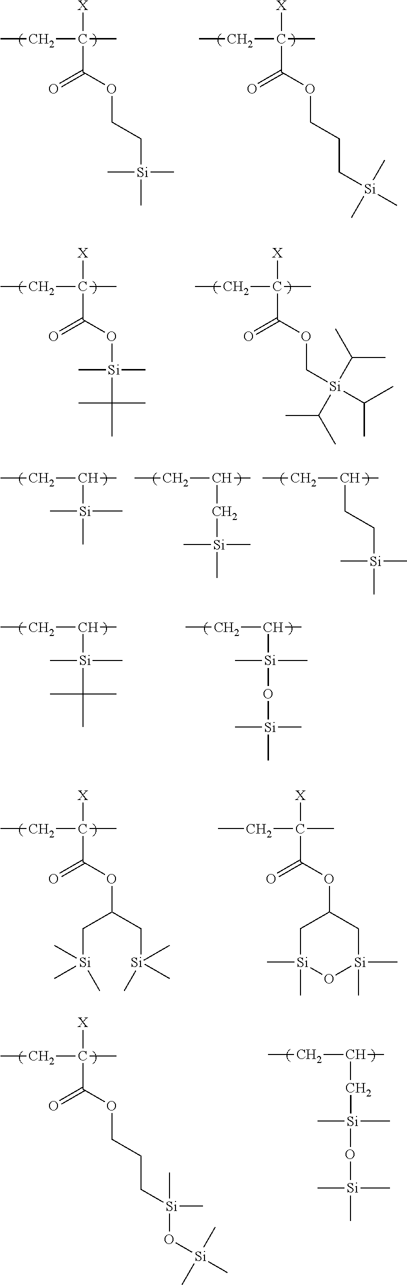

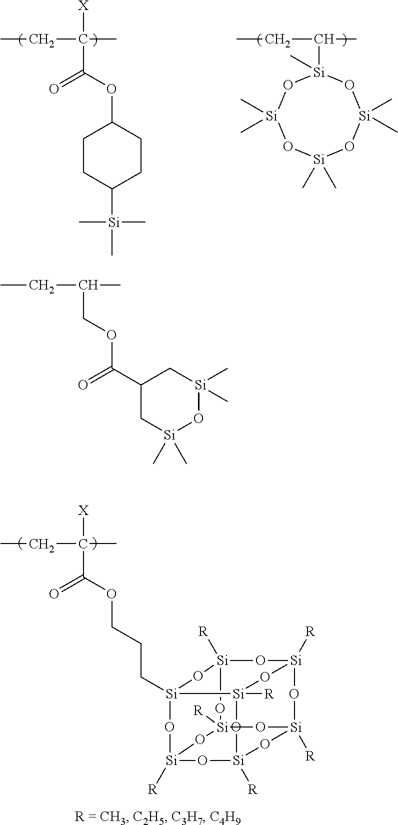

The resin (D) is preferably any one resin selected from the following (D-1) to (D-6).

(D-1) A resin containing (a) a repeating unit having a fluoroalkyl group (preferably having 1 to 4 carbon atoms), and more preferably containing only the repeating unit (a).

(D-2) A resin containing (b) a repeating unit having a trialkylsilyl group or a cyclic siloxane structure, and more preferably containing only the repeating unit (b).

(D-3) A resin containing (a) a repeating unit having a fluoroalkyl group (preferably having 1 to 4 carbon atoms) and (c) a repeating unit having a branched alkyl group (preferably having 4 to 20 carbon atoms), a cycloalkyl group (preferably having 4 to 20 carbon atoms), a branched alkenyl group (preferably having 4 to 20 carbon atoms), a cycloalkenyl group (preferably having 4 to 20 carbon atoms), or an aryl group (preferably having 4 to 20 carbon atoms), and more preferably a copolymerization resin of the repeating unit (a) and the repeating unit (c).

(D-4) A resin containing (b) a repeating unit having a trialkylsilyl group or a cyclic siloxane structure and (c) a repeating unit having a branched alkyl group (preferably having 4 to 20 carbon atoms), a cycloalkyl group (preferably having 4 to 20 carbon atoms), a branched alkenyl group (preferably having 4 to 20 carbon atoms), a cycloalkenyl group (preferably having 4 to 20 carbon atoms), or an aryl group (preferably having 4 to 20 carbon atoms), and more preferably a copolymerization resin of the repeating unit (b) and the repeating unit (c).

(D-5) A resin containing (a) a repeating unit having a fluoroalkyl group (preferably having 1 to 4 carbon atoms) and (b) a repeating unit having a trialkylsilyl group or a cyclic siloxane structure, more preferably a copolymerization resin of the repeating unit (a) and the repeating unit (b).

(D-6) A resin containing (a) a repeating unit having a fluoroalkyl group (preferably having 1 to 4 carbon atoms), (b) a repeating unit having a trialkylsilyl group or a cyclic siloxane structure, and (c) a repeating unit having a branched alkyl group (preferably having 4 to 20 carbon atoms), a cycloalkyl group (preferably having 4 to 20 carbon atoms), a branched alkenyl group (preferably having 4 to 20 carbon atoms), a cycloalkenyl group (preferably having 4 to 20 carbon atoms) or an aryl group (preferably having 4 to 20 carbon atoms), more preferably a copolymerization resin of the repeating unit (a), the repeating unit (b) and the repeating unit (c).

As the repeating unit (c) having a branched alkyl group, a cycloalkyl group, a branched alkenyl group, a cycloalkenyl group or an aryl group in the resins (D-3), (D-4), and (D-6) included, an appropriate functional group can be introduced while considering the hydrophilicity/hydrophobicity, the interaction, and the like. From the standpoints of the followability for the immersion liquid and a receding contact angle, a functional group having no polar group is preferred.

In the resins (D-3), (D-4), and (D-6), the content of the repeating unit (a) having a fluoroalkyl group and/or the repeating unit (b) having a trialkylsilyl group or a cyclic siloxane structure is preferably from 20 to 99% by mol.

The resin (D) is preferably a resin having a repeating unit represented by the following general formula (Ia).

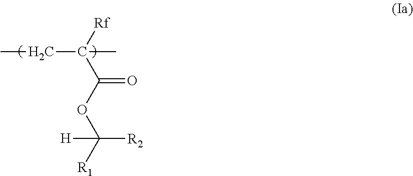

In the general formula (Ia),

Rf represents a fluorine atom or an alkyl group in which at least one hydrogen atom is substituted by a fluorine atom.

R₂ represents an alkyl group.

R₂ represents a hydrogen atom or an alkyl group.

In the general formula (Ia), the alkyl group in which at least one hydrogen atom of Rf is substituted by a fluorine atom is preferably one having 1 to 3 carbon atoms, and more preferably a trifluoromethyl group.

The alkyl group of R₁ is preferably a linear or branched alkyl group having 3 to 10 carbon atoms, and more preferably a branched alkyl group having 3 to 10 carbon atoms.

The alkyl group of R₂ is preferably a linear or branched alkyl group having 1 to 10 carbon atoms, and more preferably a linear or branched alkyl group having 3 to 10 carbon atoms.

Next, specific examples of the repeating unit represented by the general formula (Ia) will be presented, but the present invention is not limited thereto.

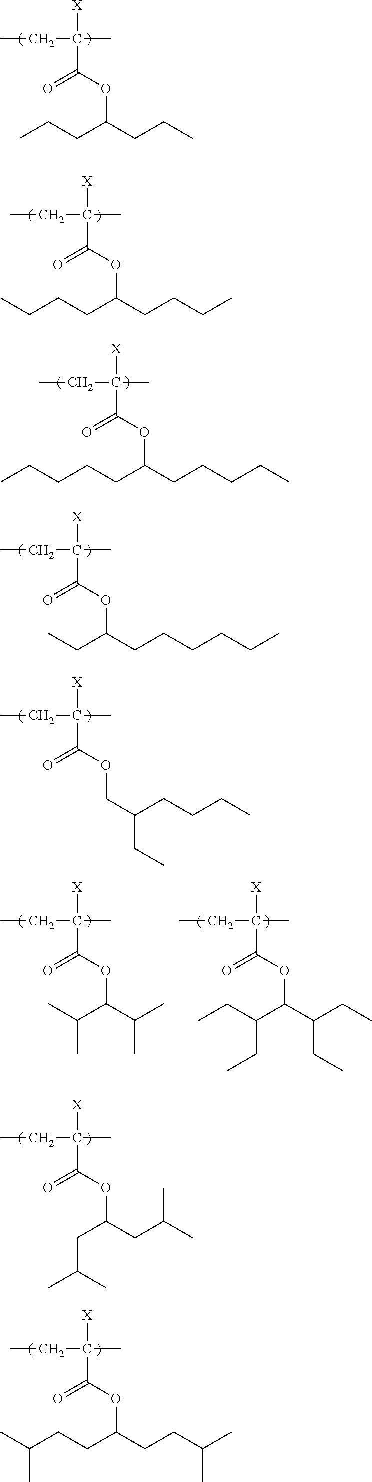

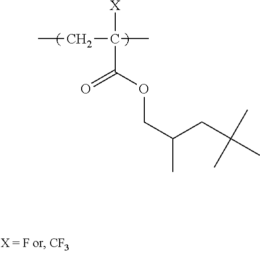

The repeating unit represented by the general formula (Ia) can be formed by polymerizing a compound represented by the following general formula (If).

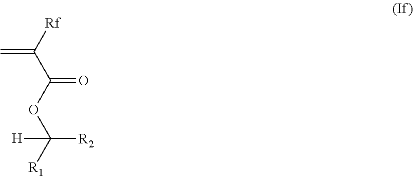

In the general formula (If),

Rf represents a fluorine atom or an alkyl group in which at least one hydrogen atom is substituted by a fluorine atom.

R₁ represents an alkyl group.

R₂ represents a hydrogen atom or an alkyl group.

In the general formula (10,

Rf, R₁, and R₂ have the same meanings as Rf, R₁, and R₂ in the general formula (Ia).

As the compound represented by the general formula (If), use can be made of a commercially available product or a synthesized product.

In the case of synthesizing the compound, this can be attained by converting 2-trifluoromethyl methacrylic acid into an acid chloride, and then esterifying the acid chloride.

The resin (D) having the repeating unit represented by the general formula (Ia) preferably further contains a repeating unit represented by the following general formula (IIIF).

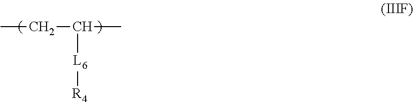

In the general formula (IIIF),

R₄ represents an alkyl group, a cycloalkyl group, an alkenyl group, a cycloalkenyl group, a trialkylsilyl group, or a group having a cyclic siloxane structure.

L₆ represents a single bond or a divalent linking group.

In the general formula (IIIF),

the alkyl group of R₄ is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The trialkylsilyl group is preferably a trialkylsilyl group having 3 to 20 carbon atoms.

The group having a cyclic siloxane structure is preferably a group containing a cyclic siloxane structure having 3 to 20 carbon atoms.

The divalent linking group of L₆ is preferably an alkylene group (preferably having 1 to 5 carbon atoms) or an oxy group.

Next, specific examples of the resin (D) having a repeating unit represented by the general formula (Ia) will be presented, though the present invention is not limited thereto.

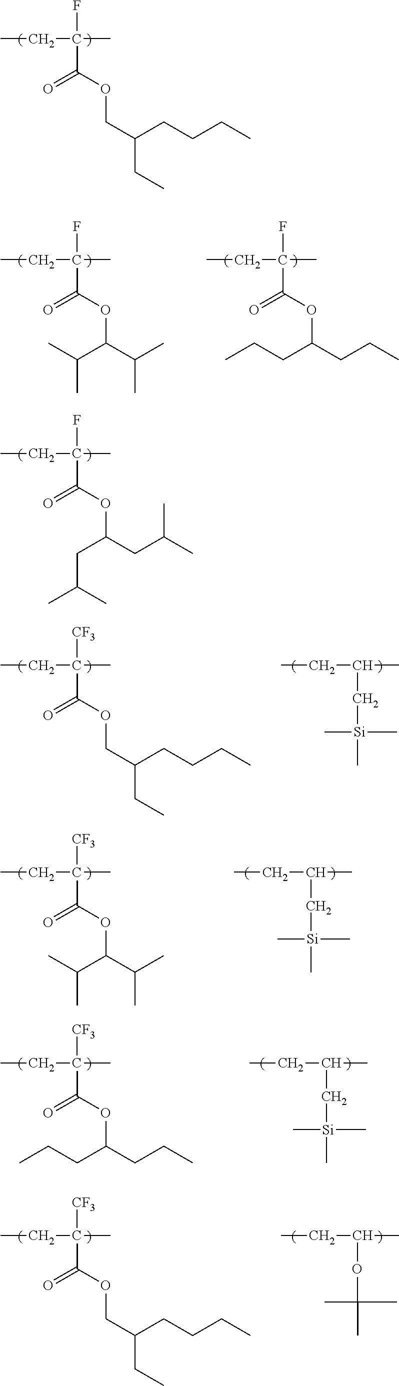

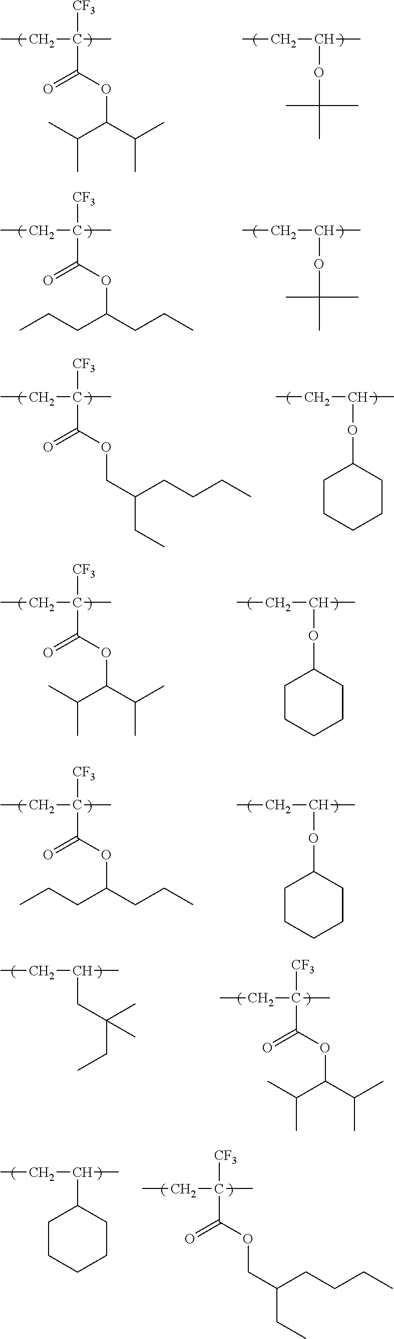

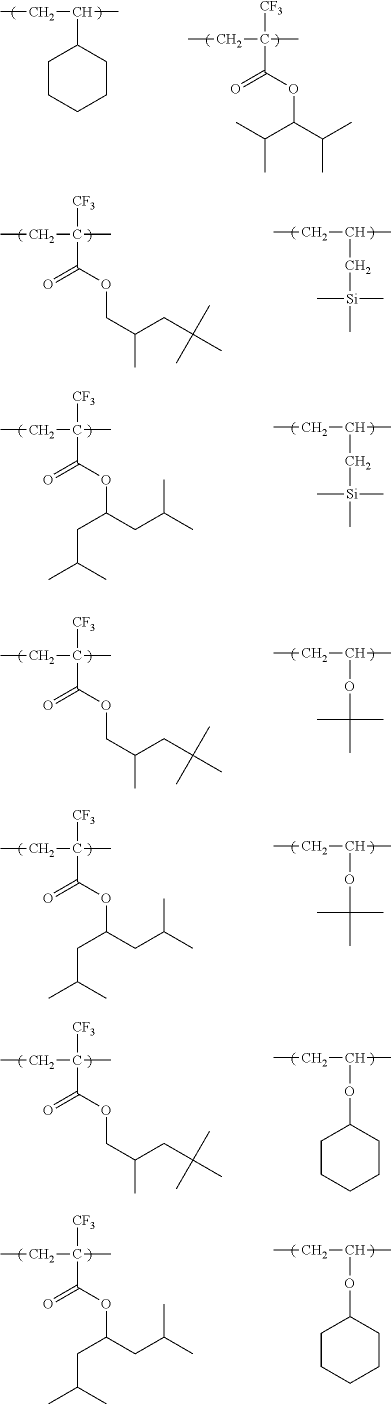

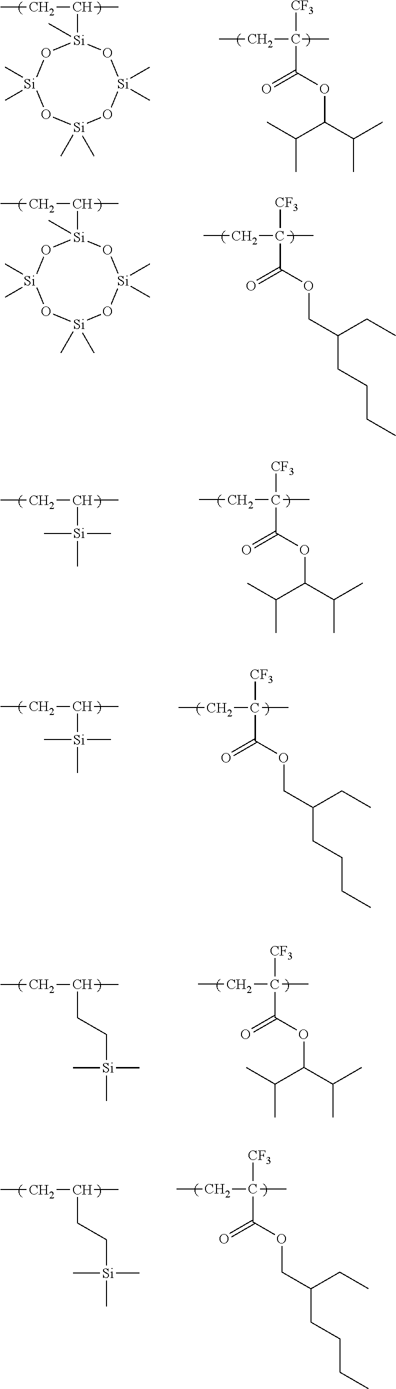

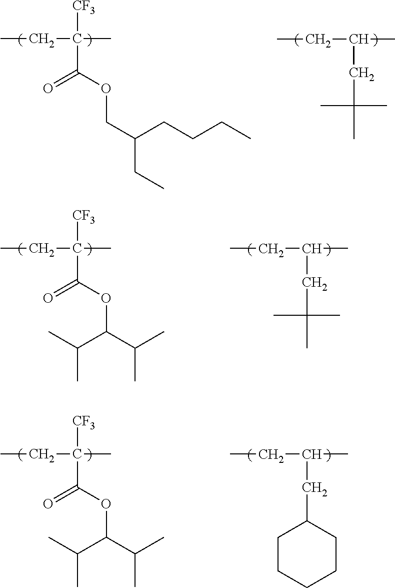

The resin (D) is preferably a resin containing a repeating unit represented by the following general formula (IIF) and a repeating unit represented by the following general formula (IIIF).

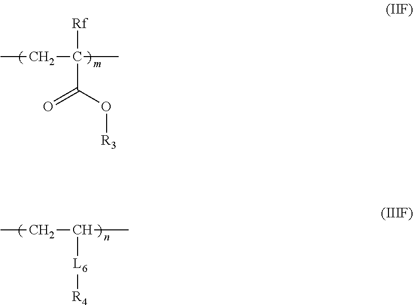

In the general formulae (IIF) and (IIIF),

Rf represents a fluorine atom or an alkyl group in which at least one hydrogen atom is substituted by a fluorine atom.

R₃ represents an alkyl group, a cycloalkyl group, an alkenyl group or a cycloalkenyl group, or a group formed by two or more of these groups bonded together.

R₄ represents an alkyl group, a cycloalkyl group, an alkenyl group, a cycloalkenyl group, a trialkylsilyl group or a group having a cyclic siloxane structure, or a group formed by two or more of these groups bonded together.

L₆ represents a single bond or a divalent linking group.

m and n each represent the molar ratio of the repeating units, provided that 0<m<100 and 0<n<100.

In the general formula (IIF), Rf has the same meaning as Rf in the general formula (Ia).

The alkyl group of R₃ and R₄ is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The trialkylsilyl group of R₄ is a trialkylsilyl group having 3 to 20 carbon atoms.

The group having a cyclic siloxane structure is preferably a group containing a cyclic siloxane structure having 3 to 20 carbon atoms.

The alkyl group, the cycloalkyl group, the alkenyl group, the cycloalkenyl group, and the trialkylsilyl group of R₃ and R₄ may have a functional group having been introduced thereinto. However, in view of followability of the immersion liquid, the functional group is preferably free of a polar group, and more preferably unsubstituted.

L₆ represents a single bond, a methylene group, an ethylene group, or an ether group.

It is preferable that m=30 to 70 and n=30 to 70, and it is more preferable that m=40 to 60 and n=40 to 60.

Next, specific examples of the resin (D) having a repeating unit represented by the general formula (IIF) and a repeating unit represented by the general formula (IIIF) will be presented, but the present invention is not limited thereto.

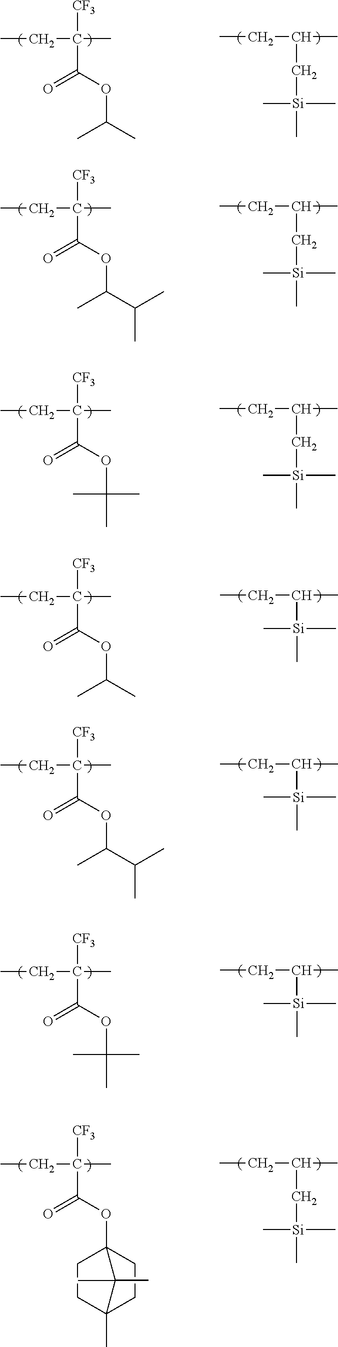

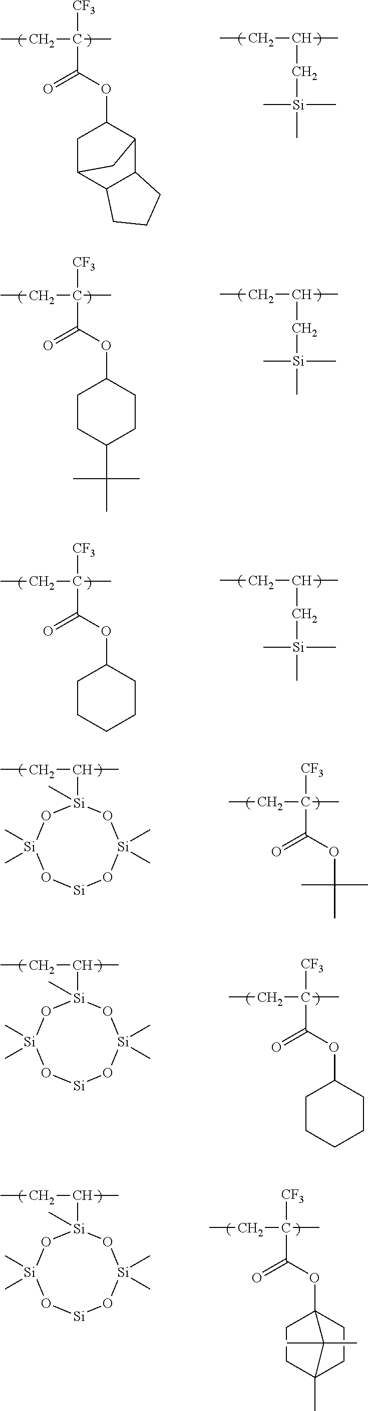

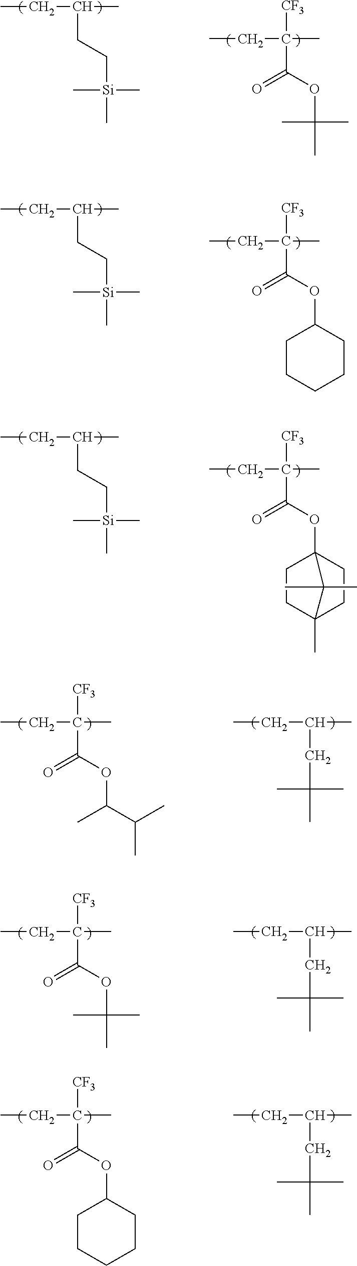

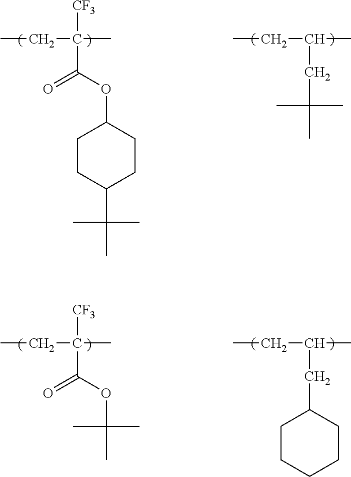

The resin (D) may have a repeating unit represented by the following general formula (VIII).

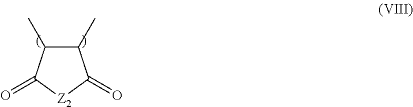

In the general formula (VIII),

Z₂ represents —O— or —N(R₄₁)—. R₄₁ represents a hydrogen atom, a hydroxyl group, an alkyl group, or —OSO₂—R₄₂. R₄₂ represents an alkyl group, a cycloalkyl group, or a camphor residue. The alkyl group of R₄₁ and R₄₂ may be substituted by a halogen atom (preferably a fluorine atom), or the like.

The resin (D) is preferably solid at ambient temperature (25° C.). Further, the glass transition temperature (Tg) thereof is preferably from 50 to 200° C., and more preferably from 80 to 160° C.

The resin being solid at 25° C. means that the melting point is 25° C. or higher.

The glass transition temperature (Tg) can be measured by a scanning calorimeter (Differential Scanning Calorimeter). For example, after heating a sample and then cooling, it can be determined by analyzing the change in the specific volume when the sample is heated again at 5° C./min.

It is preferable that the resin (D) is stable to an acid and insoluble in an alkali developer.

From the viewpoint of followability of the immersion liquid, it is preferable that the resin (D) is free from (x) an alkali-soluble group, (y) a group which decomposes by the action of an alkali (alkali developer) to increase the solubility in an alkali developer, and (z) a group which decomposes by the action of an acid to increase the solubility in a developer.

The total amount of repeating units having an alkali-soluble group or a group the solubility of which in a developer increases by the action of an acid or an alkali in the resin (D) is preferably 20% by mol or less, more preferably from 0 to 10% by mol, and still more preferably from 0 to 5% by mol, based on all of the repeating units constituting the resin (D).

Also, unlike a surfactant generally used for resists, the resin (D) contains no ionic bond or hydrophilic group such as a (polyoxyalkylene) group. In the case where the resin (D) contains a hydrophilic polar group, the followability of the immersion liquid tends to decrease. Therefore, it is more preferred that the resin (D) has no polar group selected from a hydroxyl group, alkylene glycols, and a sulfone group. It is also preferable that the resin (D) has no ether group bonded to the carbon atom of the main chain through a linking group since such an ether group causes an increase in the hydrophilicity, resulting in deterioration in the followability of immersion liquid. On the other hand, an ether group bonded directly to the carbon atom of the main chain as in the general formula (IIIF) is preferred because such an ether group can sometimes express an activity as a hydrophobic group.

Examples of (x) the alkali-soluble group include groups having a phenolic hydroxyl group, a carboxylate group, a fluoro alcohol group, a sulfonate group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene groups a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group, and the like.

Examples of (y) the group capable of decomposing by the action of an alkali (alkali developer) to increase the solubility in an alkali developer include a lactone group, an ester group, a sulfonamide group, an acid anhydride, an acid imide group, and the like.

Examples of (z) the group which decomposes by the action of an acid to increase the solubility in a developer include the same groups as those of the acid-decomposable group in the resin (A).

However, the repeating unit represented by the following general formula (pA-C) is not or scarcely decomposed by the action of an acid, as compared with the acid-decomposable group of the resin (A) and, therefore is regarded as being substantially non-acid-decomposable.

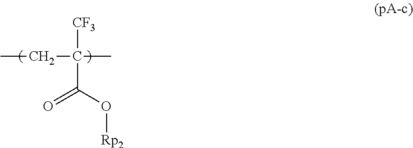

In the general formula (pA-c),

R₉₂ represents a hydrocarbon group having a tertiary carbon atom bonded to the oxygen atom in the formula.

In the case where the resin (D) contains a silicon atom, the content of the silicon atoms is preferably from 2 to 50% by mass, and more preferably from 2 to 30% by mass, based on the molecular weight of the resin (D). Also, the amount of the silicon atom-containing repeating unit is preferably from 10 to 100% by mass, and more preferably from 20 to 100% by mass, in the resin (D).

In the case where the resin (D) contains a fluorine atom, the content of the fluorine atoms is preferably from 5 to 80% by mass, and more preferably from 10 to 80% by mass, based on the molecular weight of the resin (D). Also, the content of the fluorine atom-containing repeating units is preferably from 10 to 100% by mass, and more preferably from 30 to 100% by mass, in the resin (D).

The weight-average molecular weight of the resin (D) in terms of polystyrene as a standard is preferably from 1,000 to 100,000, more preferably from 1,000 to 50,000, still more preferably from 2,000 to 15,000, and particularly preferably from 3,000 to 15,000.

The residual monomer amount in the resin (D) is preferably from 0 to 10% by mass, more preferably from 0 to 5% by mass, and still more preferably from 0 to 1% by mass. Also, from the viewpoints of the resolution, resist profile, and side wall, roughness, or the like of a resist pattern, the molecular weight distribution (Mw/Mn, also called a dispersion degree) is preferably in the range from 1 to 5, more preferably in the range from 1 to 3, and still more preferably in the range from 1 to 1.5.

The amount of the resin (D) to be added in the resist composition is preferably from 0.1 to 20% by mass, and more preferably from 0.1 to 10% by mass, based on the total solid content of the resist composition. Furthermore, the amount is preferably from 0.1 to 5% by mass, more preferably from 0.2 to 3.0% by mass, and still more preferably from 0.3 to 2.0% by mass.

Similar to the resin (A), it is preferable, as a matter of course, that the resin (D) contains only a minute amount of impurities such as metals. It is also preferable that the resin (D) contains the residual monomers and oligomer components at a predetermined level or less, for example, 0.1% by mass or less determined by HPLC. Thus, not only the sensitivity, resolution, process stability, pattern shape, and the like as a resist can be further improved but also the obtained resist is free from contaminants in the liquid or changes in sensitivity and the like with the passage of time.

As the resin (D), use can be made of a commercially available product, or of a product synthesized in accordance with a commonly employed method (for example, radical polymerization). The synthesis method can be conducted with reference to the method for synthesis of an acid-decomposable resin as previously described, the description of Chapter 2 “Polymer Synthesis” of “5^{th} Edition, Experimental Chemistry Lecture 26 Polymer Chemistry”, issued by MARUZEN Co., Ltd., and the like.

(E) Basic Compound

It is preferable that the resist composition of the present invention contains (E) an alkaline compound to relieve changes in the properties with the passage of time in the course from exposure to heating.

Examples of the preferable alkaline compound include the compounds having the structures represented by the following formulae (A) to (E).

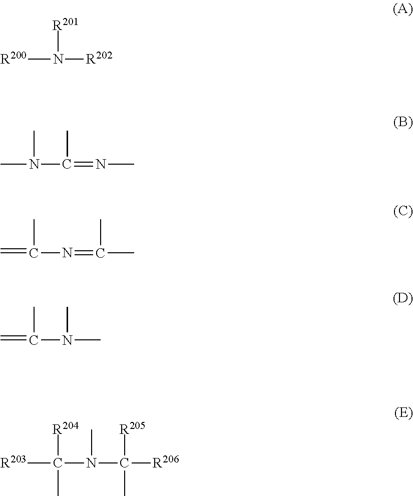

En the general formulae (A) and (E),

R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms). Here, R²⁰¹ and R²⁰² may be bonded to each other to form a ring. R²⁰³, R²⁰⁴, R²⁰⁵, and R²⁰⁶ may be the same as or different from each other, and each represent an alkyl group having 1 to 20 carbon atoms.

For the alkyl group, as the alkyl group having a substituent, an aminoalkyl group having 1 to 20 carbon atoms, an hydroxyalkyl group having 1 to 20 carbon atoms, and a cyanoalkyl group having 1 to 20 carbon atoms are preferred.

The alkyl groups in the general formulae (A) and (E) are more preferably unsubstituted alkyl groups.

Examples of preferable compounds include guanidine, aminopyrrolidine, pyrazole, pyrazoline, piperazine, aminomorpholine, aminoalkylmorpholine, piperidine, and the like. More preferable compounds include a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, an aniline derivative having a hydroxyl structure and/or an ether bond, and the like.

Examples of the compound having an imidazole structure include imidazole, 2,4,5-triphenylimidazole, benzimidazole, and the like. Examples of the compound having a diazabicyclo structure include 1,4-diazabicyclo[2,2,2]octane, 1,5-diazabicyclo[4,3,0]nona-5-ene, 1,8-diazabicyclo[5,4,0]undeca-7-ene, and the like. Examples of the compound having an onium hydroxide structure include triarylsulfonium hydroxide, phenacylsulfonium hydroxide, a sulfonium hydroxide having a 2-oxoalkyl group (more specifically triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide), and the like. Examples of the compound having an onium carboxylate structure include a compound in which the anion moiety of a compound having an onium hydroxide structure has been converted into carboxylate such as acetate, adamantane-1-carboxylate, and perfluoroalkylcarboxylate. Examples of the compound having a trialkylamine structure include tri(n-butyl)amine, tri(n-octyl)amine, and the like. Examples of the aniline compound include 2,6-diisopropylaniline, N,N-dimethylaniline, N,N-dibutylaniline, N,N-dioctylaniline, and the like. Examples of the alkylamine derivative having a hydroxyl structure and/or an ether bond include ethanolamine, diethanolamine, triethanolamine, tris(methoxyethoxyethyl)amine, and the like. Examples of the aniline derivative having a hydroxyl structure and/or an ether bond include N,N-bis(hydroxyethyl)aniline, and the like.

Examples of the preferable alkaline compound further include a phenoxy group-containing amine compound, a phenoxy group-containing ammonium salt compound, a sulfonic acid ester group-containing amine compound, and a sulfonic acid ester group-containing ammonium salt compound.

It is preferable that the phenoxy group-containing amine compound, the phenoxy group-containing ammonium salt compound, sulfonic acid ester group-containing amine compound and sulfonic acid ester group-containing ammonium salt compound has at least one alkyl group bonded to a nitrogen atom. Further, it is preferable that the alkyl chain contains an oxygen atom to form an oxyalkylene group. The number of the oxyalkylene group is one or more, preferably from 3 to 9, and more preferably from 4 to 6, per molecule. Among the oxyalkylene groups, the structures of —CH₂CH₂O—, CH(CH₃)CH₂O—, or —CH₂CH₂CH₂O— are preferred.

Specific examples of the phenoxy group-containing amine compound, the phenoxy group-containing ammonium salt compound, the sulfonic acid ester group-containing amine compound, and the sulfonic acid ester group-containing ammonium salt compound include, but not limited to, the compounds (C1-1) to (C3-3) as exemplified in [0066] of US2007/0224539 A. These alkaline compounds are used singly or in combination of two or more kinds thereof.

The amount of the basic compound to be used is usually from 0.001 to 10% by mass, and preferably from 0.01 to 5% by mass, based on the solid content of the resist composition.

The ratio of the acid generator and the basic compound to be used in the composition is preferably the acid generator/basic compound (molar ratio)=from 2.5 to 300. That is, the molar ratio is preferably 2.5 or more in view of sensitivity and resolution, and preferably 300 or less, from the standpoint of suppressing the reduction in resolution due to thickening of the resist pattern in aging after exposure until heat treatment. The acid generator/basic compound (molar ratio) is more preferably from 5.0 to 200, and still more preferably from 7.0 to 150.

(F) Surfactant

The resist composition of the present invention preferably contains (F) a surfactant. More preferably, it contains any one or two or more surfactants selected from among fluorine-based and/or silicon-based surfactants (a fluorine-based surfactant, a silicon-based surfactant, and a surfactant having both of fluorine and silicon atoms).

Since the resist composition of the present invention contains a surfactant, it becomes possible to present a resist pattern having a favorable sensitivity and resolution and a high adhesion and suffering from little development failures in the cause of using an exposure light source of 250 nm or less, in particular 220 nm or less.

Examples of the surfactants include those as set forth in [0346] to [0349] of JP-A-2008-292975.

These surfactants may be used singly or in combination of two or more kinds thereof.

The amount of the surfactant to be used is preferably from 0.01 to 10% by mass, and more preferably 0.1 to 5% by mass, based on the total amount of the resist composition (excluding the solvent).

(G) Onium Carboxylate

The resist composition according to the present invention may contain onium carboxylate. Examples of the onium carboxylate include those as set forth in [0352] to [0353] of JP-A-2008-292975.

This onium carboxylate can be synthesized by reacting sulfonium hydroxide, iodonium hydroxide, ammonium hydroxide, and carboxylic acid with silver oxide in an appropriate solvent.

The content of the onium carboxylate in the composition is generally from 0.1 to 20% by mass, preferably from 0.5 to 10% by mass, and more preferably from 1 to 7% by mass, based on the total solid content of the composition.

(H) Other Additives

The resist composition of the present invention may further contain, if desired, a dye, a plasticizer, a photosensitizer, a photoabsorbent, an alkali-soluble resin, a dissolution inhibitor, a compound accelerating the dissolution in a developer (for example, a phenol compound having a molecular weight of 1000 or less, and an alicyclic or aliphatic compound having a carboxyl group), and the like.

This phenol compound having a molecular weight of 1000 or less can be easily synthesized by a person skilled in the art with reference to, for example, the methods as set forth in JP-A-4-122938, JP-A-2-28531, U.S. Pat. No. 4,916,210, European Patent No. 219294, and the like.

Specific examples of the alicyclic or aliphatic compound having a carboxyl group include a derivative of a carboxylic acid having a steroid structure such as cholic acid, deoxycholic acid, lithocholic acid, and the like, an adamantane carboxylic acid derivative, adamantane dicarboxylic acid, cyclohexane carboxylic acid, cyclohexane carboxylic acid, cyclohexane dicarboxylic acid, and the like, but the present invention is not limited thereto.

The solid concentration of the resist composition of the present invention is usually from 1.0 to 10% by mass, preferably from 2.0 to 5.7% by mass, and still more preferably from 2.0 to 5.3% by mass. By adjusting the solid concentration within the range, the resist solution can be uniformly applied on a substrate, thereby it being possible to form a resist pattern excellent in line edge roughness. The reason is not clear, but it is probably assumed that by adjusting the solid concentration to 10% by mass or less, and preferably 5.7% by mass, the aggregation of the material in the resist solution, particularly the photo-acid generator is inhibited, and as a result a uniform resist film can be formed.

The solid concentration refers to a weight percentage of the weight of other resist components excluding the solvent, based on the total weight of the resist composition.

In the pattern forming method of the present invention, the step of forming on a substrate a film made of a resin composition which shows a decrease in the solubility in a negative-tone developer upon irradiation with an actinic ray or radiation, the step of exposing the film, the step of heating the film, and the step of subjecting the film to positive-tone development can be conducted by a commonly known method.

The wavelength of the light source to be used in the exposure apparatus in the present invention is not particularly limited, but it is possible to use a KrF excimer laser wavelength (248 nm), an ArF excimer laser wavelength (193 nm), an F₂ excimer laser wavelength (157 nm), and the like.

Furthermore, in the step of exposing in the present invention, an immersion exposure method can be employed.

The immersion exposure method is a technique for increasing resolution, in which the space between a projector lens and a sample is filled with a liquid having a high refractive index (hereinafter also called an “immersion liquid”).

In the case of carrying out the immersion exposure, the step of washing the film surface with an aqueous agent at the point (1) between the step of forming of the film on the substrate and the step of exposing and/or (2) between the step of exposing the film via the immersion liquid and the step of heating the film.

The immersion liquid is not particularly limited as long as it is a substance having a higher refractive index than air, but pure water is usually used.

In the present invention, the substrate on which the film is formed is not particularly limited, and for example, it is possible to use a substrate commonly employed in the process of producing semiconductors such as IC and the like, in the process of producing circuit substrates such as a liquid crystal, a thermal head, and the like and in the process of lithographing other photofabrications, for example, an inorganic substrate made of silicon, SiN, SiO₂, or the like, a coated inorganic substrate such as SOG or the like, etc. If necessary, an organic antireflective film may be formed between the film and the substrate.

In conducting the positive-tone development, it is preferable to use an alkali developer.

As the alkali developer for conducting the positive-tone development, use can be made of aqueous alkaline solutions of inorganic alkalis such as sodium hydroxide, potassium hydroxides sodium carbonate, sodium silicate, sodium metasilicate, aqueous ammonia, and the like; primary amines such as ethylamine, n-propyl amine, and the like; secondary amines such as diethylamine, di-n-butylamine, and the like; tertiary amines such as triethylamine, methyldiethylamine, and the like; alcohol amines such as dimethyl ethanol amine, triethanol amine, and the like; quaternary ammonium salts such as tetramethylammonium hydroxide, tetraethylammonium hydroxide, and the like; cyclic amines such as pyrrole, piperidine, and the like; etc.

Further, it is also possible to use the above-described alkali developer, to which an alcohol or a surfactant is added in an appropriate amount.

The alkali concentration in the alkali developer is usually from 0.1 to 20% by mass.

The pH value of the alkali developer is usually from 10.0 to 15.0.

A 2.38% by mass aqueous solution of trimethylammonium hydroxide is particularly preferable.

As a rinsing liquid in the rinsing treatment which is conducted after the positive-tone development, pure water is used, and pure water to which an appropriate amount of a surfactant is added can also be used.

In conducting the negative-tone development, an organic-based developer containing an organic solvent is preferably used. As the organic-based developer which can be used in conducting the negative-tone development, a polar solvent such as a ketone-based solvent, an ester-based solvent, an alcohol-based solvent, an amide-based solvent, an ether-based solvent, and the like, and a hydrocarbon solvent can be used.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methyl cyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, propylene carbonate, and the like.

Examples of the ester-based solvent include methyl acetate, butyl acetate, ethyl acetate, isopropyl acetate, amyl acetate, propylene glycol monomethyl ether acetate (PGMEA, also called 1-methoxy-2-acetoxypropane), ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, and the like.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, n-decanol, and the like; glycol solvents such as ethylene glycol, diethylene glycol, triethylene glycol, and the like; and glycol ether-based solvents such as ethylene glycol monomethyl ether, propylene glycol monomethyl ether (PGMEA, also called 1-methoxy-2-acetoxypropane), ethylene glycol monoethyl ether, propylene glycol monoethyl ether, diethylene glycol monomethyl ether, triethylene glycol monoethyl ether, methoxymethyl butanol, and the like.

Examples of the ether-based solvent include the glycol ether solvents cited above, dioxane, tetrahydrofuran, and the like.

Examples of the amide-based solvent include N-methyl-2-pyrrolidone, N,N-dimethylacetamide, N,N-dimethylformamide, hexamethylphosphoric triamide, 1,3-dimethyl-2-imidazolidinone, and the like.

Examples of the hydrocarbon-based solvent include aromatic hydrocarbon solvents such as toluene, xylene, and the like and aliphatic hydrocarbon solvents such as pentane, hexane, octane, decane, and the like.

These solvents may be used in a mixture of two or more kinds thereof, or alternatively, the solvents may be mixed with solvents other than the solvents as described above or water.

Particularly, the negative-tone developer is preferably a developer which contains at least one solvent selected from a ketone-based solvent, an ester-based solvent, an alcohol-based solvent, an amide-based solvent, and an ether-based solvent.

The negative-tone developer preferably has a vapor pressure at 20° C. of 5 kPa or less, more preferably 3 kPa or less, and most preferably 2 kPa or less. By adjusting the vapor pressure of the negative-tone developer to 5 kPa or less, the evaporation of a phase difference liquid on the substrate or in the development cap is inhibited, and thus, the temperature uniformity in the wafer surface, resulting in favorable dimensional uniformity.

Specific examples of the developer having a vapor pressure of 5 kPa or less include ketone-based solvents such as 1-octanone, 2-octanone, 1-nonanone, 2-nonanone, 4-heptanone, 2-hexanone, diisobutyl ketone, cyclohexanone, methyl cyclohexanone, phenyl acetone, methyl isobutyl ketone, and the like; ester-based solvents such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate, propyl lactate, and the like; alcohol-based solvents such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, n-decanol, and the like; glycol-based solvents such as ethylene glycol, diethylene glycol, triethylene glycol, and the like; glycol ether solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, methoxymethyl butanol, and the like; ether-based solvents such as tetrahydrofuran, and the like; amide solvents such as N-methyl-2-pyrrolidone, N,N-dimethylacetamide, N,N-dimethylformamide, and the like; aromatic hydrocarbon-based solvents such as toluene, xylene, and the like; and aliphatic hydrocarbon solvents such as octane, decane, and the like.

Specific examples of the developer having a vapor pressure in the more preferable range of 2 kPa or less include ketone-based solvents such as 1-octanone, 2-octanone, 1-nonanone, 2-nonanone, 4-heptanone, 2-hexanone, diisobutyl ketone, cyclohexanone, methyl cyclohexanone, phenyl acetone, and the like; ester-based solvents such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate, propyl lactate, and the like; alcohol-based solvents such as alcohols such as n-butyl alcohol, sec-butyl alcohol, tert-butyl alcohol, isobutyl alcohol, n-hexyl alcohol, n-heptyl alcohol, n-octyl alcohol, n-decanol, and the like; glycol-based solvents such as ethylene glycol, diethylene glycol, triethylene glycol, and the like; glycol ether solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, methoxymethyl butanol, and the like; amide-based solvents such as N-methyl-2-pyrrolidone, N,N-dimethylacetamide, N,N-dimethylformamide, and the like; aromatic hydrocarbon-based solvents such as xylene, and the like; and aliphatic hydrocarbon-based solvents such as octane, decane, and the like.

The developer which can be used in conducting the negative-tone development may contain an appropriate amount of a surfactant, if desired.

Although the surfactant is not particularly limited, for example, ionic or nonionic, fluorine- and/or silicon-based surfactants, or the like can be used. Examples of such fluorine and/or silicon-based surfactants include the surfactants as set forth in JP-A-62-36663, JP-A-61-226746, JP-A-61-226745, JP-A-62-170950, JP-A-63-34540, JP-A-7-230165, JP-A-8-62834, JP-A-9-54432, JP-A-9-5988, and the specifications of U.S. Pat. No. 5,405,720, U.S. Pat. No. 5,360,692, U.S. Pat. No. 5,529,881, U.S. Pat. No. 5,296,330, U.S. Pat. No. 5,436,098, U.S. Pat. No. 5,576,143, U.S. Pat. No. 5,294,511, and U.S. Pat. No. 5,824,451. A nonionic surfactant is preferred. The nonionic surfactant is not particularly limited, but a fluorine-based surfactant or a silicon-based surfactant is more preferably used.

The amount of the surfactant to be used is usually from 0.001 to 5% by mass, preferably from 0.005 to 2% by mass, and still more preferably from 0.01 to 0.5% by mass, based on the total amount of the developer.

As the development method, a method including dipping the substrate in a tank filled with the developer for a predetermined period of time (a dip method), a method including heaping up the developer on the substrate surface due to surface tension and allowing it to stand for a predetermined time to thereby conduct the development (a paddle method), a method including spraying the developer onto the substrate surface (a spray method), a method including rotating the substrate at a predetermined speed and continuously coating it with the developer by scanning a developer-coating nozzle at a predetermined speed (a dynamic dispense method), or the like can be employed.

Furthermore, after the step of conducting the negative-tone development, the step of ceasing the development while replacing by another solvent may be carried out.

After the negative-tone development, it is preferable to carry out the step of washing with the use of a rinsing liquid for negative-tone development containing an organic solvent.

The rinsing liquid used in the rinsing step after the negative-tone development is not particularly limited as long as it does not dissolve the resist pattern, and a solution containing a common organic solvent can be used. As the rinsing liquid, a rinsing liquid containing at least one organic solvent selected from a hydrocarbon-based solvent, a ketone-based solvent, an ester-based solvent, an alcohol-based solvent, an amide-based solvent, and an ether-based solvent (dibutyl ether, diisoamyl ether, and the like) is preferably used. More preferably, a step of washing with the use of a rinsing liquid containing at least one organic solvent selected from a ketone-based solvent, an ester-based solvent, an alcohol-based solvent, and an amide-based solvent is conducted after the negative-tone development. Still more preferably, a step of washing with the use of a rinsing liquid containing an alcohol-based solvent or an ether-based solvent is conducted after the negative-tone development. Particularly preferably, a step of washing with the use of a rinsing liquid containing a secondary or higher alcohol having at least 5 carbon atoms (more preferably 5 to 12 carbon atoms, and still more preferably 5 to 10 carbon atoms) and having an alkyl chain of a branched and/or cyclic structure is conducted. Alternatively, particularly preferably, a step of washing with the use of a rinsing liquid containing primary alcohol is conducted after the negative-tone development. Here, examples of the primary alcohol used in the rinsing step after the negative-tone development include linear, branched, and cyclic primary alcohols, and specifically, 1-butanol, 2-butanol, 3-methyl-1-butanol, tert-butyl alcohol, 1-pentanol, 2-pentanol, 1-hexanol, 1-heptanol, 1-octanol, 2-hexanol, 2-heptanol, 2-octanol, 3-hexanol, 3-heptanol, 3-octanol, 4-octanol, 3-methyl-3-pentanol, cyclopentanol, 2,3-dimethyl-2-butanol, 3,3-dimethyl-2-butanol, 2-methyl-2-pentanol, 2-methyl-3-pentanol, 3-methyl-2-pentanol, 3-methyl-3-pentanol, 4-methyl-2-pentanol, 4-methyl-3-pentanol, cyclohexanol, 5-methyl-2-hexanol, 4-methyl-2-hexanol, 4,5-dimethyl-2-hexanol, 6-methyl-2-heptanol, 7-methyl-2-octanol, 8-methyl-2-nonanol, 9-methyl-2-decanol, or the like, and preferably, 1-hexanol, 2-hexanol, 1-pentanol, 3-methyl-1-butanol, 3-methyl-2-pentanol, 3-methyl-3-pentanol, 4-methyl-2-pentanol, or 4-methyl-3-pentanol can be used (Further, parts of these specific examples correspond to secondary or higher alcohols having at least 5 carbon atoms and having an alkyl chain of a branched and/or cyclic structure).

These components may be used in a mixture of two or more kinds thereof, or alternatively, may be mixed with organic solvents other than those as described above.

The water content of the rinsing liquid is preferably 10% by mass or less, more preferably 5% by mass or less, and particularly preferably 3% by mass or less. By adjusting the water content to 10% by mass or less, favorable development characteristics can be established.

The rinsing liquid used after the negative-tone development preferably has a vapor pressure at 20° C. of 0.05 kPa or more and 5 kPa or less, more preferably 0.1 kPa or more and 5 kPa or less, and most preferably 0.12 kPa or more and 3 kPa or less. By adjusting the vapor pressure of the rinsing liquid to 0.05 kPa or more and 5 kPa or less, the temperature uniformity in the wafer surface is improved, and further, the swelling due to penetration of the rinsing liquid is inhibited, resulting in favorable dimensional uniformity on the wafer surface.

It is also possible to employ a rinsing liquid containing an appropriate amount of a surfactant can be added to the rinsing liquid and used.

In the rinsing step, the wafer which has been subjected to negative-tone development is subjected to washing treatment using the above-described rinsing liquid containing an organic solvent. The washing treatment method is not particularly limited, but for example, a method including coating the substrate under rotation at a predetermined speed with the rinsing liquid (a spin coating method), a method including dipping the substrate in a tank filled with the rinsing liquid for a predetermined period of time (a dip method), a method including spraying the rinsing liquid onto the substrate surface (a spray method), or the like can be employed. Among these, it is preferable to conduct the washing treatment by the spin coating method and, after the completion of the washing, rotating the substrate at a rotational speed of 2000 rpm to 4000 rpm, thereby removing the rinsing liquid from the substrate.

### EXAMPLES

Hereinbelow, the present invention will be described with reference to Examples, but the present invention is not limited thereto.

### Synthesis Example 1

### Synthesis of Resin (P-1)

Under a nitrogen stream, 5.9 g of cyclohexanone was charged into a three-neck flask and heated at 80° C. Thereto, a solution prepared by dissolving 10.9 g (64.0 mmol) of a monomer (P-1-A), 6.0 g (25.6 mmol) of a monomer (P-1-B), 11.2 g (38.4 mmol) of a monomer (P-1-C), and 2.10 g (12.8 mmol) of a polymerization initiator V-60 (azobisisobutyronitrile, manufactured by Wako Pure Chemical Industries, Ltd.) in 106 g of cyclohexanone was added dropwise over 6 hours. After the completion of dropwise addition, the reaction was further allowed to proceed at 80° C. for 2 hours. After the completion of polymerization, 450 mL of at an aqueous solution in methanol (volume ratio methanol:water=9:1) at 20° C. was added dropwise thereto, and the precipitated solid was taken by decantation. This solid was dried under a vacuum at 40° C. to obtain 15.2 g of a resin P-1. The weight average molecule and the dispersity (Mw/Mn) of the obtained resin (P-1) were 10000 and was 1.4, respectively.

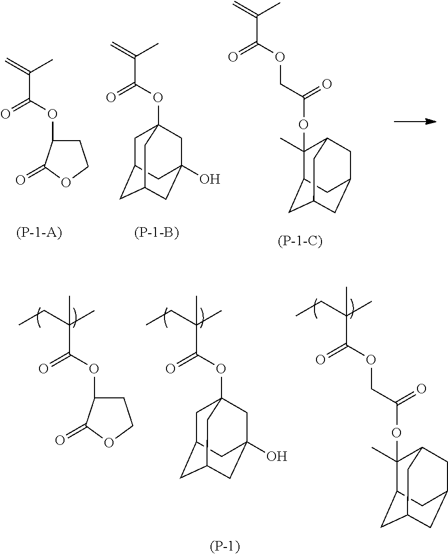

In the same manner as in Synthesis Example 1 above except that the monomers each corresponding to the repeating units were used at a desired compositional ratio (molar ratio), the resins (P-2) to (P-27), (P-R1), and (P-R2) and the hydrophobic resins (1b) to (4b) were synthesized. Here, the hydrophobic resins (1b) to (4b) correspond to the resin (D).

Next, the structures of the resins (P-2) to (P-27), (P-R1), and (P-R2) and the hydrophobic resins (1b) to (4b) will be presented. Also, the compositional ratio (molar ratio), the weight average molecule, and the dispersity of the resins (P-2) to (P-27), (P-R1), and (P-R2) and the hydrophobic resins (1b) to (4b) including the resin (P-1) above are shown in Table 1.

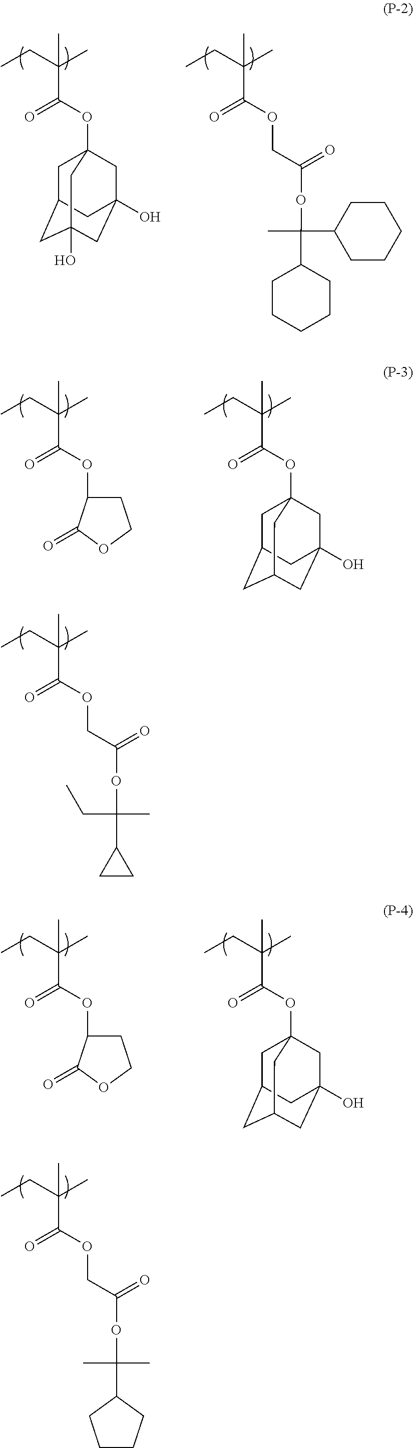

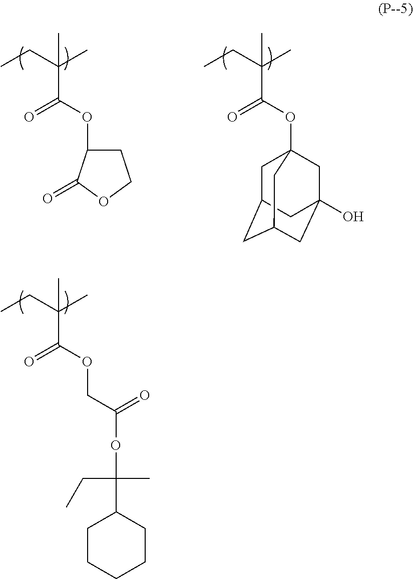

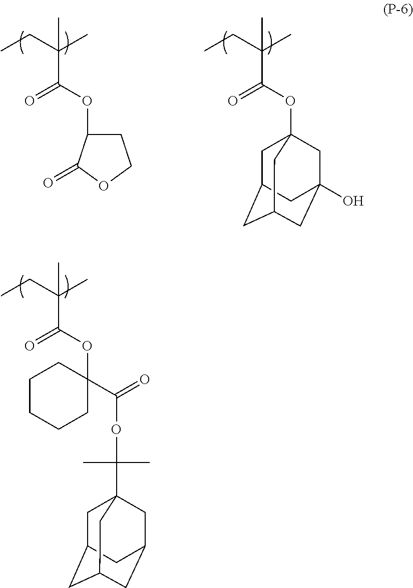

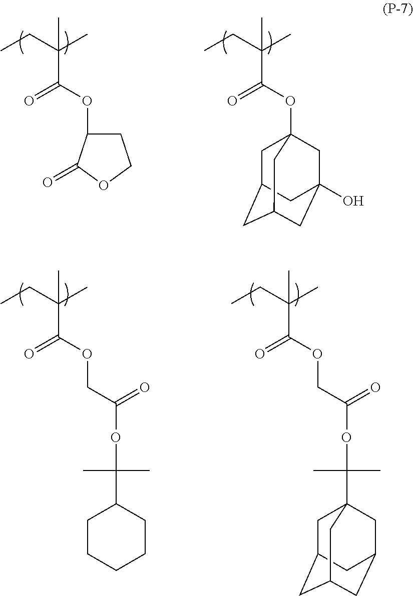

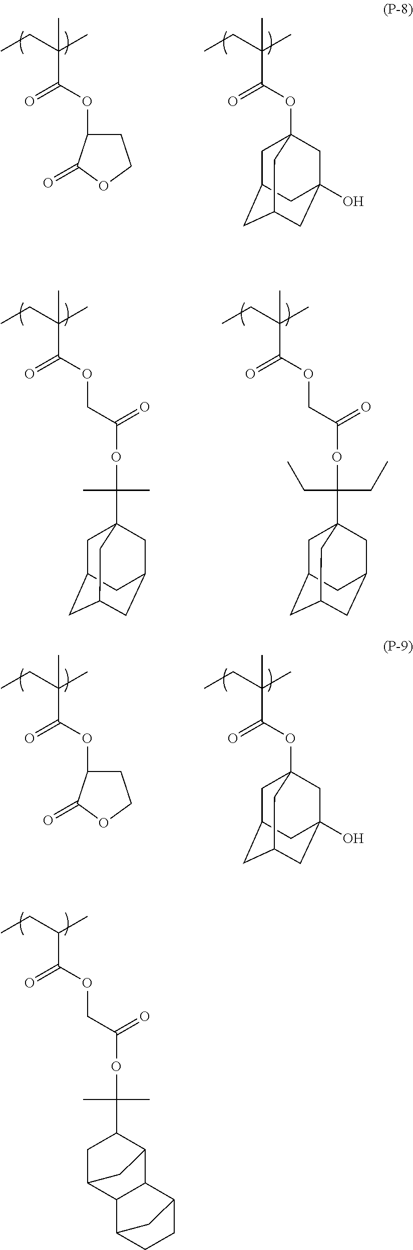

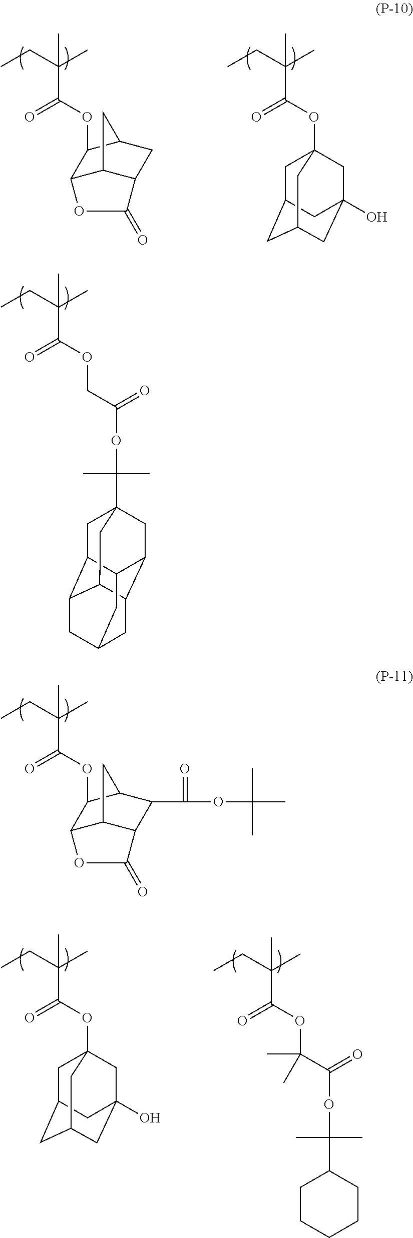

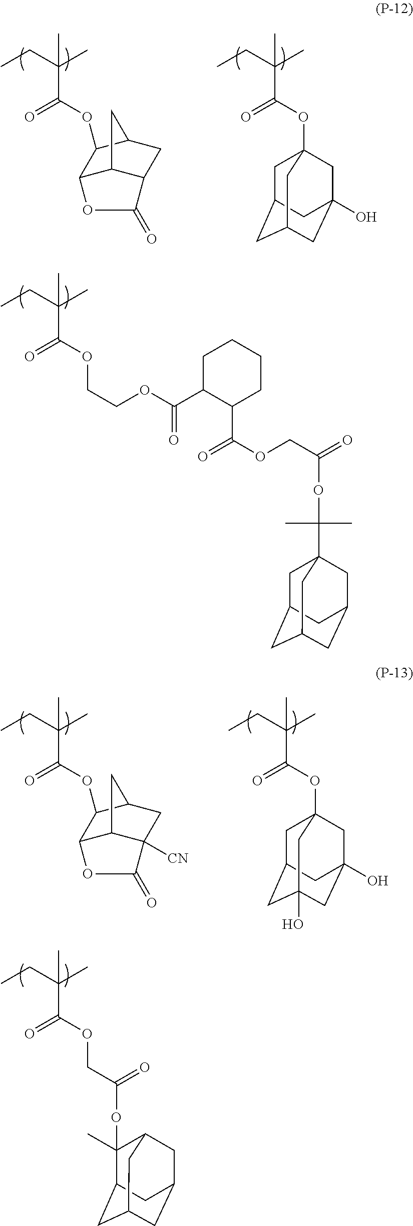

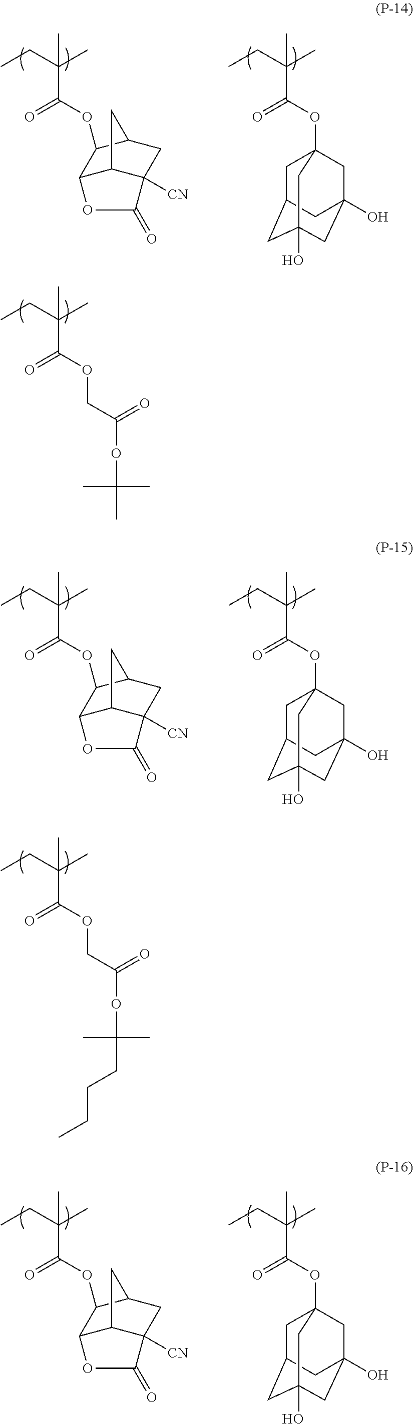

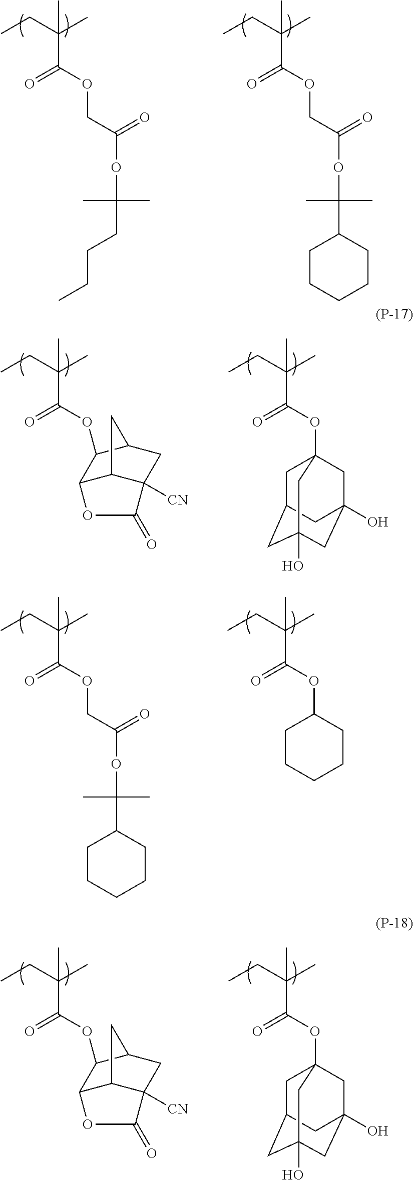

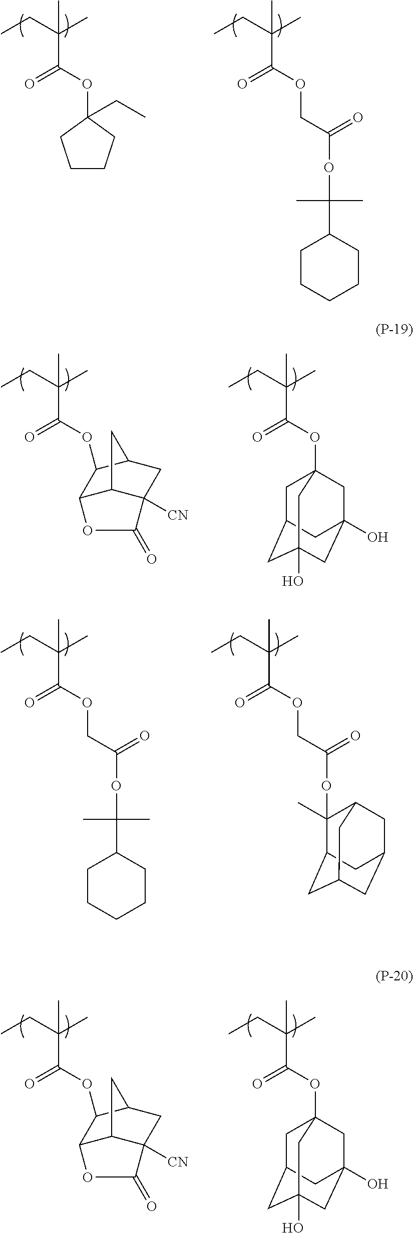

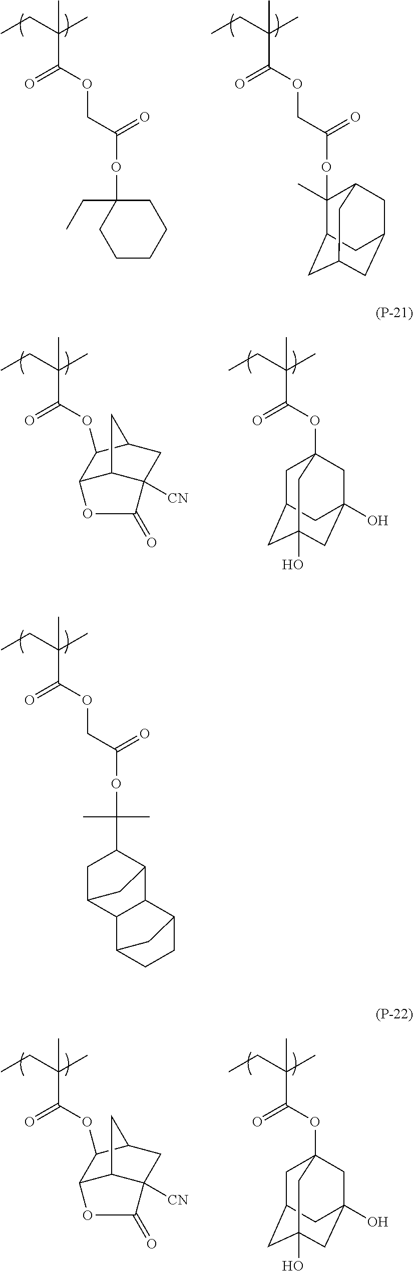

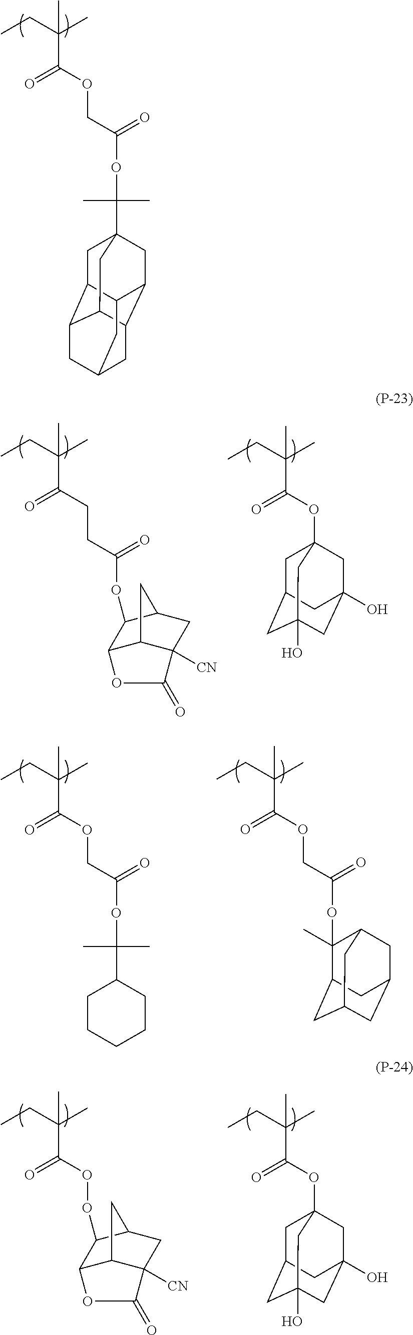

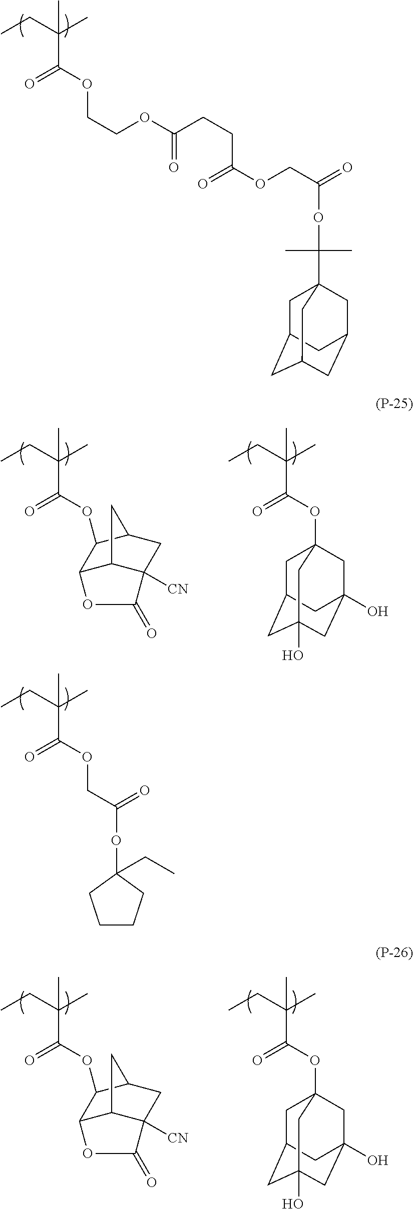

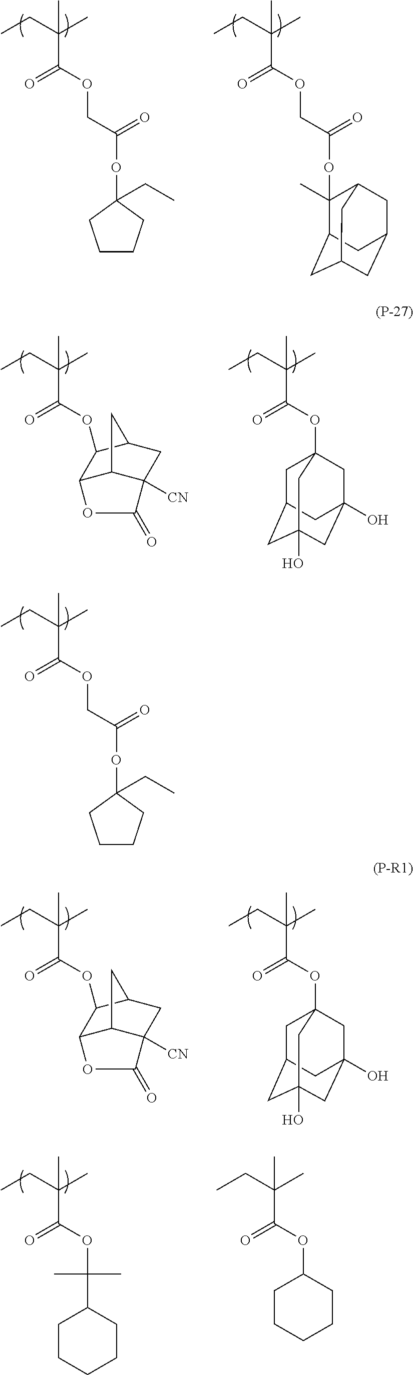

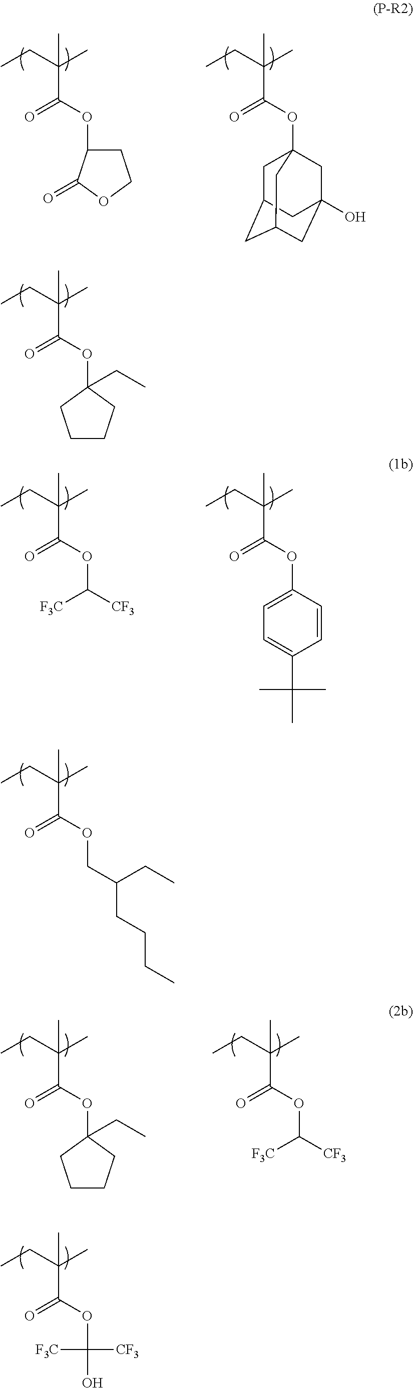

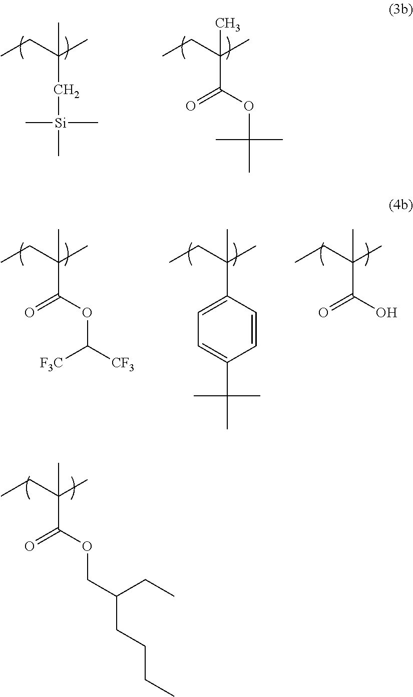

TABLE 1

| | Composition | | |
|---|---|---|---|
| Resin | (molar ratio) | Mw | Mw/Mn |
| (P-1) | 50/20/30 | 10000 | 1.4 |
| (P-2) | 30/70 | 8000 | 1.3 |
| (P-3) | 40/10/50 | 6000 | 1.5 |
| (P-4) | 40/10/50 | 15000 | 1.5 |
| (P-5) | 40/10/50 | 15000 | 1.4 |
| (P-6) | 40/10/50 | 10000 | 1.4 |
| (P-7) | 40/10/40/10 | 10000 | 1.4 |
| (P-8) | 40/10/40/10 | 10000 | 1.5 |
| (P-9) | 50/10/40 | 8000 | 1.4 |
| (P-10) | 50/10/40 | 6000 | 1.4 |
| (P-11) | 40/10/50 | 15000 | 1.5 |
| (P-12) | 40/10/50 | 15000 | 1.4 |
| (P-13) | 40/10/50 | 10000 | 1.4 |
| (P-14) | 40/10/50 | 10000 | 1.5 |
| (P-15) | 40/10/50 | 8000 | 1.3 |
| (P-16) | 40/10/40/10 | 6000 | 1.5 |
| (P-17) | 40/10/40/10 | 15000 | 1.4 |
| (P-18) | 40/10/40/10 | 15000 | 1.2 |
| (P-19) | 30/10/50/10 | 10000 | 1.4 |
| (P-20) | 30/10/50/10 | 10000 | 1.5 |
| (P-21) | 50/10/40 | 8000 | 1.3 |
| (P-22) | 50/10/40 | 6000 | 1.5 |
| (P-23) | 40/10/40/10 | 15000 | 1.5 |
| (P-24) | 40/10/50 | 15000 | 1.4 |
| (P-25) | 40/10/50 | 10000 | 1.4 |
| (P-26) | 40/10/40/10 | 10000 | 1.2 |
| (P-27) | 40/10/50 | 8000 | 1.4 |
| (P-R1) | 40/10/40/10 | 10000 | 1.4 |
| (P-R2) | 30/20/50 | 15000 | 1.7 |
| (1b) | 30/60/10 | 5000 | 1.4 |
| (2b) | 50/40/10 | 6500 | 1.5 |
| (3b) | 50/50 | 4000 | 1.3 |
| (4b) | 39/57/2/2 | 4500 | 1.3 |

### Synthesis Example 2

### Synthesis of Compound (PAG-1)

The compound (PAG-1) was synthesized in accordance with [0108] to [0110] of JP-A-2007-161707.

The compounds (PAG-2), (PAG-3), (PAG-4), (PAG-5), (PAG-6), (PAG-8), and (PAG-9) were also synthesized in accordance with the same approach.

Further, as the compound (PAG-7), CGI*1907 (manufactured by Ciba Specialty Chemicals Corporation) was used.

Next, the structures of the compounds (PAG-1) to (PAG-9) will be represented.

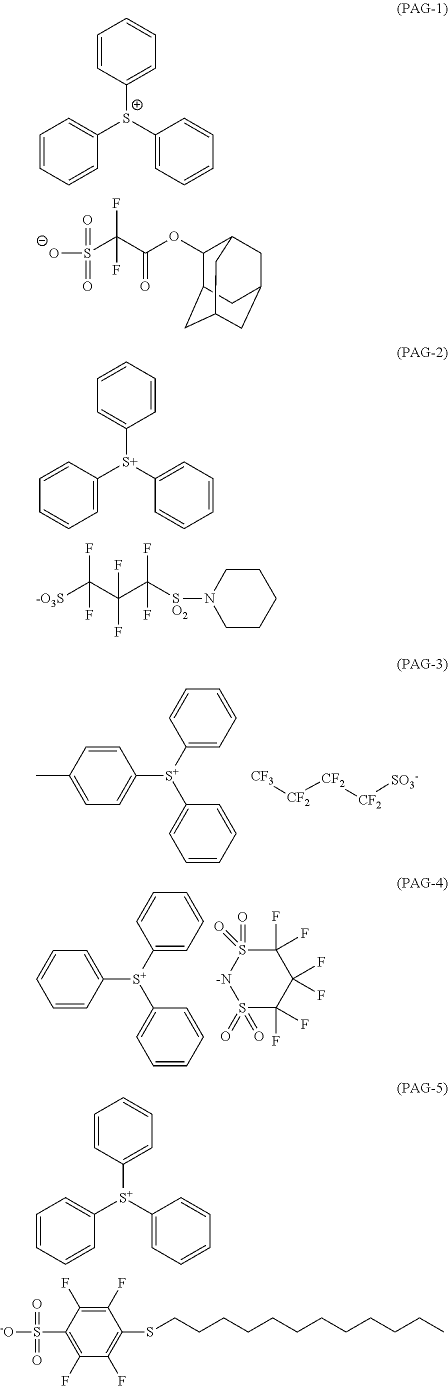

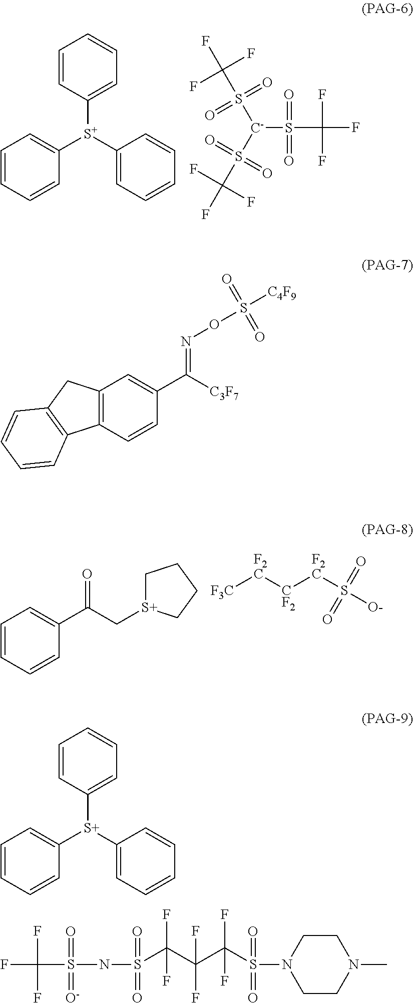

<Preparation of Resist Composition>

The components shown in Table 2 below were dissolved in a solvent shown in Table 2 to prepare a solution having a solid content concentration of 4% by mass, and the solution was each filtered through a polyethylene filter having a pore size of 0.03 μm to prepare the resist compositions Ar-1 to Ar-28, Ar-R1, and Ar-R2.

TABLE 2

| | | | | | (C) Acid | | | |
|---|---|---|---|---|---|---|---|---|
| | | | | | generator | | | |
| | (A) | | (B) Acid | | used in | | (D) Basic | |
| Resist | Resin | mass/g | generator | mass/g | combination | mass/g | compound | mass/g |
| Ar-1 | (P-1) | 10 | (PAG-2) | 1.0 | | | (B-1) | 0.7 |
| Ar-2 | (P-2) | 10 | (PAG-3) | 1.0 | | | (B-2) | 0.7 |
| Ar-3 | (P-3) | 10 | (PAG-4) | 1.0 | | | (B-3) | 0.7 |
| Ar-4 | (P-4) | 10 | (PAG-5) | 1.0 | | | (B-4) | 0.12 |
| Ar-5 | (P-5) | 10 | (PAG-6) | 0.5 | (PAG-1) | 0.5 | (B-5) | 0.12 |
| Ar-6 | (P-6) | 10 | (PAG-7) | 1.0 | (PAG-9) | 0.2 | (B-6) | 0.12 |
| Ar-7 | (P-7) | 10 | (PAG-2) | 1.0 | | | (B-1) | 0.7 |
| Ar-8 | (P-8) | 10 | (PAG-3) | 1.0 | | | (B-2) | 0.7 |
| Ar-9 | (P-9) | 10 | (PAG-4) | 1.0 | | | (B-3) | 0.7 |
| Ar-10 | (P-10) | 10 | (PAG-5) | 1.0 | | | (B-4) | 0.12 |
| Ar-11 | (P-11) | 10 | (PAG-6) | 0.5 | (PAG-1) | 0.5 | (B-5) | 0.12 |
| Ar-12 | (P-12) | 10 | (PAG-8) | 1.0 | (PAG-9) | 0.2 | (B-6) | 0.12 |
| Ar-13 | (P-13) | 10 | (PAG-2) | 1.0 | | | (B-1) | 0.7 |
| Ar-14 | (P-14) | 10 | (PAG-3) | 1.0 | | | (B-2) | 0.7 |
| Ar-15 | (P-15) | 10 | (PAG-4) | 1.0 | | | (B-3) | 0.7 |
| Ar-16 | (P-16) | 10 | (PAG-5) | 1.0 | | | (B-4) | 0.12 |
| Ar-17 | (P-17) | 10 | (PAG-6) | 0.5 | (PAG-1) | 0.5 | (B-5) | 0.12 |
| Ar-18 | (P-18) | 10 | (PAG-7) | 1.0 | (PAG-9) | 0.2 | (B-6) | 0.12 |
| Ar-19 | (P-19) | 10 | (PAG-2) | 1.0 | | | (B-1) | 0.7 |
| Ar-20 | (P-20) | 10 | (PAG-3) | 1.0 | | | (B-2) | 0.7 |
| Ar-21 | (P-21) | 10 | (PAG-4) | 1.0 | | | (B-3) | 0.7 |
| Ar-22 | (P-22) | 10 | (PAG-5) | 1.0 | | | (B-4) | 0.12 |
| Ar-23 | (P-23) | 10 | (PAG-6) | 0.5 | (PAG-1) | 0.5 | (B-5) | 0.12 |
| Ar-24 | (P-24) | 10 | (PAG-7) | 1.0 | (PAG-9) | 0.2 | (B-6) | 0.12 |
| Ar-25 | (P-25) | 10 | (PAG-2) | 1.0 | | | (B-1) | 0.7 |
| Ar-26 | (P-26) | 10 | (PAG-3) | 1.0 | | | (B-2) | 0.7 |
| Ar-27 | (P-27) | 10 | (PAG-4) | 1.0 | | | (B-3) | 0.7 |
| Ar-28 | (P-1) | 10 | (PAG-2) | 1.0 | | | (B-1) | 0.7 |
| Ar-R1 | (P-R1) | 10 | (PAG-2) | 1.0 | | | (B-1) | 0.15 |
| (Comparative | | | | | | | | |
| Example) | | | | | | | | |
| Ar-R2 | (P-R2) | 10 | (PAG-5) | 1.0 | | | (B-1) | 0.15 |
| (Comparative | | | | | | | | |
| Example) | | | | | | | | |

| | (E) Basic | | | | (G) | | | |
|---|---|---|---|---|---|---|---|---|
| | compound | | (F) | | Hydro- | | | |
| | used in | | Sur- | | phobic | | (H) | mass |
| Resist | combination | mass/g | factant | mass/g | resin | mass/g | Solvent | ratio |
| Ar-1 | (B-3) | 0.5 | W-1 | 0.04 | (1b) | 0.06 | A1/B1 | 60/40 |
| Ar-2 | (B-7) | 0.5 | W-2 | 0.04 | (2b) | 0.06 | A1/B2 | 80/20 |
| Ar-3 | (B-8) | 0.5 | W-3 | 0.04 | (3b) | 0.06 | A2/B1 | 70/30 |
| Ar-4 | | | W-1 | 0.04 | (4b) | 0.06 | A3/B2 | 80/20 |
| Ar-5 | | | W-2 | 0.04 | (1b) | 0.06 | A1/A2/B1 | 50/4/46 |
| Ar-6 | | | W-3 | 0.04 | (2b) | 0.06 | A1/B1 | 60/40 |
| Ar-7 | (B-3) | 0.5 | W-1 | 0.04 | (1b) | 0.06 | A1/B1 | 60/40 |
| Ar-8 | (B-7) | 0.5 | W-2 | 0.04 | (2b) | 0.06 | A1/B2 | 80/20 |
| Ar-9 | (B-8) | 0.5 | W-3 | 0.04 | (3b) | 0.06 | A2/B1 | 70/30 |
| Ar-10 | | | W-1 | 0.04 | (4b) | 0.06 | A3/B2 | 80/20 |
| Ar-11 | | | W-2 | 0.04 | (1b) | 0.06 | A1/A2/B1 | 50/4/46 |
| Ar-12 | | | W-3 | 0.04 | (2b) | 0.06 | A1/B1 | 60/40 |
| Ar-13 | (B-3) | 0.5 | W-1 | 0.04 | (1b) | 0.06 | A1/B1 | 60/40 |
| Ar-14 | (B-7) | 0.5 | W-2 | 0.04 | (2b) | 0.06 | A1/B2 | 80/20 |
| Ar-15 | (B-8) | 0.5 | W-3 | 0.04 | (3b) | 0.06 | A2/B1 | 70/30 |
| Ar-16 | | | W-1 | 0.04 | (4b) | 0.06 | A3/B2 | 80/20 |
| Ar-17 | | | W-2 | 0.04 | | | A1/A2/B1 | 50/4/46 |
| Ar-18 | | | W-3 | 0.04 | | | A1/B1 | 60/40 |
| Ar-19 | (B-3) | 0.5 | W-1 | 0.04 | (1b) | 0.06 | A1/B1 | 60/40 |
| Ar-20 | (B-7) | 0.5 | W-2 | 0.04 | (2b) | 0.06 | A1/B2 | 80/20 |
| Ar-21 | (B-8) | 0.5 | W-3 | 0.04 | (3b) | 0.06 | A2/B1 | 70/30 |
| Ar-22 | | | W-1 | 0.04 | (4b) | 0.06 | A3/B2 | 80/20 |
| Ar-23 | | | W-2 | 0.04 | (1b) | 0.06 | A1/A2/B1 | 50/4/46 |
| Ar-24 | | | W-3 | 0.04 | (2b) | 0.06 | A1/B1 | 60/40 |
| Ar-25 | (B-3) | 0.5 | W-1 | 0.04 | (1b) | 0.06 | A1/B1 | 60/40 |
| Ar-26 | (B-7) | 0.5 | W-2 | 0.04 | (2b) | 0.06 | A1/B2 | 80/20 |
| Ar-27 | (B-8) | 0.5 | W-3 | 0.04 | (3b) | 0.06 | A2/B1 | 70/30 |
| Ar-28 | (B-3) | 0.5 | W-1 | 0.04 | | | A1/B1 | 60/40 |
| Ar-R1 | | | W-3 | 0.04 | (2b) | 0.06 | A1/B1 | 60/40 |
| (Comparative | | | | | | | | |
| Example) | | | | | | | | |
| Ar-R2 | | | W-3 | 0.04 | (2b) | 0.06 | A1/B1 | 60/40 |
| (Comparative | | | | | | | | |
| Example) | | | | | | | | |

The abbreviations in Table 2 are as follows.

B-1 to B-8: Each represents of the following compounds.

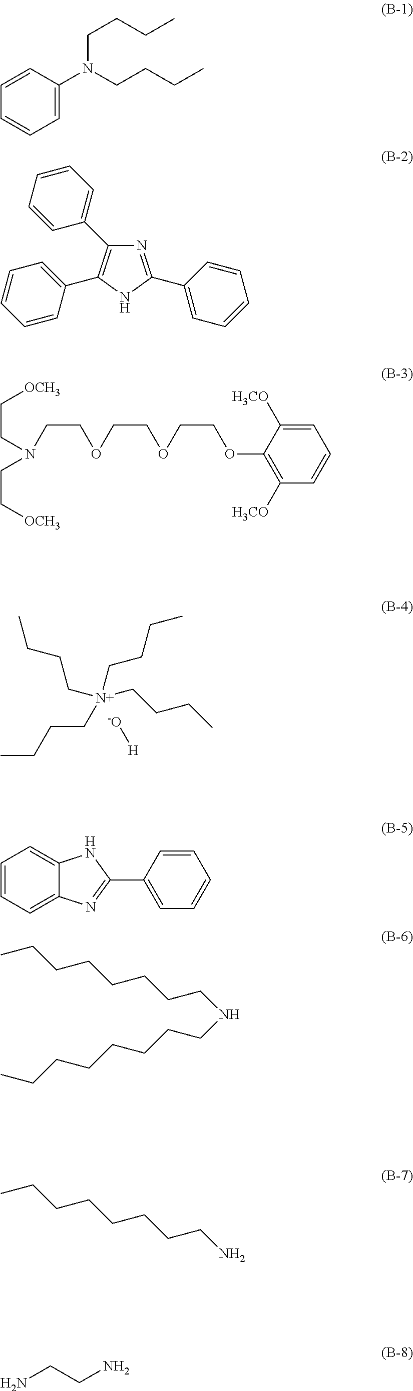

W-1: Megaface F176 (manufactured by Dai-Nippon Ink and Chemicals, Incorporated) (fluorine-based)

W-2: Megaface R08 (manufactured by Dai-Nippon Ink and Chemicals, Incorporated)(fluorine-based and silicon-based)

W-3: Polysiloxane polymer KP-341 (manufactured by Shin-Etsu Chemical Co., Ltd.) (silicon-based)

A1: Propylene glycol monomethyl ether acetate (PGMEA)

A2: γ-butyrolactone

A3: Cyclohexanone

B1: Propylene glycol monomethyl ether (PGME)

B2: Ethyl lactate

Using the prepared resist composition, a resist pattern was formed by the following method.

### Example 1

### Exposure Once→Negative Development: Abbreviated Symbol E-B-N

An organic antireflective film ARC29A (manufactured by Nissan Chemical Industries, Ltd.) was coated on a silicon wafer and baked at 205° C. for 60 seconds to form an antireflective film having a film thickness of 86 nm. Then, the resist composition Ar-1 was coated thereon and baked at 100° C. for 60 seconds to form a resist film having a film thickness of 100 nm. The obtained wafer was subjected to pattern exposure via an exposure mask (line/space=1/1) using an ArF excimer laser scanner (NA 0.75). Thereafter, after heating at 90° C. for 60 seconds, the wafer was subjected to development with a negative-tone developer (negative-tone development) for 20 seconds, rinsed with a rinsing liquid, and then rotated at a rotational speed of 4000 rpm for 30 seconds to obtain a resist pattern of a 90 nm (1:1) line-and-space.

### Examples 2 to 28 and Comparative Examples 1 and 2

By the same method as in Example 1 except for using the resists and the conditions as set forth in Table 3, a resist pattern of a 90 nm (1:1) line-and-space was obtained.

### Example 29

### Exposure Once Positive Development→Negative Development: Abbreviated Symbol E-B-N-P

An organic antireflective film ARC29A (manufactured by Nissan Chemical Industries, Ltd.) was coated on a silicon wafer and baked at 205° C. for 60 seconds to form an antireflective film having a film thickness of 86 nm. Then, the resist composition Ar-13 was coated thereon and baked at 100° C. for 60 seconds to form a resist film having a film thickness of 100 nm. The obtained wafer was subjected to pattern exposure via an exposure mask (line/space=1/1) using an ArF excimer laser scanner (NA 0.75). Thereafter, the wafer was heated at 90° C. for 60 seconds and then subjected to development with an aqueous tetramethyl ammonium hydroxide solution (2.38% by mass) for 30 seconds (positive-tone development), and rinsed with pure water to obtain a pattern having a pitch of 480 nm and a line width of 360 nm. Then, the wafer was subjected to development with a negative-tone developer for 30 seconds (negative-tone development), rinsed with a rinsing liquid, and then rotated at a rotational speed of 4000 rpm for 30 seconds to obtain a resist pattern of a 120 nm (1:1) line-and-space.

### Comparative Example 3

By the same method as in Example 29 except for using the resists and the conditions as set forth in Table 3, a resist pattern of a 120 nm (1:1) line-and-space was obtained.

### Example 30

### Exposure Once→Negative Development→Positive Development: Abbreviated Symbol E-B-N-P

An organic antireflective film ARC29A (manufactured by Nissan Chemical Industries, Ltd.) was coated on a silicon wafer and baked at 205° C. for 60 seconds to form an antireflective film having a film thickness of 86 nm. Then, the resist composition Ar-13 was coated thereon and baked at 100° C. for 60 seconds to form a resist film having a film thickness of 100 nm. The obtained wafer was subjected to pattern exposure via an exposure mask (line/space=1/1) using an ArF excimer laser scanner (NA 0.75). Thereafter, the wafer was heated at 90° C. for 60 seconds and then subjected to development with a negative-tone developer for 30 seconds (negative-tone development), rinsed with a rinsing liquid, and then rotated at a rotational speed of 4000 rpm for 30 seconds to obtain a pattern having a pitch of 480 nm and a line width of 360 nm. Then, the wafer was subjected to development with an aqueous tetramethyl ammonium hydroxide solution (2.38% by mass) for 30 seconds (positive-tone development), and rinsed with pure water to obtain a resist pattern of a 120 nm (1:1) line-and-space.

### Comparative Example 4

By the same method as in Example 30 except for using the resists and the conditions as set forth in Table 3, a resist pattern of a 120 nm (1:1) line-and-space was obtained.

### Example 31

### Exposure Twice→Negative Development: Abbreviated Symbol E-E-B-N

An organic antireflective film ARC29A (manufactured by Nissan Chemical Industries, Ltd.) was coated on a silicon wafer and baked at 205° C. for 60 seconds to form an antireflective film having a film thickness of 86 nm. Then, the resist composition Ar-17 was coated thereon and baked at 100° C. for 60 seconds to form a resist film having a film thickness of 150 nm The obtained wafer was subjected to first pattern exposure via an exposure mask (line/space=1/1) using an ArF excimer laser scanner (NA 0.75). Subsequently, the mask was rotated in the direction perpendicular to the first exposure, via which second pattern exposure was conducted. Thereafter, the wafer was heated at 90° C. for 60 seconds and then subjected to development with a negative-tone developer for 30 seconds (negative-tone development), rinsed with a rinsing liquid, and then rotated at a rotational speed of 4000 rpm for 30 seconds to obtain a hole pattern having a pitch of 240 nm and a hole diameter of 120 nm.

### Comparative Example 5

By the same method as in Example 31 except for using the resists and the conditions as set forth in Table 3, a hole pattern of a pitch of 240 nm and a hole diameter of 120 nm was obtained.

### Example 32

### Exposure Once→Bake→Positive Development→Bake→Negative Development: Abbreviated Symbol E-B-P-B-N

An organic antireflective film ARC29A (manufactured by Nissan Chemical Industries, Ltd.) was coated on a silicon wafer and baked at 205° C. for 60 seconds to form an antireflective film having a film thickness of 86 nm. Then, the resist composition Ar-18 was coated thereon and baked at 100° C. for 60 seconds to form a resist film having a film thickness of 150 nm. The obtained wafer was subjected to first pattern exposure via an exposure mask (line/space=1/1) using an ArF excimer laser scanner (NA 0.75). Thereafter, the wafer was heated at 90° C. for 60 seconds and then subjected to development with an aqueous tetramethyl ammonium hydroxide solution (2.38% by mass) for 30 seconds (positive-tone development), and rinsed with pure water to obtain a pattern having a pitch of 480 nm and a line width of 360 nm. Then, the wafer was heated at 130° C. for 60 seconds and then subjected to development with a negative-tone developer for 30 seconds (negative-tone development), rinsed with a rinsing liquid, and then rotated at a rotational speed of 4000 rpm for 30 seconds to obtain a resist pattern of a 120 nm (1:1) line-and-space.

### Example 33

### Exposure Once a Bake→Negative Development→Bake→Positive Development: Abbreviated Symbol E-B-N-B-P

An organic antireflective film ARC29A (manufactured by Nissan Chemical Industries, Ltd.) was coated on a silicon wafer and baked at 205° C. for 60 seconds to form an antireflective film having a film thickness of 86 nm. Then, the resist composition Ar-19 was coated thereon and baked at 100° C. for 60 seconds to form a resist film having a film thickness of 150 nm. The obtained wafer was subjected to first pattern exposure via an exposure mask (line/space=1/1) using an ArF excimer laser scanner (NA 0.75). Thereafter, the wafer was heated at 90° C. for 60 seconds and then subjected to development with a negative-tone developer for 30 seconds (negative-tone development), rinsed with a rinsing liquid, and then rotated at a rotational speed of 4000 rpm for 30 seconds to obtain a pattern having a pitch of 400 nm and a line width of 300 nm. Then, the wafer was heated at 130° C. for 60 seconds and then subjected to development with an aqueous tetramethyl ammonium hydroxide solution (2.38% by mass) for 30 seconds (positive-tone development), and rinsed with pure water to obtain a resist pattern of a 120 nm (1:1) line-and-space.

### Example 34

### Immersion Exposure Once→Negative Development: Abbreviated Symbol iE-B-N)

An organic antireflective film ARC29SR (manufactured by Nissan Chemical Industries, Ltd.) was coated on a silicon wafer and baked at 205° C. for 60 seconds to form an antireflective film having a film thickness of 95 nm. Then, the resist composition Ar-20 was coated thereon and baked at 100° C. for 60 seconds to form a resist film having a film thickness of 100 nm. The obtained wafer was subjected to pattern exposure via an exposure mask (line/space=1/1) using an ArF excimer laser scanner (NA 1.20). Pure water was used as the immersion liquid. Thereafter, the obtained wafer was heated at 90° C. for 60 seconds and then subjected to development with a negative-tone developer for 30 seconds (negative-tone development), rinsed with a rinsing liquid, and then rotated at a rotational speed of 4000 rpm for 30 seconds to obtain a hole pattern having a pitch of 100 nm and a line width of 50 nm.

### Comparative Example 6

By the same method as in Example 34 except for using the resists and the conditions as set forth in Table 3, a hole pattern of a pitch of 100 nm and a line width of 50 nm was obtained.

TABLE 3

| | | | | | Negative | Negative | Solvent | Rinsing | Rinsing | Solvent | Step |
|---|---|---|---|---|---|---|---|---|---|---|---|
| | | | First | Second | developer | developer | ratio | liquid | liquid | ratio | abbrevi- |
| | Resist | PB | PEB | PEB | (1) | (2) | (1)/(2) | (1) | (2) | (1)/(2) | ation |
| Example 1 | Ar-1 | 100C60s | 90C60s | — | Butyl | | 100/0 | 1-Hexanol | | 100/0 | E-B-N |
| | | | | | acetate | | | | | | |
| Example 2 | Ar-2 | 100C60s | 90C60s | — | Butyl | B1 | 70/30 | 1-Hexanol | | 100/0 | E-B-N |
| | | | | | acetate | | | | | | |
| Example 3 | Ar-3 | 100C60s | 90C60s | — | B1 | | 100/0 | 1-Hexanol | | 100/0 | E-B-N |
| Example 4 | Ar-4 | 100C60s | 90C60s | — | B1 | | 100/0 | t-Butyl alcohol | | 100/0 | E-B-N |
| Example 5 | Ar-5 | 100C60s | 90C60s | — | Butyl | | 100/0 | t-Butyl alcohol | | 100/0 | E-B-N |
| | | | | | acetate | | | | | | |
| Example 6 | Ar-6 | 100C60s | 90C60s | — | Butyl | | 100/0 | 1-Hexanol | Dibutyl | 80/20 | E-B-N |
| | | | | | acetate | | | | ether | | |
| Example 7 | Ar-7 | 100C60s | 90C60s | — | Butyl | | 100/0 | 1-Hexanol | Dibutyl | 50/50 | E-B-N |
| | | | | | acetate | | | | ether | | |
| Example 8 | Ar-8 | 100C60s | 90C60s | — | Butyl | | 100/0 | 4-Methyl-2-pentanol | Diisoamyl | 20/80 | E-B-N |
| | | | | | acetate | | | | ether | | |
| Example 9 | Ar-9 | 100C60s | 90C60s | — | Butyl | | 100/0 | 4-Methyl-2-pentanol | | 100/0 | E-B-N |
| | | | | | acetate | | | | | | |
| Example 10 | Ar-10 | 100C60s | 90C60s | — | Butyl | | 100/0 | 4-Methyl-2-pentanol | | 100/0 | E-B-N |
| | | | | | acetate | | | | | | |
| Example 11 | Ar-11 | 100C60s | 90C60s | — | Butyl | | 100/0 | 4-Methyl-2-pentanol | | 100/0 | E-B-N |
| | | | | | acetate | | | | | | |
| Example 12 | Ar-12 | 100C60s | 90C60s | — | Butyl | | 100/0 | 4-Methyl-2-pentanol | | 100/0 | E-B-N |
| | | | | | acetate | | | | | | |
| Example 13 | Ar-13 | 100C60s | 90C60s | — | Butyl | | 100/0 | 4-Methyl-2-pentanol | | 100/0 | E-B-N |
| | | | | | acetate | | | | | | |
| Example 14 | Ar-14 | 100C60s | 90C60s | — | Butyl | | 100/0 | 4-Methyl-2-pentanol | | 100/0 | E-B-N |
| | | | | | acetate | | | | | | |
| Example 15 | Ar-15 | 100C60s | 90C60s | — | Butyl | | 100/0 | 4-Methyl-2-pentanol | | 100/0 | E-B-N |
| | | | | | acetate | | | | | | |
| Example 16 | Ar-16 | 100C60s | 90C60s | — | Butyl | | 100/0 | 4-Methyl-2-pentanol | | 100/0 | E-B-N |
| | | | | | acetate | | | | | | |
| Example 17 | Ar-17 | 100C60s | 90C60s | — | Butyl | | 100/0 | 1-Hexanol | | 100/0 | E-B-N |
| | | | | | acetate | | | | | | |
| Example 18 | Ar-18 | 100C60s | 90C60s | — | Butyl | | 100/0 | 1-Hexanol | | 100/0 | E-B-N |
| | | | | | acetate | | | | | | |
| Example 19 | Ar-19 | 100C60s | 90C60s | — | Butyl | | 100/0 | 4-Methyl-2-pentanol | | 100/0 | E-B-N |
| | | | | | acetate | | | | | | |
| Example 20 | Ar-20 | 100C60s | 90C60s | — | Butyl | | 100/0 | 4-Methyl-2-pentanol | | 100/0 | E-B-N |
| | | | | | acetate | | | | | | |
| Example 21 | Ar-21 | 100C60s | 90C60s | — | Butyl | | 100/0 | 2-Hexanol | | 100/0 | E-B-N |
| | | | | | acetate | | | | | | |
| Example 22 | Ar-22 | 100C60s | 90C60s | — | Butyl | | 100/0 | 1-Pentanol | | 100/0 | E-B-N |
| | | | | | acetate | | | | | | |
| Example 23 | Ar-23 | 100C60s | 90C60s | — | Butyl | | 100/0 | 1-Hexanol | Diisoamyl | 80/20 | E-B-N |
| | | | | | acetate | | | | ether | | |
| Example 24 | Ar-24 | 100C60s | 90C60s | — | Butyl | | 100/0 | 1-Hexanol | Diisoamyl | 20/80 | E-B-N |
| | | | | | acetate | | | | ether | | |
| Example 25 | Ar-25 | 100C60s | 90C60s | — | Butyl | | 100/0 | 4-Methyl-2-pentanol | | 100/0 | E-B-N |
| | | | | | acetate | | | | | | |
| Example 26 | Ar-26 | 100C60s | 90C60s | — | Butyl | | 100/0 | 2-Hexanol | | 100/0 | E-B-N |
| | | | | | acetate | | | | | | |
| Example 27 | Ar-27 | 100C60s | 90C60s | — | Butyl | | 100/0 | 1-Pentanol | | 100/0 | E-B-N |
| | | | | | acetate | | | | | | |
| Example 28 | Ar-28 | 100C60s | 90C60s | — | Butyl | | 100/0 | 1-Hexanol | Diisoamyl | 20/80 | E-B-N |
| | | | | | acetate | | | | ether | | |
| Example 29 | Ar-13 | 100C60s | 90C60s | — | Butyl | | 100/0 | 4-Methyl-2-pentanol | | 100/0 | E-B-P-N |
| | | | | | acetate | | | | | | |
| Example 30 | Ar-13 | 100C60s | 90C60s | — | Butyl | | 100/0 | 4-Methyl-2-pentanol | | 100/0 | E-B-N-P |
| | | | | | acetate | | | | | | |
| Example 31 | Ar-17 | 100C60s | 90C60s | — | Butyl | | 100/0 | 1-Hexanol | | 100/0 | E-E-B-N |
| | | | | | acetate | | | | | | |
| Example 32 | Ar-18 | 100C60s | 90C60s | 130C60s | Butyl | | 100/0 | 1-Hexanol | | 100/0 | E-B-P- |
| | | | | | acetate | | | | | | B-N |
| Example 33 | Ar-19 | 100C60s | 90C60s | 130C60s | Butyl | | 100/0 | 1-Hexanol | | 100/0 | E-B-N- |
| | | | | | acetate | | | | | | B-P |
| Example 34 | Ar-20 | 100C60s | 90C60s | — | Butyl | | 100/0 | 1-Hexanol | | 100/0 | iE-B-N |
| | | | | | acetate | | | | | | |
| Compara- | Ar-R1 | 115C60s | 105C60s | — | Butyl | | 100/0 | 1-Hexanol | | 100/0 | E-B-N |
| tive | (Compara- | | | | acetate | | | | | | |
| Example 1 | tive | | | | | | | | | | |
| | Example) | | | | | | | | | | |
| Compara- | Ar-R2 | 115C60s | 105C60s | — | Butyl | | 100/0 | 1-Hexanol | | 100/0 | E-B-N |
| tive | (Compara- | | | | acetate | | | | | | |
| Example 2 | tive | | | | | | | | | | |
| | Example) | | | | | | | | | | |
| Compara- | Ar-R1 | 115C60s | 105C60s | — | Butyl | | 100/0 | 1-Hexanol | | 100/0 | E-B-P-N |
| tive | (Compara- | | | | acetate | | | | | | |
| Example 3 | tive | | | | | | | | | | |
| | Example) | | | | | | | | | | |
| Compara- | Ar-R1 | 115C60s | 105C60s | — | Butyl | | 100/0 | 1-Hexanol | | 100/0 | E-B-N-P |
| tive | (Compara- | | | | acetate | | | | | | |
| Example 4 | tive | | | | | | | | | | |
| | Example) | | | | | | | | | | |
| Compara- | Ar-R1 | 115C60s | 105C60s | — | Butyl | | 100/0 | 1-Hexanol | | 100/0 | E-E-B-N |
| tive | (Compara- | | | | acetate | | | | | | |
| Example 5 | tive | | | | | | | | | | |
| | Example) | | | | | | | | | | |
| Compara- | Ar-R1 | 115C60s | 105C60s | — | Butyl | | 100/0 | 1-Hexanol | | 100/0 | iE-B-N |
| tive | (Compara- | | | | acetate | | | | | | |
| Example 6 | tive | | | | | | | | | | |
| | Example) | | | | | | | | | | |

In Table 3, PB means heating before exposure and PEB means heating after exposure. Further, in the sections of PB, First PEB and Second PEB, for example, “100C 60s” means heating at 100° C. for 60 seconds. B1 of the negative-tone developer represents the above-described solvent. The “negative developer ratio (1)/(2)” and the “rinsing liquid ratio (1)/(2)” means a molar ratio, respectively.

<Evaluation Methods>

[Line Edge Roughness (LWR)]

A resist pattern of a line-and-space of 90 nm (1:1), 120 nm (1:1), or 50 nm (1:1) was observed by using a length-measuring scanning electron microscope (SEM manufactured by Hitachi, Ltd., S-9380 II). Within a 2 μm area in the longitudinal direction of the space pattern, measurement of line width was made at 50 points at the constant intervals, and 3σ was computed from the standard deviation. A smaller value indicates the better performance (Further, with respect to Example 31 and Comparative Example 5, evaluation of HR below was conducted instead of evaluation of LWR).

[Hole Roughness (HR)]

The hole patterns obtained in Example 31 and Comparative Example 5 were observed by using a length-measuring scanning electron microscope (SEM manufactured by Hitachi, Ltd., S-9380 II). Measurement was made by computing 3σ from the standard deviation of the diameters of the hole patterns. A smaller value indicates the better performance.

[Exposure Latitude (EL)]

Assuming that an exposure amount for forming a resist pattern of a line-and-space of 90 nm (1:1), 120 nm (1:1), or 50 nm (1:1) (provided that in the case of Example 31 and Comparative Example 5, the hole patterns of a pitch of 240 nm and a hole diameter of 120 nm) is an optimal exposure amount (which means, in the case of the multiple development, after finally conducting the multiple development, an exposure dose of a resist pattern of the above-described line-and-space, and thus, in the case of the multiple development, a first exposure dose for forming a resist pattern of the above-described line-and-space), an exposure amount width allowing a pattern size of 90 nm±10% when the exposure amount is varied is determined, and this value is divided by the optimal exposure amount, thereby obtaining an exposure latitude, which is expressed in terms of a percentage. A larger value indicates a smaller change in the performance due to change in the exposure amount and better exposure latitude (EL).

[Defocus Latitude (DOF)]

Assuming that an exposure amount and a focus an exposure amount for forming a resist pattern of a line-and-space of 90 nm (1:1), 120 nm (1:1), or 50 nm (1:1) (provided that in the case of Example 31 and Comparative Example 5, the hole patterns of a pitch of 240 nm and a hole diameter of 120 nm) are an optimal exposure amount (which means, in the case of the multiple development, after finally conducting the multiple development, an exposure dose of a resist pattern of the above-described line-and-space, and in the case of the multiple development, a first exposure dose for forming a resist pattern of the above-described line-and-space) and an optimal focus, respectively, the width of focus allowing the pattern size of 90 nm±10%, when the focus is varied (defocused) while maintaining the exposure amount at a level of the optimal exposure amount, was determined. A larger value indicates a smaller change in performance due to change in the focus and better depth of focus (DOF).

TABLE 4

| | | LWR/HR | EL | DOF |
|---|---|---|---|---|
| | Resist | [nm] | [%] | [μm] |
| Example 1 | Ar-1 | 7.5 | 9.3 | 0.55 |
| Example 2 | Ar-2 | 7.5 | 9.3 | 0.55 |
| Example 3 | Ar-3 | 7.5 | 9.3 | 0.55 |
| Example 4 | Ar-4 | 7.5 | 9.3 | 0.55 |
| Example 5 | Ar-5 | 7.5 | 9.3 | 0.55 |
| Example 6 | Ar-6 | 7.5 | 9.3 | 0.55 |
| Example 7 | Ar-7 | 7.5 | 9.3 | 0.55 |
| Example 8 | Ar-8 | 7.5 | 9.3 | 0.55 |
| Example 9 | Ar-9 | 7.5 | 9.3 | 0.55 |
| Example 10 | Ar-10 | 7.5 | 9.3 | 0.55 |
| Example 11 | Ar-11 | 7.5 | 9.3 | 0.55 |
| Example 12 | Ar-12 | 7.5 | 9.3 | 0.55 |
| Example 13 | Ar-13 | 6.5 | 10.3 | 0.65 |
| Example 14 | Ar-14 | 6.5 | 10.3 | 0.65 |
| Example 15 | Ar-15 | 6.5 | 10.3 | 0.65 |
| Example 16 | Ar-16 | 6.5 | 10.3 | 0.65 |
| Example 17 | Ar-17 | 6.5 | 10.3 | 0.65 |
| Example 18 | Ar-18 | 6.5 | 10.3 | 0.65 |
| Example 19 | Ar-19 | 6.5 | 10.3 | 0.65 |
| Example 20 | Ar-20 | 6.5 | 10.3 | 0.65 |
| Example 21 | Ar-21 | 6.5 | 10.3 | 0.65 |
| Example 22 | Ar-22 | 6.5 | 10.3 | 0.65 |
| Example 23 | Ar-23 | 6.5 | 10.3 | 0.65 |
| Example 24 | Ar-24 | 6.5 | 10.3 | 0.65 |
| Example 25 | Ar-25 | 6.5 | 10.3 | 0.65 |
| Example 26 | Ar-26 | 6.5 | 10.3 | 0.65 |
| Example 27 | Ar-27 | 7.5 | 9.1 | 0.6 |
| Example 28 | Ar-28 | 6.5 | 10.3 | 0.65 |
| Example 29 | Ar-13 | 10.4 | 7.2 | 0.3 |
| Example 30 | Ar-13 | 10.4 | 8.2 | 0.3 |
| Example 31 | Ar-17 | 6.5 | 10.3 | 0.65 |
| Example 32 | Ar-18 | 10 | 10 | 0.3 |
| Example 33 | Ar-19 | 10 | 10 | 0.3 |
| Example 34 | Ar-20 | 6.2 | 12 | 0.65 |
| Comparative | Ar-R1 | 15.5 | 5.5 | 0.2 |
| Example 1 | (Comparative Example) | | | |
| Comparative | Ar-R2 | 15.5 | 5.5 | 0.2 |
| Example 2 | (Comparative Example) | | | |
| Comparative | Ar-R1 | 19.5 | 3.5 | 0.1 |
| Example 3 | (Comparative Example) | | | |
| Comparative | Ar-R1 | 19.5 | 3.5 | 0.1 |
| Example 4 | (Comparative Example) | | | |
| Comparative | Ar-R1 | 15.5 | 5.5 | 0.2 |
| Example 5 | (Comparative Example) | | | |
| Comparative | Ar-R1 | 15 | 5 | 0.2 |
| Example 6 | (Comparative Example) | | | |

From Table 4, it is clear that a fine pattern with high precision, which is excellent in line edge roughness (hole roughness), exposure latitude, and depth of focus, can be stably formed by the resist composition for negative-tone development of the present invention.

### INDUSTRIAL APPLICABILITY

According to the present invention, a resist composition for negative-tone development, which is excellent in line width roughness (LWR), exposure latitude (EL), and depth of focus (DOF), and a pattern forming method using the same can be provided.

The entire disclosure of Japanese Patent Application No. 2009-041379 filed on Feb. 24, 2009, from which the benefit of foreign priority has been claimed in the present application, is incorporated herein by reference, as if fully set forth.

1. A resist composition for negative-tone development, comprising:
(A) a resin having an acid-decomposable repeating unit represented by the following general formula (1) and being capable of decreasing the solubility in a negative developer by the action of an acid: 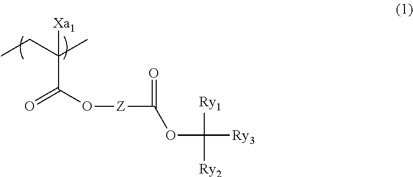
wherein, in the general formula (1),
Xa₁ represents a hydrogen atom, an alkyl group, a cyano group, or a halogen atom,
each of Ry₁ to Ry₃ independently represents an alkyl group or a cycloalkyl group, and at least two of Ry₁ to Ry₃ may be bonded to each other to form a ring structure, and
Z represents a divalent linking group.

2. The resist composition for negative-tone development according to claim 1, wherein
in the case where at least two of Ry₁ to Ryₐ are bonded to each other to form a monocyclic hydrocarbon structure, the monocyclic hydrocarbon structure is a 6 or more-membered ring.

3. The resist composition for negative-tone development according to claim 1, wherein
the repeating unit represented by the general formula (1) is an acid-decomposable repeating unit represented by the following general formula (2a) or (2b): 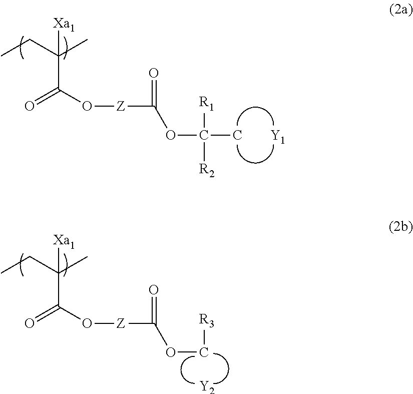
wherein, in the general formulae (2a) and (2b),
Xa₁ and Z are respectively the same as Xa₁ and Z in the general formula (1),
Y₁ represents a plurality of atoms necessary to complete an alicyclic hydrocarbon group together with the carbon atom as shown,
Y₂ represents a plurality of atoms necessary to complete an alicyclic hydrocarbon group together with the carbon atom as shown, and
each of R₁, R₂, and R₃ independently represents an alkyl group or a cycloalkyl group.

4. The resist composition for negative-tone development according to claim 3, wherein
the resin (A) does not have a repeating unit derived from an acrylic acid or an acrylic ester, in the case where the total number of carbon atoms of Y₁, R₁, and R₂ in the general formula (2a) is 6 or less, and in the case where the total number of carbon atoms of Y₂ and R₃ in the general formula (2b) is 6 or less.

5. The resist composition for negative-tone development according to claim 3, wherein
with respect to all repeating units derived from an acrylic acid or an acrylic ester in the resin (A), a carbon atom at the α-position in the repeating units, which is a carbon atom constituting a main chain of the resin and bonding to a —C(═O)— group, is substituted with a substituent other than a hydrogen atom via a bonding moiety not constituting the main chain of the resin and not bonding to the —C(═O)— group, in the case where the total number of carbon atoms of Y₁, R₁, and R₂ in the general formula (2a) is 6 or less, and in the case where the total number of carbon atoms of Y₂ and R₃ in the general formula (2b) is 6 or less.

6. The resist composition for negative-tone development according to claim 5, wherein
the substituent is an alkyl group, a cyano group, or a halogen atom.

7. The resist composition for negative-tone development according to claim 5, wherein
the substituent is a methyl group.

8. The resist composition for negative-tone development according to claim 1, further comprising:
(B) an acid generator; and
(C) a solvent.

9. A pattern forming method comprising:
(a) a step of forming a film with the resist composition for negative-tone development according to claim 1,
(b) a step of exposing the film, and
(d) a step of developing the film with a negative-tone developer,
wherein the negative-tone developer is an organic-based developer containing an organic solvent.

10. The pattern forming method according to claim 9, further comprising:
(c) a step of developing the film with a positive-tone developer,
wherein
the resin is a resin capable of increasing the polarity by the action of an acid to increase the solubility in a positive-tone developer.

11. A pattern forming method comprising:
(a) a step of forming a film with the resist composition for negative-tone development according to claim 2,
(b) a step of exposing the film, and
(d) a step of developing the film with a negative-tone developer,
wherein the negative-tone developer is an organic-based developer containing an organic solvent.

12. A pattern forming method comprising:
(a) a step of forming a film with the resist composition for negative-tone development according to claim 3,
(b) a step of exposing the film, and
(d) a step of developing the film with a negative-tone developer,
wherein the negative-tone developer is an organic-based developer containing an organic solvent.

13. A pattern forming method comprising:
(a) a step of forming a film with the resist composition for negative-tone development according to claim 4,
(b) a step of exposing the film, and
(d) a step of developing the film with a negative-tone developer,
wherein the negative-tone developer is an organic-based developer containing an organic solvent.

14. A pattern forming method comprising:
(a) a step of forming a film with the resist composition for negative-tone development according to claim 5,
(b) a step of exposing the film, and
(d) a step of developing the film with a negative-tone developer,
wherein the negative-tone developer is an organic-based developer containing an organic solvent.

15. A pattern forming method comprising:
(a) a step of forming a film with the resist composition for negative-tone development according to claim 6,
(b) a step of exposing the film, and
(d) a step of developing the film with a negative-tone developer,
wherein the negative-tone developer is an organic-based developer containing an organic solvent.

16. A pattern forming method comprising:
(a) a step of forming a film with the resist composition for negative-tone development according to claim 7,
(b) a step of exposing the film, and
(d) a step of developing the film with a negative-tone developer,
wherein the negative-tone developer is an organic-based developer containing an organic solvent.

17. A pattern forming method comprising:
(a) a step of forming a film with the resist composition for negative-tone development according to claim 8,
(b) a step of exposing the film, and
(d) a step of developing the film with a negative-tone developer,
wherein the negative-tone developer is an organic-based developer containing an organic solvent.

18. The resist composition for negative-tone development according to claim 1,
wherein
each of Ry₁ to Ryₐ independently represents an alkyl group.

19. A pattern forming method comprising:
(a) a step of forming a film with the resist composition for negative-tone development according to claim 18,
(b) a step of exposing the film, and
(d) a step of developing the film with a negative-tone developer,
wherein the negative-tone developer is an organic-based developer containing an organic solvent.
